(19) United States
(12) Patent Application Publication
(10) Pub. No.: US 2025/0351674 A1
(43) Pub. Date: Nov. 13, 2025

(54) SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Masataka NAKADA, Tochigi (JP); Yukinori SHIMA, Tatebayashi (JP); Masayoshi DOBASHI, Shimotsuga (JP); Junichi KOEZUKA, Tochigi (JP); Daisuke KUROSAKI, Utsunomiya (JP)

(21) Appl. No.: 19/100,705

(22) PCT Filed: Jul. 27, 2023
(86) PCT No.: PCT/IB2023/057604

§ 371 Date: Feb. 3, 2025

(30) Foreign Application Priority Data
Aug. 10, 2022 (JP) 2022-128020

(51) Int. Cl. H10K 59/121; H10K 59/12

(52) U.S. Cl. CPC H10K 59/1213; H10K 59/1201

(57) ABSTRACT

A semiconductor device achieving both low power consumption and high performance is provided. The semiconductor device includes first and second transistors and a first insulating layer. The first transistor includes first to third conductive layers, a first semiconductor layer, and a second insulating layer. The first insulating layer is sandwiched between the first conductive layer and the second conductive layer. The first insulating layer and the second conductive layer include an opening reaching the first conductive layer. In the opening, the first semiconductor layer is in contact with a top surface of the first conductive layer, a side surface of the first insulating layer, and a side surface of the second conductive layer. The first semiconductor layer includes a region overlapping with the third conductive layer with the second insulating layer therebetween. The second transistor includes a second semiconductor layer, second and third insulating layers, and a fourth conductive layer. An end portion of the second semiconductor layer is aligned or substantially aligned with an end portion of the third insulating layer. The second semiconductor layer includes a region overlapping with the fourth conductive layer with the second insulating layer and the third insulating layer therebetween.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. In a display device, for example, when the area occupied by transistors is reduced, the pixel size can be reduced and resolution can be increased. Thus, minute transistors have been required.

As devices requiring high-resolution display devices, for example, devices for virtual reality (VR), augmented reality (AR), substitutional reality (SR), or mixed reality (MR) have been actively developed.

As a display device, a light-emitting apparatus including an organic EL (Electro Luminescence) element or a light-emitting diode (LED) has been developed.

Patent Document 1 discloses a high-resolution display device using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a semiconductor device including a transistor having a minute size. Another object is to provide a semiconductor device including a transistor with a short channel length. Another object is to provide a semiconductor device including a transistor with a high on-state current. Another object is to provide a semiconductor device including a highly reliable transistor. Another object is to provide a semiconductor device including a transistor with favorable electrical characteristics. Another object is to provide a semiconductor device that occupies a small area. Another object of one embodiment of the present invention is to provide a high-performance semiconductor device. Another object is to provide a semiconductor device with low power consumption. Another object is to provide a highly reliable semiconductor device. Another object is to provide a semiconductor device with high productivity. Another object is to provide a novel semiconductor device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first transistor, a second transistor, and a first insulating layer. The first transistor includes a first conductive layer, a second conductive layer, a first semiconductor layer, a second insulating layer over the first semiconductor layer, and a third conductive layer over the second insulating layer. The first insulating layer is sandwiched between the first conductive layer and the second conductive layer. The first insulating layer and the second conductive layer include an opening reaching the first conductive layer. In the opening, the first semiconductor layer is in contact with a top surface of the first conductive layer, a side surface of the first insulating layer, and a side surface of the second conductive layer. The first semiconductor layer includes a region overlapping with the third conductive layer with the second insulating layer therebetween. The second transistor includes a second semiconductor layer over the first insulating layer, a third insulating layer over the second semiconductor layer, the second insulating layer over the third insulating layer, and a fourth conductive layer over the second insulating layer. An end portion of the second semiconductor layer is aligned or substantially aligned with an end portion of the third insulating layer. The second insulating layer is in contact with a top surface and a side surface of the third insulating layer and a side surface of the second semiconductor layer. The second semiconductor layer includes a region overlapping with the fourth conductive layer with the second insulating layer and the third insulating layer therebetween.

The above semiconductor device preferably includes a fourth insulating layer between the first insulating layer and the second semiconductor layer. The fourth insulating layer is preferably in contact with a bottom surface of the second conductive layer.

The above semiconductor device preferably includes an island-shaped fourth insulating layer between the first insulating layer and the second semiconductor layer. The end portion of the second semiconductor layer is preferably in contact with a top surface of the fourth insulating layer. An end portion of the fourth insulating layer is preferably in contact with a top surface of the first insulating layer. The second insulating layer is preferably in contact with the top surface and a side surface of the fourth insulating layer.

The above semiconductor device preferably includes a fourth insulating layer between the first insulating layer and the second semiconductor layer. The fourth insulating layer is preferably in contact with a top surface and a side surface of the second conductive layer.

One embodiment of the present invention is a semiconductor device including a first transistor, a second transistor, and a first insulating layer. The first transistor includes a first conductive layer, a second conductive layer, a first semiconductor layer, a second insulating layer over the first semiconductor layer, and a third conductive layer over the second insulating layer. The first insulating layer is sandwiched between the first conductive layer and the second conductive layer. The first insulating layer and the second conductive layer include a first opening reaching the first conductive layer. In the first opening, the first semiconductor layer is in contact with a top surface of the first conductive layer, a side surface of the first insulating layer, and a side surface of the second conductive layer. The first semiconductor layer includes a region overlapping with the third conductive layer with the second insulating layer therebetween. The second transistor includes a fourth conductive layer, a fifth conductive layer, a second semiconductor layer, a third insulating layer over the second semiconductor layer, the second insulating layer over the third insulating layer, and a sixth conductive layer over the second insulating layer. The first insulating layer is sandwiched between the fourth conductive layer and the fifth conductive layer. The first insulating layer and the fifth conductive layer include a second opening reaching the fourth conductive layer. In the second opening, the second semiconductor layer is in contact with a top surface of the fourth conductive layer, a side surface of the first insulating layer, and a side surface of the fifth conductive layer. An end portion of the second semiconductor layer is aligned or substantially aligned with an end portion of the third insulating layer. The second semiconductor layer includes a region overlapping with the sixth conductive layer with the second insulating layer and the third insulating layer therebetween. In the above semiconductor device, the first semiconductor layer and the second semiconductor layer each preferably include a metal oxide.

In the above semiconductor device, the first semiconductor layer and the second semiconductor layer preferably include different materials.

In the above semiconductor device, the first semiconductor layer and the second semiconductor layer preferably include the same material.

In the above semiconductor device, the second transistor preferably includes a seventh conductive layer. The seventh conductive layer preferably includes a region overlapping with the second semiconductor layer with the first insulating layer therebetween.

In the above semiconductor device, the first conductive layer and the seventh conductive layer preferably include the same material.

In the above semiconductor device, the second transistor preferably includes a seventh conductive layer. The seventh conductive layer is preferably provided between the first insulating layer and the fourth insulating layer.

In the above semiconductor device, the second conductive layer and the seventh conductive layer preferably include the same material.

### Effect of the Invention

One embodiment of the present invention can provide a semiconductor device including a transistor having a minute size. Alternatively, a semiconductor device including a transistor with a short channel length can be provided. Alternatively, a semiconductor device including a transistor with a high on-state current can be provided. Alternatively, a semiconductor device including a highly reliable transistor can be provided. Alternatively, a semiconductor device including a transistor with favorable electrical characteristics can be provided. Alternatively, a semiconductor device that occupies a small area can be provided. Alternatively, one embodiment of the present invention can provide a high-performance semiconductor device. Alternatively, a semiconductor device with low power consumption can be provided. Alternatively, a highly reliable semiconductor device can be provided. Alternatively, a semiconductor device with high productivity can be provided. Alternatively, a novel semiconductor device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2 is a perspective view illustrating an example of a semiconductor device.

FIG. 3A and FIG. 3B are perspective views illustrating a structure of a semiconductor device.

FIG. 4A and FIG. 4B are perspective views illustrating a structure of a semiconductor device.

FIG. 5A is a top view illustrating an example of a semiconductor device. FIG. 5B is a cross-sectional view illustrating the example of the semiconductor device.

FIG. 6A is a top view illustrating an example of a semiconductor device. FIG. 6B and FIG. 6C are cross-sectional views illustrating the example of the semiconductor device.

FIG. 7A to FIG. 7C are cross-sectional views illustrating examples of a semiconductor device.

FIG. 8A to FIG. 8C are cross-sectional views illustrating examples of a semiconductor device.

FIG. 9A and FIG. 9B are cross-sectional views illustrating an example of a semiconductor device.

FIG. 10A and FIG. 10B are cross-sectional views illustrating examples of a semiconductor device.

FIG. 11A and FIG. 11B are cross-sectional views illustrating an example of a semiconductor device.

FIG. 12A and FIG. 12B are cross-sectional views illustrating examples of a semiconductor device.

FIG. 13 is a cross-sectional view illustrating an example of a semiconductor device.

FIG. 14A and FIG. 14B are cross-sectional views illustrating an example of a semiconductor device.

FIG. 15A and FIG. 15B are cross-sectional views illustrating an example of a semiconductor device.

FIG. 16A and FIG. 16B are cross-sectional views illustrating an example of a semiconductor device.

FIG. 17A and FIG. 17B are cross-sectional views illustrating an example of a semiconductor device.

FIG. 18 is a cross-sectional view illustrating an example of a semiconductor device.

FIG. 19A and FIG. 19B are cross-sectional views illustrating an example of a semiconductor device.

FIG. 20A and FIG. 20B are cross-sectional views illustrating an example of a semiconductor device.

FIG. 21A and FIG. 21B are cross-sectional views illustrating an example of a semiconductor device.

FIG. 22 is a cross-sectional view illustrating an example of a semiconductor device.

FIG. 23A and FIG. 23B are cross-sectional views illustrating an example of a semiconductor device.

FIG. 24A is a top view illustrating an example of a semiconductor device. FIG. 24B and FIG. 24C are cross-sectional views illustrating the example of the semiconductor device.

FIG. 25 is a cross-sectional view illustrating an example of a semiconductor device.

FIG. 26A and FIG. 26B are cross-sectional views illustrating an example of a semiconductor device.

FIG. 27A is a top view illustrating an example of a semiconductor device. FIG. 27B is a cross-sectional view illustrating the example of the semiconductor device.

FIG. 28 is a cross-sectional view illustrating an example of a semiconductor device.

FIG. 29A is a top view illustrating an example of a semiconductor device. FIG. 29B and FIG. 29C are cross-sectional views illustrating the example of the semiconductor device.

FIG. 30A to FIG. 30E are cross-sectional views illustrating an example of a method for manufacturing a semiconductor device.

FIG. 31A to FIG. 31D are cross-sectional views illustrating an example of a method for manufacturing a semiconductor device.

FIG. 32A to FIG. 32D are cross-sectional views illustrating an example of a method for manufacturing a semiconductor device.

FIG. 33A to FIG. 33C are cross-sectional views illustrating an example of a method for manufacturing a semiconductor device.

FIG. 34A to FIG. 34D are cross-sectional views illustrating an example of a method for manufacturing a semiconductor device.

FIG. 35A to FIG. 35D are cross-sectional views illustrating an example of a method for manufacturing a semiconductor device.

FIG. 36A to FIG. 36D are cross-sectional views illustrating an example of a method for manufacturing a semiconductor device.

FIG. 37A to FIG. 37D are cross-sectional views illustrating an example of a method for manufacturing a semiconductor device.

FIG. 38A to FIG. 38C are cross-sectional views illustrating an example of a method for manufacturing a semiconductor device.

FIG. 39A to FIG. 39D are cross-sectional views illustrating an example of a method for manufacturing a semiconductor device.

FIG. 40A to FIG. 40D are cross-sectional views illustrating an example of a method for manufacturing a semiconductor device.

FIG. 41A to FIG. 41D are cross-sectional views illustrating an example of a method for manufacturing a semiconductor device.

FIG. 42A to FIG. 42D are cross-sectional views illustrating an example of a method for manufacturing a semiconductor device.

FIG. 43A to FIG. 43C are cross-sectional views illustrating an example of a method for manufacturing a semiconductor device.

FIG. 44A and FIG. 44B are cross-sectional views illustrating an example of a method for manufacturing a semiconductor device.

FIG. 45A is a perspective view illustrating an example of a display device. FIG. 45B is a block diagram of the display device.

FIG. 46A is a circuit diagram of a latch circuit. FIG. 46B is a circuit diagram of an inverter circuit.

FIG. 47A and FIG. 47B are each a circuit diagram of a pixel circuit. FIG. 47C is a cross-sectional view illustrating an example of a pixel circuit.

FIG. 48 is a cross-sectional view illustrating an example of a display device.

FIG. 49 is a cross-sectional view illustrating an example of a display device.

FIG. 50 is a cross-sectional view illustrating an example of a display device.

FIG. 51A to FIG. 51C are cross-sectional views illustrating an example of a display device.

FIG. 52 is a cross-sectional view illustrating an example of a display device.

FIG. 53 is a cross-sectional view illustrating an example of a display device.

FIG. 54 is a cross-sectional view illustrating an example of a display device.

FIG. 55A to FIG. 55F are cross-sectional views illustrating an example of a method for manufacturing a display device.

FIG. 56A to FIG. 56D are diagrams illustrating examples of electronic devices.

FIG. 57A to FIG. 57F are diagrams illustrating examples of electronic devices.

FIG. 58A to FIG. 58G are diagrams illustrating examples of electronic devices.

FIG. 59A and FIG. 59B are diagrams showing I_{d}-V_{g} characteristics of transistors of an example.

FIG. 60 is a diagram showing reliability of transistors of an example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, the expression “electrically connected” includes the case where components are connected through an “object having any electric function”. Here, there is no particular limitation on the “object having any electric function” as long as electric signals can be transmitted and received between the components that are connected through the object. Examples of the “object having any electric function” include a switching element such as a transistor, a resistor, a coil, a capacitor, and other elements with a variety of functions as well as an electrode and a wiring.

Unless otherwise specified, an off-state current in this specification and the like refers to a leakage current between a source and a drain of a transistor in an off state (also referred to as a non-conduction state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, the expression “top-view shapes are substantially the same” means that at least outlines of stacked layers partly overlap with each other. For example, the case of processing the upper layer and the lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also sometimes represented by the expression “top-view shapes are substantially the same”. In the case where top-view shapes are the same or substantially the same, it can be said that end portions match or substantially match each other.

In this specification and the like, a tapered shape refers to such a shape that at least part of the side surface of a structure is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the structure are not necessarily completely flat and may be substantially flat with a slight curvature or substantially flat with slight unevenness.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers of light-emitting elements (also referred to as light-emitting devices) having different emission wavelengths are separately formed may be referred to as an SBS (Side By Side) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have the functions of two or three of the carrier-injection layer, the carrier-transport layer, and the carrier-blocking layer.

In this specification and the like, a light-emitting element includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes an active layer functioning as a photoelectric conversion layer between a pair of electrodes. In this specification and the like, one of the pair of electrodes may be referred to as a pixel electrode and the other may be referred to as a common electrode.

Note that in this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

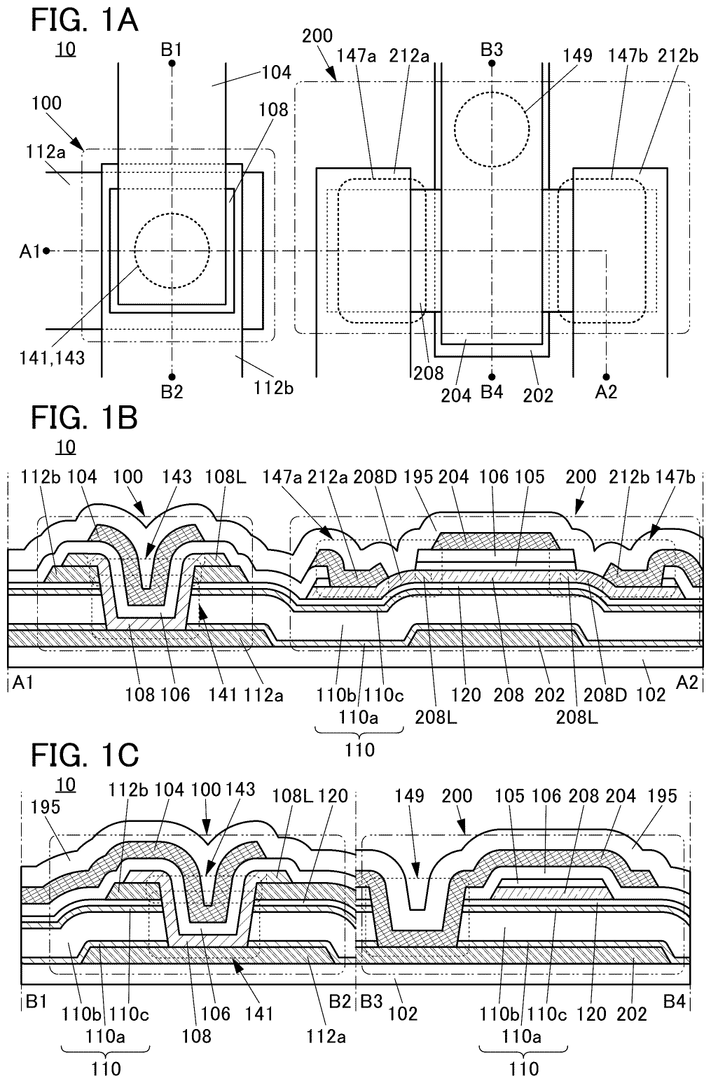

In this embodiment, a semiconductor device of one embodiment of the present invention will be described with reference to FIG. 1 to FIG. 25.

### Structure Example 1

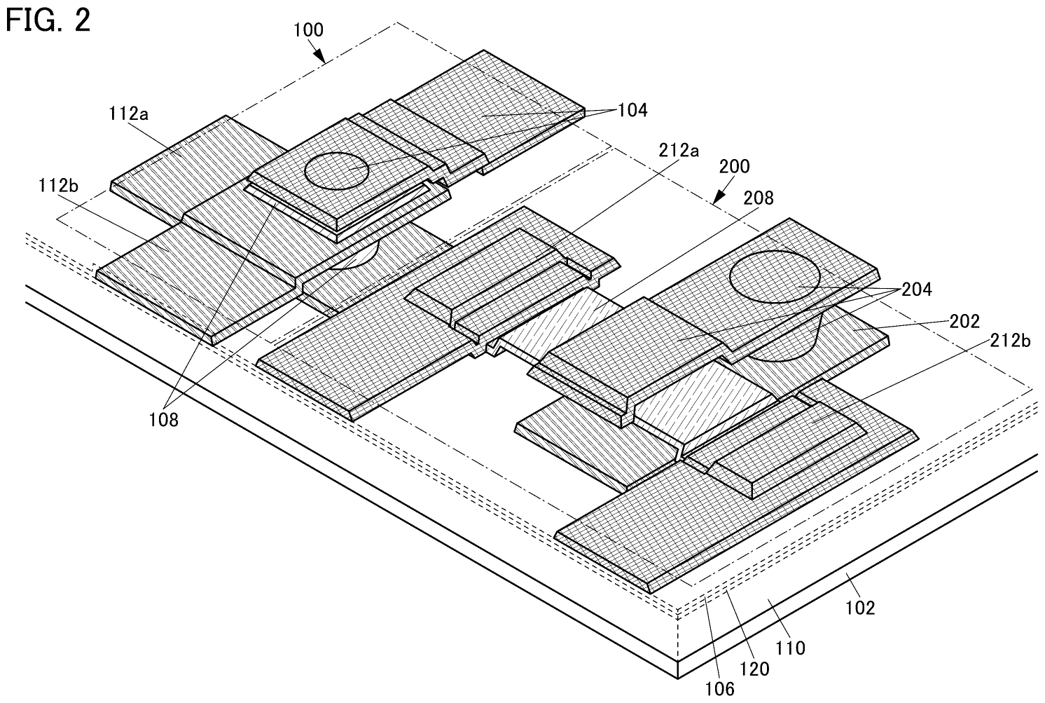

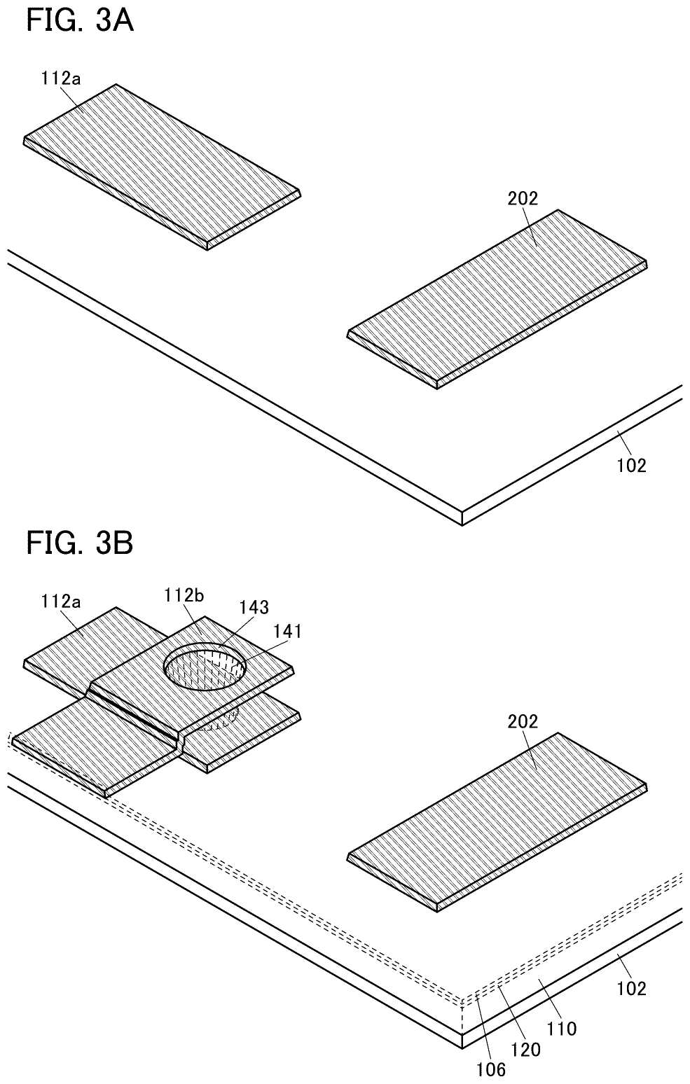

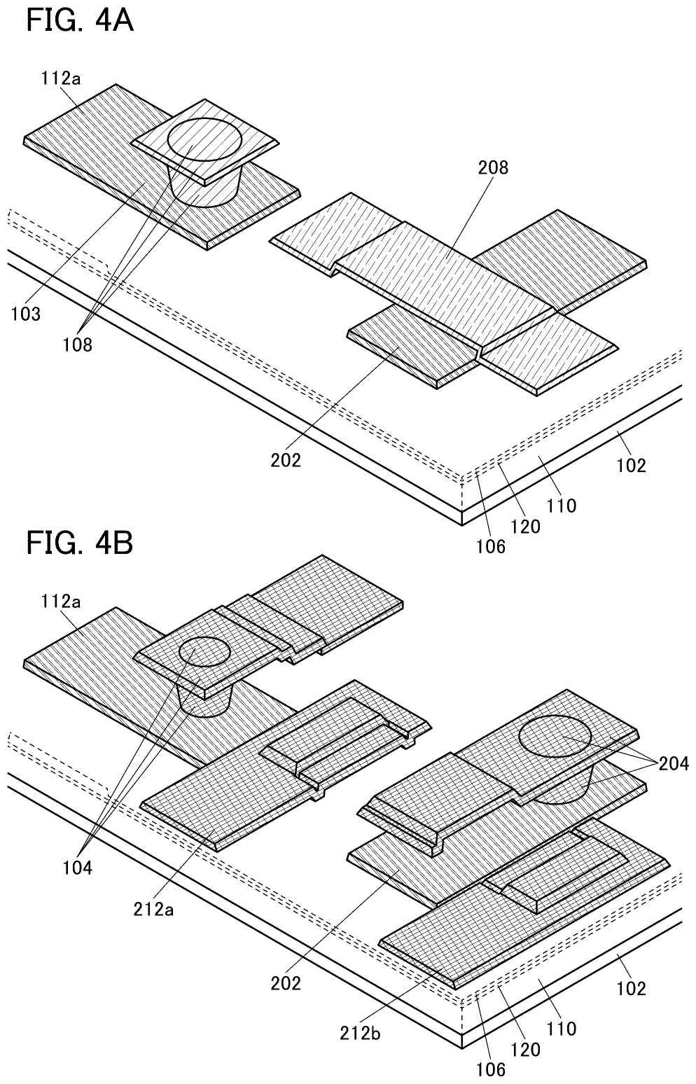

The semiconductor device of one embodiment of the present invention will be described. FIG. 1A is a top view (also referred to as a plan view) of a semiconductor device 10. FIG. 1B is a cross-sectional view of a cross section along the dashed-dotted line A1-A2 in FIG. 1A, and FIG. 1C is a cross-sectional view of cross sections along the dashed-dotted line B1-B2 and the dashed-dotted line B3-B4 in FIG. 1A. FIG. 2 is a perspective view of the semiconductor device 10. FIG. 3A to FIG. 4B are perspective views selectively illustrating some components of the semiconductor device 10. Note that in FIG. 1A, some components (e.g., an insulating layer) of the semiconductor device 10 are not illustrated. Some components are not illustrated in top views of semiconductor devices in the following diagrams, as in FIG. 1A. In FIG. 2 to FIG. 4B, insulating layers are illustrated to be seen through, and their outlines are indicated by dashed lines.

The semiconductor device 10 includes a transistor 100 and a transistor 200. The transistor 100 and the transistor 200 have different structures, and some steps can be shared in forming the transistor 100 and the transistor 200. The thickness of a gate insulating layer is different between the transistor 100 and the transistor 200. Furthermore, the material used for a semiconductor layer can be different between the transistor 100 and the transistor 200.

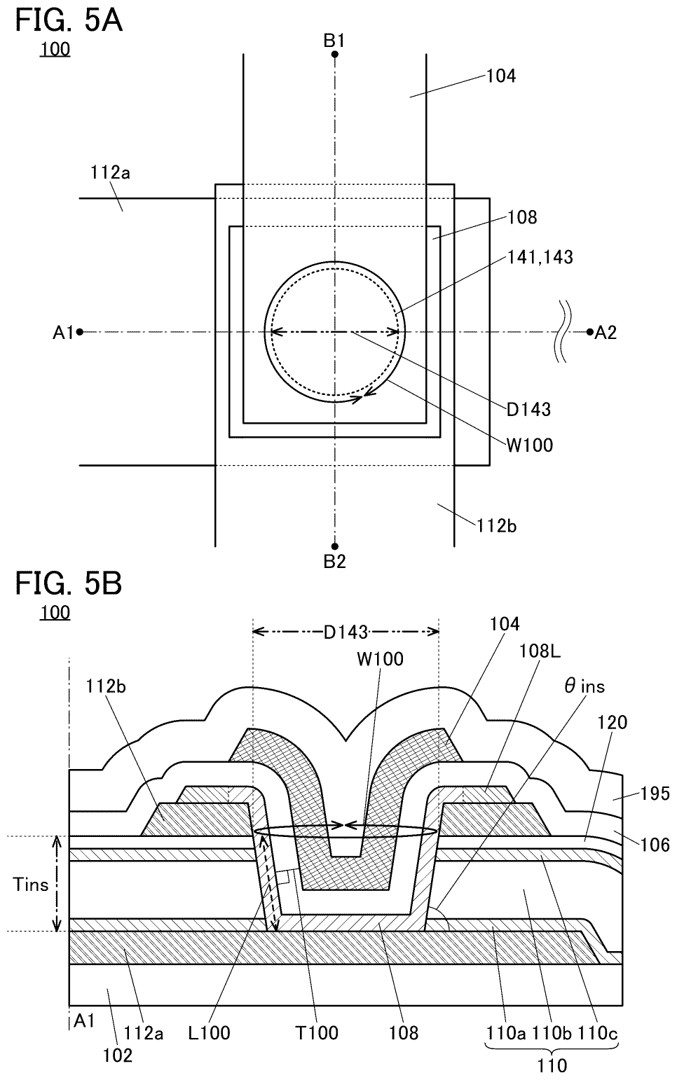

FIG. 5 is an enlarged view of the transistor 100 illustrated in FIG. 1B. The transistor 100 includes a conductive layer 112a, a semiconductor layer 108, a conductive layer 112b, an insulating layer 106, and a conductive layer 104. The layers included in the transistor 100 may each have a single-layer structure or a stacked-layer structure.

The conductive layer 112a is provided over a substrate 102. The conductive layer 112a functions as one of a source electrode and a drain electrode of the transistor 100.

An insulating layer 110 is provided over the conductive layer 112a. The insulating layer 110 is provided to cover the top surface and a side surface of the conductive layer 112a. An insulating layer 120 is provided over the insulating layer 110.

The insulating layer 110 preferably has a stacked-layer structure. FIG. 1B and the like illustrate a structure in which the insulating layer 110 has a stacked-layer structure of an insulating layer 110a, an insulating layer 110b over the insulating layer 110a, and an insulating layer 110c over the insulating layer 110b.

The insulating layer 110a is positioned over the conductive layer 112a. The insulating layer 110a is provided to cover the top surface and the side surface of the conductive layer 112a.

The insulating layer 110b is provided over the insulating layer 110a, and the insulating layer 110c is provided over the insulating layer 110b. Furthermore, the insulating layer 120 is provided over the insulating layer 110c. An opening 141 reaching the conductive layer 112a is provided in the insulating layer 110 and the insulating layer 120.

The conductive layer 112b is positioned over the insulating layer 120. An opening 143 overlapping with the opening 141 is provided in the conductive layer 112b. In FIG. 3B, the opening 141 is denoted by a dashed line. The conductive layer 112b functions as the other of the source electrode and the drain electrode of the transistor 100. The conductive layer 112b includes a region overlapping with the conductive layer 112a with the insulating layer 110 and the insulating layer 120 therebetween. The insulating layer 110 and the insulating layer 120 are sandwiched between the conductive layer 112a and the conductive layer 112b.

There is no particular limitation on the top-view shapes of the opening 141 and the opening 143. The shapes of the opening 141 and the opening 143 can each be a circle, an ellipse, a polygon such as a triangle, a quadrangle (including a rectangle, a rhombus, and a square), a pentagon, or any of these polygons whose corners are rounded, for example. Note that the polygon may be a concave polygon (a polygon at least one of the interior angles of which is greater than) 180° or a convex polygon (a polygon all the interior angles of which are less than or equal to) 180°. The top-view shapes of the opening 141 and the opening 143 are preferably circular as illustrated in FIG. 1A and the like. When the top-view shapes of the openings are circular, processing accuracy at the time of formation of the openings can be high, whereby the openings can be formed to have minute sizes. Note that in this specification and the like, a circular shape is not necessarily a perfect circular shape.

In this specification and the like, a top-view shape refers to a shape in a plan view. For example, the top-view shape of the opening 141 refers to the shape of an end portion of the top surface of the insulating layer sandwiched between the conductive layer 112a and the conductive layer 112b on the opening 141 side. For example, in the structure illustrated in FIG. 1B and the like, the top-view shape of the opening 141 refers to the shape of an end portion of the top surface of the insulating layer 120 on the opening 141 side. The top-view shape of the opening 143 refers to the shape of an end portion of the bottom surface of the conductive layer 112b on the opening 143 side.

As illustrated in FIG. 1A, the top-view shape of the opening 141 and the top-view shape of the opening 143 can be the same or substantially the same. In that case, it is preferable that the end portion of the bottom surface of the conductive layer 112b on the opening 143 side be aligned or substantially aligned with the end portion of the top surface of the insulating layer 120 on the opening 141 side as illustrated in FIG. 1B, FIG. 1C, and FIG. 5. The bottom surface of the conductive layer 112b refers to the surface thereof on the insulating layer 120 side. The top surface of the insulating layer 120 refers to the surface thereof on the conductive layer 112b side.

Note that the opening 141 and the opening 143 do not necessarily have the same top-view shape. In the case where the top-view shapes of the opening 141 and the opening 143 are circular, the opening 141 and the opening 143 may be concentrically arranged, but not necessarily concentrically arranged.

The semiconductor layer 108 is in contact with the top surface of the conductive layer 112a, a side surface of the insulating layer 110, a side surface of the insulating layer 120, and the top surface and a side surface of the conductive layer 112b. The semiconductor layer 108 is provided to cover the opening 141 and the opening 143. The semiconductor layer 108 is provided in contact with the side surfaces of the insulating layer 110 and the insulating layer 120 on the opening 141 side and an end portion of the conductive layer 112b on the opening 143 side (which can also be referred to as part of the top surface of the conductive layer 112b and the side surface of the conductive layer 112b on the opening 143 side). The semiconductor layer 108 is in contact with the conductive layer 112a in the opening 141.

Although an end portion of the semiconductor layer 108 is in contact with the top surface of the conductive layer 112b in the example illustrated in FIG. 1B and the like, the present invention is not limited to this example. The semiconductor layer 108 may cover an end portion of the conductive layer 112b, and the end portion of the semiconductor layer 108 may be in contact with the top surface of the insulating layer 120.

The insulating layer 106 is positioned over the semiconductor layer 108 and the conductive layer 112b. The insulating layer 106 is provided to cover the opening 141 and the opening 143 with the semiconductor layer 108 therebetween. Part of the insulating layer 106 functions as the gate insulating layer of the transistor 100.

The conductive layer 104 is positioned over the insulating layer 106. The conductive layer 104 overlaps with the semiconductor layer 108 with the insulating layer 106 therebetween. The conductive layer 104 functions as a gate electrode of the transistor.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, the drain current can also be regarded as flowing in a vertical direction or a substantially vertical direction. Accordingly, the transistor 100 can be referred to as a vertical-channel transistor or a VFET (Vertical Field Effect Transistor).

The channel length of the transistor 100 can be controlled by the thicknesses of the insulating layers (here, the insulating layer 110 and the insulating layer 120) provided between the conductive layer 112a and the conductive layer 112b. Accordingly, the transistor can be fabricated with high accuracy to have a channel length smaller than the resolution limit of a light-exposure apparatus used for fabrication of the transistor. Furthermore, variations in characteristics among a plurality of the transistors 100 are also reduced. Accordingly, the semiconductor device including the transistor 100 can operate stably and have higher reliability. When the variations in characteristics are reduced, the circuit design flexibility is increased and the operation voltage of the semiconductor device can be reduced. Thus, the power consumption of the semiconductor device can be reduced.

In the transistor 100, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape.

The conductive layer 112a, the conductive layer 112b, and the conductive layer 104 can each function as a wiring, and the transistor 100 can be provided in a region where these wirings overlap with each other. That is, the area occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel.

Although the semiconductor layer 108, the insulating layer 106, and the conductive layer 104 cover the opening 141 and the opening 143 in the example illustrated in FIG. 1B and the like, one embodiment of the present invention is not limited thereto. A step may be formed between the conductive layer 112a and each of the insulating layer 110, the insulating layer 120, and the conductive layer 112b, and the semiconductor layer 108, the insulating layer 106, and the conductive layer 104 may be provided along the step.

The transistor 200 includes a semiconductor layer 208, an insulating layer 105, the insulating layer 106, and a conductive layer 204. The transistor 200 may further include a conductive layer 202. The conductive layer 202 includes a region overlapping with the semiconductor layer 208 with the insulating layer 110 and the insulating layer 120 therebetween. The layers constituting the transistor 200 may each have a single-layer structure or a stacked-layer structure.

The conductive layer 202 is provided over the substrate 102. The conductive layer 202 functions as a back gate electrode of the transistor 200. The conductive layer 202 can be formed using the same material as the conductive layer 112a. The conductive layer 202 can be formed through the same process as the conductive layer 112a. For example, the conductive layer 112a and the conductive layer 202 can be formed by forming and processing a conductive film to be the conductive layer 112a and the conductive layer 202.

The insulating layer 110 is provided over the conductive layer 202, and the insulating layer 120 is provided over the insulating layer 110. Part of the insulating layer 110 and part of the insulating layer 120 function as a back gate insulating layer of the transistor 200. Note that the conductive layer 202 is not necessarily provided.

The semiconductor layer 208 is provided over the insulating layer 120. The semiconductor layer 208 includes a region overlapping with the conductive layer 202 with the insulating layer 110 and the insulating layer 120 therebetween. The semiconductor layer 208 can be formed through a process different from that for the semiconductor layer 108. The semiconductor layer 208 can be formed using a material different from that for the semiconductor layer 108. The materials used for the semiconductor layer 108 and the semiconductor layer 208 can be selected in accordance with the electrical characteristics and reliability required for the transistor 100 and the transistor 200. Note that the semiconductor layer 208 may be formed using the same material as the semiconductor layer 108.

The insulating layer 105 is provided over the semiconductor layer 208, and the insulating layer 106 is provided over the insulating layer 105. Part of the insulating layer 105 and part of the insulating layer 106 function as the gate insulating layer of the transistor 200. The insulating layer 105 and the insulating layer 106 have an opening 147a and an opening 147b each reaching the semiconductor layer 208.

As illustrated in FIG. 1B and the like, the gate insulating layer of the transistor 200 has a stacked-layer structure of the insulating layer 105 and the insulating layer 106. Meanwhile, the gate insulating layer of the transistor 100 has a single-layer structure of the insulating layer 106. With such a structure, the thickness of the gate insulating layer can be different between the transistor 100 and the transistor 200. Specifically, the thickness of the gate insulating layer of the transistor 200 can be larger than that of the gate insulating layer of the transistor 100.

The conductive layer 204, a conductive layer 212a, and a conductive layer 212b are provided over the insulating layer 106. The conductive layer 204, the conductive layer 212a, and the conductive layer 212b can be formed using the same material as the conductive layer 104. The conductive layer 204, the conductive layer 212a, and the conductive layer 212b can be formed in the same process as the conductive layer 104. For example, the conductive layer 104, the conductive layer 204, the conductive layer 212a, and the conductive layer 212b can be formed by forming and processing a conductive film to be the conductive layer 104, the conductive layer 204, the conductive layer 212a, and the conductive layer 212b.

The conductive layer 204 includes a region overlapping with the semiconductor layer 208 with the insulating layer 105 and the insulating layer 106 therebetween and functions as a gate electrode of the transistor 200. An end portion of the conductive layer 204 is positioned inward from an end portion of the insulating layer 106. In other words, the end portion of the conductive layer 204 is in contact with the top surface of the insulating layer 106. In other words, the insulating layer 105 and the insulating layer 106 each include a portion extending outward from the end portion of the conductive layer 204 at least over the semiconductor layer 208.

The conductive layer 212a and the conductive layer 212b are provided to cover part of the opening 147a and part of the opening 147b, respectively, and are in contact with the semiconductor layer 208 in the opening 147a and the opening 147b, respectively. The conductive layer 212a functions as one of a source electrode and a drain electrode of the transistor 200, and the conductive layer 212b functions as the other.

In the semiconductor layer 208 between the source electrode and the drain electrode, the whole region overlapping with the gate electrode with the gate insulating layer therebetween functions as a channel formation region. The semiconductor layer 208 includes a pair of regions 208L between which the channel formation region is sandwiched and a pair of regions 208D outside the pair of regions 208L.

The region 208D can also be referred to as a region having a higher carrier concentration or a lower resistance than the channel formation region, or an n-type region. In the semiconductor layer 208, the region in contact with the conductive layer 212a and the region 208D adjacent to the region serve as one of a source region and a drain region. In the semiconductor layer 208, the region in contact with the conductive layer 212b and the region 208D adjacent to the region serve as the other of the source region and the drain region.

The region 208L can be referred to as a region whose resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. The region 208L can also be referred to as a region whose resistance is substantially equal to or higher than that of the region 208D, a region whose carrier concentration is substantially equal to or lower than that of the region 208D, a region whose oxygen vacancy density is substantially equal to or lower than that of the region 208D, or a region whose impurity concentration is substantially equal to or lower than that of the region 208D.

The region 208L functions as a buffer region for relieving a drain electric field. The region 208L is a region not overlapping with the conductive layer 204 and thus is a region where a channel is hardly formed by application of a gate voltage to the conductive layer 204. The region 208L preferably has a higher carrier concentration than the channel formation region. Thus, the region 208L can function as an LDD (Lightly Doped Drain) region. The region 208L serving as the LDD region is provided between the channel formation region and the region 208D, whereby the transistor 200 can have a high drain breakdown voltage.

The carrier concentration in the semiconductor layer 208 preferably has a distribution such that the concentration is lowest in the channel formation region and increases in the order of the region 208L and the region 208D. Providing the region 208L between the channel formation region and the region 208D can keep the carrier concentration of the channel formation region extremely low even when an impurity such as hydrogen diffuses from the region 208D during the manufacturing process, for example.

Note that the carrier concentration in the region 208L is not necessarily uniform and sometimes has a gradient such that the carrier concentration decreases from the region 208D side toward the channel formation region. For example, one or both of the hydrogen concentration and the oxygen vacancy concentration in the region 208L may have a gradient such that the concentration decreases from the region 208D side to the channel formation region side.

The regions 208L and the regions 208D can be formed by adding an impurity element to the semiconductor layer 208 using the conductive layer 204, the conductive layer 212a, and the conductive layer 212b as masks after formation of these conductive layers, for example. The regions 208L are each a region of the semiconductor layer 208 that overlaps with the insulating layer 105 and the insulating layer 106 and does not overlap with the conductive layer 204. The regions 208D are each a region of the semiconductor layer 208 that overlaps none of the insulating layer 105, the insulating layer 106, and the conductive layer 204.

An end portion of part of the conductive layer 212a and an end portion of part of the conductive layer 212b are preferably positioned inside the opening 147a and the opening 147b, respectively, as illustrated in FIG. 1B and FIG. 1C. In other words, the end portion of the part of the conductive layer 212a and the end portion of the part of the conductive layer 212b are preferably in contact with the semiconductor layer 208 in the opening 147a and the opening 147b, respectively. In that case, the region in contact with the conductive layer 212a can be adjacent to one of the pair of regions 208D, and the region in contact with the conductive layer 212b can be adjacent to the other of the pair of regions 208D.

There is no particular limitation on the top-view shapes of the opening 147a and the opening 147b. The top-view shapes of the opening 147a and the opening 147b can be any of the shapes that can be used for the opening 141 and the opening 143. Although the top-view shapes of the opening 147a and the opening 147b are different from the top-view shapes of the opening 141 and the opening 143 in the structure illustrated in FIG. 1A and the like, one embodiment of the present invention is not limited thereto. The top-view shapes of the opening 147a and the opening 147b may be the same as those of the opening 141 and the opening 143.

The regions 208L and the regions 208D each include the impurity element. As the impurity element, one or more of hydrogen, boron, carbon, nitrogen, fluorine, phosphorus, sulfur, arsenic, aluminum, magnesium, silicon, and a noble gas can be used. Note that typical examples of a noble gas include helium, neon, argon, krypton, and xenon. It is particularly preferable to use one or more of boron, phosphorus, aluminum, magnesium, and silicon as the impurity element.

When the regions 208L and the regions 208D are formed by adding the impurity element to the semiconductor layer 208, the impurity element may be supplied to the semiconductor layer 108 through the insulating layer 106 with the use of the conductive layer 104 as a mask. In that case, a region 108L is formed in the region of the semiconductor layer 108 that does not overlap with the conductive layer 104. Note that in the transistor 100, the region of the semiconductor layer 108 that is in contact with the conductive layer 112b serves as a source region or a drain region. The region 108L is formed in part of the source region or the drain region. Note that the concentration of the impurity element in the region 108L may be different from that in the region 208L. The region 108L is not necessarily formed. For example, in the case where the conductive layer 104 extends to cover the end portion of the semiconductor layer 108, the conductive layer 104 masks the whole semiconductor layer 108 to preclude the supply of the impurity element to the semiconductor layer 108, and the region 108L is not formed.

As illustrated in FIG. 1C, the conductive layer 204 may be electrically connected to the conductive layer 202 through an opening 149 provided in the insulating layer 106, the insulating layer 120, and the insulating layer 110. In that case, the conductive layer 204 and the conductive layer 202 can be supplied with the same potential. When the conductive layer 204 and the conductive layer 202 are supplied with the same potential, the amount of current that can flow in the transistor 200 in an on state can be increased.

There is no particular limitation on the top-view shape of the opening 149. The top-view shape of the opening 149 can be any of the shapes that can be used for the opening 141 and the opening 143. The top-view shape of the opening 149 may be the same as the top-view shape of one or more of the opening 141, the opening 143, the opening 147a, and the opening 147b or may be different from the top-view shapes of all of these openings.

As illustrated in FIG. 1A and FIG. 1C, the conductive layer 204 and the conductive layer 202 preferably extend outward from an end portion of the semiconductor layer 208 in the channel width direction of the transistor 200. In that case, as shown in FIG. 1C, the whole of the semiconductor layer 208 in the channel width direction is covered with the conductive layer 204 with the insulating layer 105 and the insulating layer 106 therebetween and also covered with the conductive layer 202 with the insulating layer 110 and the insulating layer 120 therebetween. In such a structure, the semiconductor layer 208 can be electrically surrounded by electric fields generated by a pair of gate electrodes. Here, it is particularly preferable that the same potential be supplied to the conductive layer 204 and the conductive layer 202. In that case, electric fields for inducing a channel can be effectively applied to the semiconductor layer 208, whereby the on-state current of the transistor 200 can be increased. Thus, the transistor 200 can also be miniaturized.

Note that a structure where the conductive layer 204 and the conductive layer 202 are not connected to each other may be employed. In that case, a constant potential may be applied to one of the pair of gate electrodes, and a signal for driving the transistor 200 may be applied to the other of the pair of gate electrodes. Here, the potential applied to one of the gate electrodes can control the threshold voltage at the time of driving the transistor 200 with the other gate electrode.

The conductive layer 202 may be electrically connected to the conductive layer 212a or the conductive layer 212b. In that case, the conductive layer 212a or the conductive layer 212b and the conductive layer 202 are electrically connected to each other through an opening provided in the insulating layer 106, the insulating layer 120, and the insulating layer 110.

The transistor 200 is a planar transistor in which the semiconductor layer 208 is provided in a planar shape. The transistor 200 is what is called a top-gate transistor including the gate electrode above the semiconductor layer 208. For example, when an impurity element is added to the semiconductor layer 208 with the conductive layer 204, which serves as the gate electrode, used as a mask, the regions 208D serving as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 has a value larger than or equal to that of the resolution limit of a light-exposure apparatus used for fabrication of the transistor. That is, the channel length of the transistor 200 can be longer than that of the transistor 100. The transistor with a long channel length can have favorable saturation.

In this specification and the like, the state where the change in current is small in the saturation region of the I_{d}-V_{d} characteristics of a transistor is sometimes described using the expression “favorable saturation”.

The transistor 100 with a short channel length and the transistor 200 with a long channel length can be formed over the same substrate by the formation steps some of which are shared. For example, when the transistor 100 is used as the transistor required to have a high on-state current and the transistor 200 is used as the transistor required to have favorable saturation, the semiconductor device can achieve high performance.

As described above, the thickness of the gate insulating layer of the transistor 200 can be larger than that of the gate insulating layer of the transistor 100. A larger thickness of the gate insulating layer leads to a higher gate breakdown voltage of the transistor. On the other hand, a smaller thickness of the gate insulating layer leads to a higher on-state current and a higher operation speed of the transistor. In other words, the transistor 200 with a high gate breakdown voltage and the transistor 100 with a high on-state current and a high operation speed can be formed over the same substrate. For example, when the transistor 200 is used as a transistor to which a high voltage is applied and the transistor 100 is used as a transistor required to operate at a high speed, the semiconductor device can achieve both high-speed operation and high reliability.

Furthermore, the material used for the semiconductor layer 108 and the material used for the semiconductor layer 208 can be different from each other. Not only the structure of the transistor and the thickness of the gate insulating layer but also the material used for the semiconductor layer can be selected as appropriate in accordance with the electrical characteristics and reliability required for the transistor.

An insulating layer 195 is provided to cover the transistor 100 and the transistor 200. The insulating layer 195 functions as a protective layer protecting the transistor 100 and the transistor 200.

Next, components of the transistor 100 and the transistor 200 are described in detail.

First, the structure of the transistor 100 is described in detail with reference to FIG. 5A and FIG. 5B. FIG. 5A is an enlarged view of the transistor 100 illustrated in FIG. 1A, and FIG. 5B is an enlarged view of the transistor 100 illustrated in FIG. 1B.

In the semiconductor layer 108, the region in contact with the conductive layer 112a functions as one of the source region and the drain region, the region in contact with the conductive layer 112b functions as the other of the source region and the drain region, and the region between the source region and the drain region functions as a channel formation region.

The channel length of the transistor 100 is the distance between the source region and the drain region. In FIG. 5B, a channel length L100 of the transistor 100 is indicated by a dashed double-headed arrow. It can be said that in a cross-sectional view, the channel length L100 is the shortest distance between the region of the semiconductor layer 108 that is in contact with the conductive layer 112a and the region of the semiconductor layer 108 that is in contact with the conductive layer 112b.

In a cross-sectional view, the channel length L100 of the transistor 100 corresponds to the lengths of the side surfaces of the insulating layers sandwiched between the conductive layer 112a and the conductive layer 112b on the opening 141 side. That is, the channel length L100 depends on a thickness Tins of the insulating layers sandwiched between the conductive layer 112a and the conductive layer 112b (here, the sum of the thicknesses of the insulating layer 110 and the insulating layer 120) and an angle θins formed by the side surfaces of these insulating layers on the opening 141 side and the formation surface (here, the top surface of the conductive layer 112a). Thus, the channel length L100 can have a value smaller than that of the resolution limit of a light-exposure apparatus, for example, which enables a transistor having a minute size. Specifically, it is possible to obtain a transistor with an extremely short channel length that could not be achieved with a conventional light-exposure apparatus for mass production of flat panel displays (the minimum line width: approximately 2 μm or approximately 1.5 μm, for example). Moreover, it is also possible to obtain a transistor with a channel length less than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be fabricated. Furthermore, the area occupied by the circuit can be reduced. Therefore, a small semiconductor device can be obtained. The application of the semiconductor device of one embodiment of the present invention to a large display device or a high-resolution display device can reduce signal delay in wirings and reduce display unevenness even if the number of wirings is increased, for example. In addition, since the area occupied by the circuit can be reduced, the bezel of the display device can be narrowed.

By adjusting the thickness Tins and the angle θins, the channel length L100 can be controlled. Note that in FIG. 5B, the thickness Tins is indicated by a dashed-dotted double-headed arrow.

The thickness Tins can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3.0 μm, less than or equal to 2.5 μm, less than or equal to 2.0 μm, less than or equal to 1.5 μm, less than or equal to 1.2 μm, or less than or equal to 1.0 μm.

The side surfaces of the insulating layer 110 and the insulating layer 120 on the opening 141 side preferably have tapered shapes. The angle θins formed by the side surfaces of the insulating layer 110 and the insulating layer 120 on the opening 141 side and the formation surface of the insulating layer 110 (here, the top surface of the conductive layer 112a) is preferably less than 90°. By reducing the angle θins, the coverage with a layer (e.g., the semiconductor layer 108) provided over these insulating layers can be improved. The smaller the angle θins is, the larger the channel length L100 is. The larger the angle θins is, the smaller the channel length L100 is.

The angle θins can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than 90°, less than or equal to 85°, or less than or equal to 80°. The angle θins may be less than or equal to 75°, less than or equal to 70°, less than or equal to 65°, or less than or equal to 60°.

Although the side surfaces of the insulating layer 110 and the insulating layer 120 on the opening 141 side are linear in the cross-sectional view shown in FIG. 5B or the like, one embodiment of the present invention is not limited thereto. In the cross-sectional view, the side surfaces of the insulating layer 110 and the insulating layer 120 on the opening 141 side may be curved, or the side surfaces may include both a linear region and a curved region.

In FIG. 5A and FIG. 5B, a width D143 of the opening 143 is indicated by a dashed double-dotted double-headed arrow. In the example illustrated in FIG. 5A, the top-view shape of each of the opening 141 and the opening 143 is a circle. In this case, the width D143 corresponds to the diameter of the circle, and a channel width W100 of the transistor 100 is the length of the circumference of the circle. That is, the channel width W100 is π×D143. Accordingly, in the case where the opening 141 and the opening 143 have circular top-view shapes, the channel width W100 of the transistor can be smaller than in the case where the opening 141 and the opening 143 have any other shape.

Note that the opening 141 and the opening 143 sometimes have different diameters. The inner diameter of each of the opening 141 and the opening 143 sometimes varies in the depth direction. As the diameter of the opening, for example, the average value of the following three diameters can be used: the diameter at the highest level of the insulating layer 110 and the insulating layer 120 in a cross-sectional view, the diameter at the lowest level of the insulating layer 110 and the insulating layer 120 in the cross-sectional view, and the diameter at the midpoint between these levels. For another example, any of the diameter at the highest level of the insulating layer 110 and the insulating layer 120 in a cross-sectional view, the diameter at the lowest level of the insulating layer 110 and the insulating layer 120 in the cross-sectional view, and the diameter at the midpoint between these levels can be used as the diameter of the opening.

In the case where the opening 143 is formed by a photolithography method, the width D143 of the opening 143 is larger than or equal to the resolution limit of a light-exposure apparatus. The width D143 can be, for example, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

Next, the thickness of the gate insulating layer of the transistor 100 is described with reference to FIG. 5B. The insulating layer 106 sandwiched between the conductive layer 104 that functions as the gate electrode and the semiconductor layer 108 functions as the gate insulating layer. A thickness T100 of the gate insulating layer is the shortest distance between the conductive layer 104 and the semiconductor layer 108 in a cross-sectional view. Since the insulating layer 106 is provided to cover the opening 141 and the opening 143 with the semiconductor layer 108 therebetween, the thickness T100 of the gate insulating layer sometimes varies depending on the angle θins and the formation method of the insulating layer 106. The angle θins and the formation conditions of the insulating layer 106 are preferably adjusted to achieve the desired thickness T100.

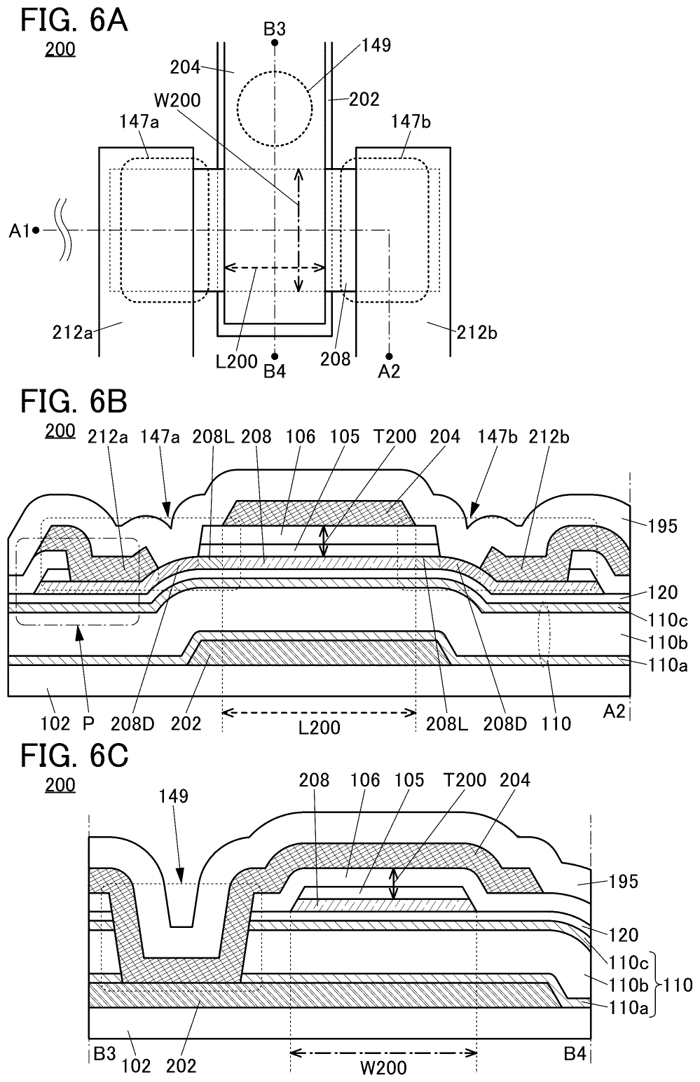

Next, the structure of the transistor 200 is described in detail with reference to FIG. 6A to FIG. 6C. FIG. 6A is a top view of the transistor 200, FIG. 6B is an enlarged view of the transistor 200 illustrated in FIG. 1B, and FIG. 6C is an enlarged view of the transistor 200 illustrated in FIG. 1C.

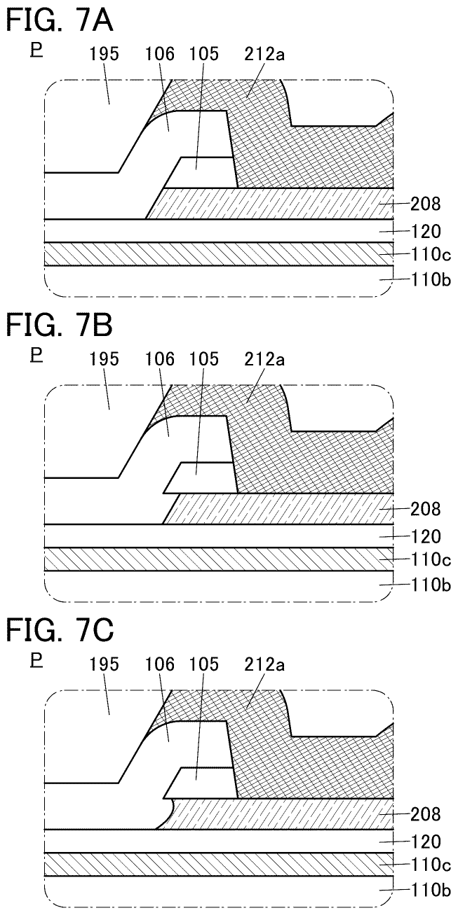

FIG. 7A shows an enlarged view of a region P indicated by the dashed-dotted line in FIG. 6B. An end portion of the semiconductor layer 208 is aligned or substantially aligned with an end portion of the insulating layer 105. The end portion of the semiconductor layer 208 and the end portion of the insulating layer 105 can be aligned or substantially aligned with each other in the following manner, for example: a semiconductor film to be the semiconductor layer 208, an insulating film to be the insulating layer 105 over the semiconductor film, and a resist mask over the insulating film are formed, and the insulating film and the semiconductor film are processed using the resist mask. With such a structure, the process can be simplified.

The expression “end portions are aligned or substantially aligned with each other” can be replaced with the expression “end portions match or substantially match each other”. In the case where end portions are aligned or substantially aligned with each other, it can be said that at least parts of the outlines of stacked layers overlap with each other in a plan view. For example, the case of processing the upper layer and the lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match each other”.

As illustrated in FIG. 7B, the end portion of the semiconductor layer 208 is not necessarily aligned with the end portion of the insulating layer 105. For example, in the case where a dry etching method is used to form the insulating layer 105 and a wet etching method is used to form the semiconductor layer 208, the end portion of the semiconductor layer 208 is positioned inward from the end portion of the insulating layer 105 in some cases. Alternatively, the end portion of the semiconductor layer 208 may be positioned outward from the end portion of the insulating layer 105. Note that a side surface of the semiconductor layer 208 is not necessarily linear in a cross-sectional view. As illustrated in FIG. 7C, the side surface of the semiconductor layer 208 may be curved.

In the semiconductor layer 208, the pair of regions 208D function as the source region and the drain region, and the region between the source region and the drain region functions as the channel formation region. The channel formation region includes a region overlapping with the conductive layer 204 with the insulating layer 106 therebetween.

The channel length of the transistor 200 is the length of the region between the pair of regions 208D where the semiconductor layer 208 and the conductive layer 204 overlap with each other. In FIG. 6A and FIG. 6B, a channel length L200 of the transistor 200 is indicated by a dashed double-headed arrow. The channel length L200 of the transistor 200 depends on the length of the conductive layer 204 and has a value larger than or equal to that of the resolution limit of the light-exposure apparatus used for fabrication of the transistor. For example, the channel length L200 can be greater than or equal to 1.5 μm. The transistor with a long channel length can have favorable saturation.

The channel width of the transistor 200 is the width of the region where the semiconductor layer 208 and the conductive layer 204 overlap with each other in the direction orthogonal to the channel length direction. In FIG. 6A and FIG. 6C, a channel width W200 of the transistor 200 is indicated by a dashed-dotted double-headed arrow.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, when the transistor 100 is used as the transistor required to have a high on-state current and the transistor 200 is used as the transistor required to have favorable saturation, the semiconductor device 10 can achieve high performance by utilizing the advantages of the transistors.

Next, the thickness of the gate insulating layer of the transistor 200 is described with reference to FIG. 6B and FIG. 6C. The insulating layer 105 and the insulating layer 106 sandwiched between the conductive layer 204 that functions as the gate electrode and the semiconductor layer 208 function as the gate insulating layer. A thickness T200 of the gate insulating layer is the shortest distance between the conductive layer 204 and the semiconductor layer 208 in a cross-sectional view. In FIG. 6B and FIG. 6C, the thickness T200 of the gate insulating layer is indicated by a solid double-headed arrow.

In the semiconductor device 10 of one embodiment of the present invention, the transistor 100 and the transistor 200 having different structures can be formed over the substrate 102 by the formation steps some of which are shared. In other words, some steps can be shared in forming the transistor 100 and the transistor 200 that differ in the channel length and the thickness of the gate insulating layer. Specifically, the conductive layer 112a and the conductive layer 202 can be formed in the same process. One part of the insulating layer 106 serves as the gate insulating layer of the transistor 100 and another part of the insulating layer 106 serves as the gate insulating layer of the transistor 200. The conductive layer 104, the conductive layer 204, the conductive layer 212a, and the conductive layer 212b can be formed in the same process. This allows higher productivity and lower manufacturing cost of the semiconductor device 10.

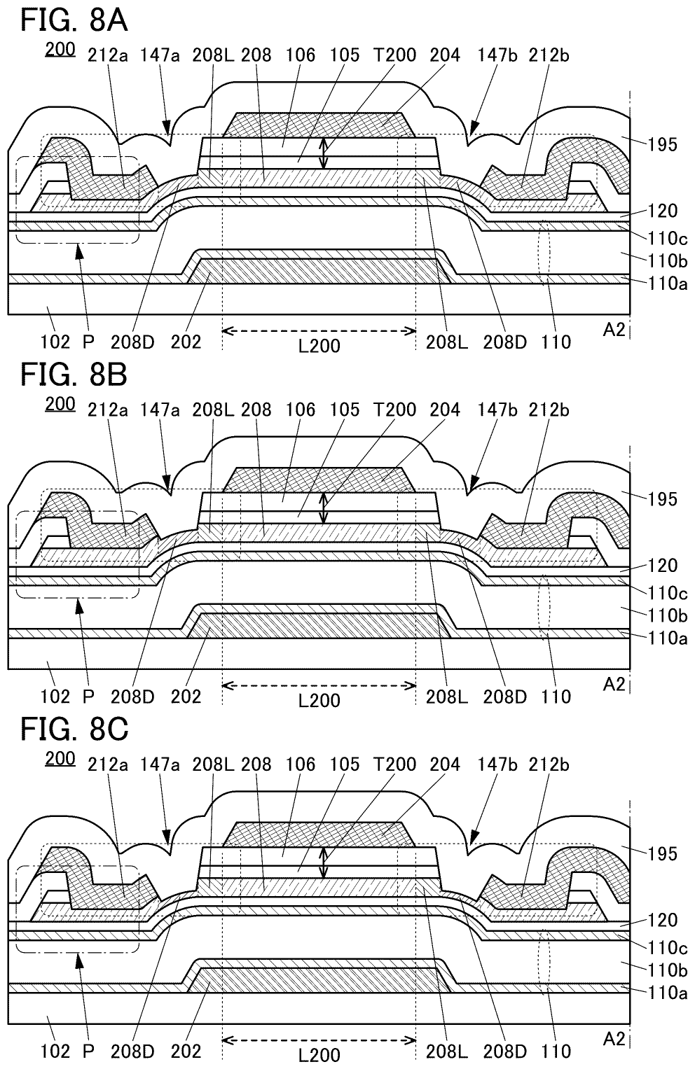

Although the thickness of the semiconductor layer 208 is uniform without varying from place to place in the example shown in FIG. 6B or the like, one embodiment of the present invention is not limited to this example. As illustrated in FIG. 8A, the thickness of the semiconductor layer 208 in a region overlapping with the insulating layer 106 and the insulating layer 105 may be different from the thickness of the semiconductor layer 208 in a region not overlapping with the insulating layer 106 or the insulating layer 105. For example, at the time of forming the opening 147a and the opening 147b, the semiconductor layer 208 is sometimes partly removed to have a smaller thickness in the region not overlapping with the insulating layer 106 or the insulating layer 105 than in the region overlapping with the insulating layer 106 and the insulating layer 105. Alternatively, as illustrated in FIG. 8B, the thickness of the semiconductor layer 208 in a region overlapping with any of the insulating layer 106, the insulating layer 105, the conductive layer 212a, and the conductive layer 212b may be different from the thickness of the semiconductor layer 208 in a region overlapping with none of them. For example, at the time of forming the conductive layer 212a and the conductive layer 212b, the semiconductor layer 208 is sometimes partly removed to have a smaller thickness in the region overlapping with none of the insulating layer 106, the insulating layer 105, the conductive layer 212a, and the conductive layer 212b than in the region overlapping with any of them. Alternatively, as illustrated in FIG. 8C, the thickness of the semiconductor layer 208 in the region overlapping with the insulating layer 106 and the insulating layer 105, the thickness of the semiconductor layer 208 in the region overlapping with any of the insulating layer 106, the insulating layer 105, the conductive layer 212a, and the conductive layer 212b, and the thickness of the semiconductor layer 208 in the region overlapping with none of them may be different from one another.

Components included in the semiconductor device of this embodiment will be described below.

### [Semiconductor Layer 108 and Semiconductor Layer 208]

A semiconductor material used for each of the semiconductor layer 108 and the semiconductor layer 208 is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may contain an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

Each of the semiconductor layer 108 and the semiconductor layer 208 preferably includes a metal oxide exhibiting semiconductor characteristics (also referred to as an oxide semiconductor).

The band gap of the metal oxide used for the semiconductor layer 108 and the band gap of the metal oxide used for the semiconductor layer 208 are each preferably greater than or equal to 2.0 eV, further preferably greater than or equal to 2.5 eV.

Examples of the metal oxide that can be used for the semiconductor layer 108 and the semiconductor layer 208 include indium oxide, gallium oxide, and zinc oxide. The metal oxide preferably contains at least indium or zinc. The metal oxide preferably contains two or three selected from indium, an element M, and zinc. The element M is a metal element or metalloid element that has a high binding energy with oxygen, such as a metal element or metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, for each of the semiconductor layer 108 and the semiconductor layer 208, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga-A1 oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased. In addition, the transistor can have a high on-state current.

Note that the metal oxide may contain, instead of or in addition to indium, one or more of metal elements with large period numbers in the periodic table of the elements. The larger the overlap between orbits of metal elements is, the more likely it is that the metal oxide will have high carrier conductivity. Thus, a transistor containing a metal element with a larger period number in the periodic table can have higher field-effect mobility in some cases. Examples of the metal element with a larger period number in the periodic table include metal elements belonging to Period 5 and metal elements belonging to Period 6. Specific examples of the metal elements include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more selected from non-metallic elements. By containing a non-metallic element, the metal oxide sometimes has an increased carrier concentration, a reduced band gap, or the like, in which case the transistor can have increased field-effect mobility. Examples of the non-metallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Thus, a change in electrical characteristics of the transistor can be inhibited and the reliability of the transistor can be improved.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited and the reliability of the transistor can be improved.

The compositions of the metal oxides used for the semiconductor layer 108 and the semiconductor layer 208 affect the electrical characteristics and reliability of the transistors. Therefore, when the compositions of the metal oxides are varied in accordance with the electrical characteristics and reliability required for the transistors, the semiconductor device can have both good electrical characteristics and high reliability.

As an analysis method of the composition of a metal oxide, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage, the content percentage of the element M may be difficult to quantitate, or the element M is not detected in some cases.

When a metal oxide is an In-M-Zn oxide, the proportion of the number of In atoms is preferably higher than or equal to that of the number of element M atoms in the In-M-Zn oxide. Examples of the atomic ratio of the metal elements of such an In-M-Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the neighborhood of any of the above atomic ratios. Note that a composition in the neighborhood includes the range of ±30% of an intended atomic ratio. By increasing the proportion of the number of indium atoms in the metal oxide, the on-state current, field-effect mobility, or the like of the transistor can be improved.

The proportion of the number of In atoms may be lower than that of the number of element M atoms in the In-M-Zn oxide. Examples of the atomic ratio of the metal elements of such an In-M-Zn oxide include In:M:Zn=1:3:2, In:M:Zn=1:3:3, and In:M:Zn=1:3:4 and a composition in the neighborhood of any of these atomic ratios. By increasing the proportion of the number of element M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

A sputtering method or an atomic layer deposition (ALD) method can be suitably used for forming the metal oxide. Note that in the case where the metal oxide is formed by a sputtering method, the composition of the formed metal oxide film may be different from the composition of a target. In particular, the zinc content percentage of the formed metal oxide film may be reduced to approximately 50% of that of the target.

The semiconductor layer 108 and the semiconductor layer 208 may each have a stacked-layer structure including two or more metal oxide layers. The two or more metal oxide layers included in each of the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in each of the semiconductor layer 108 and the semiconductor layer 208 may have different compositions. For example, a stacked-layer structure of a first metal oxide layer with a composition of In:M:Zn=1:3:4 [atomic ratio] or in the neighborhood thereof and a second metal oxide layer with a composition of In:M:Zn=1:1:1 [atomic ratio] or in the neighborhood thereof provided over the first metal oxide layer can be suitably employed. In particular, gallium, aluminum, or tin is preferably used as the element M. A stacked-layer structure of any one selected from indium oxide, indium gallium oxide, and IGZO and any one selected from IAZO, IAGZO, and ITZO (registered trademark) may be employed, for example.

The semiconductor layer 108 and the semiconductor layer 208 each preferably include a metal oxide layer having crystallinity. Examples of the structure of a metal oxide having crystallinity include a CAAC (c-axis aligned crystal) structure, a polycrystalline structure, and a nano-crystal (nc) structure. With the use of a metal oxide layer having crystallinity as the semiconductor layer 108, the density of defect states in the semiconductor layer 108 can be reduced, which enables the semiconductor device to have high reliability.

The higher the crystallinity of the metal oxide layer used as each of the semiconductor layer 108 and the semiconductor layer 208 is, the lower the density of defect states in the semiconductor layer 108 can be. By contrast, the use of a metal oxide layer having low crystallinity enables the transistor to flow a large amount of current.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas to the total flow rate of the film formation gas used in the formation (also referred to as an oxygen flow rate ratio) or the oxygen partial pressure in a treatment chamber is, the higher the crystallinity of the formed metal oxide layer can be.

The semiconductor layer 108 and the semiconductor layer 208 may each have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of each of the semiconductor layer 108 and the semiconductor layer 208 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. Note that the thickness of the semiconductor layer 108 may be the same as or different from the thickness of the semiconductor layer 208.

In the case where an oxide semiconductor is used for each of the semiconductor layer 108 and the semiconductor layer 208, hydrogen contained in the oxide semiconductor reacts with oxygen bonded to a metal atom to be water, and thus sometimes forms oxygen vacancies (V_{O}) in the oxide semiconductor. In some cases, a defect where hydrogen enters an oxygen vacancy (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of a transistor.

In the case where an oxide semiconductor is used for each of the semiconductor layer 108 and the semiconductor layer 208, the amount of V_{O}H in the semiconductor layer 108 and the semiconductor layer 208 is preferably reduced as much as possible so that each of the semiconductor layer 108 and the semiconductor layer 208 becomes a highly purified intrinsic or substantially highly purified intrinsic semiconductor layer. In order to obtain such an oxide semiconductor with a sufficiently reduced amount of V_{O}H, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurity such as V_{O}H is used for the channel formation region of the transistor, the transistor can have stable electrical characteristics. Note that repairing oxygen vacancies by supplying oxygen to an oxide semiconductor is sometimes referred to as oxygen adding treatment.

When an oxide semiconductor is used for each of the semiconductor layer 108 and the semiconductor layer 208, the carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. The minimum carrier concentration of the oxide semiconductor in the region functioning as the channel formation region is not particularly limited and can be 1×10⁻⁹ cm⁻³, for example.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, a semiconductor device can have lower power consumption by including the OS transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Examples of silicon that can be used for the semiconductor layer 108 and the semiconductor layer 208 include single crystal silicon, polycrystalline silicon, microcrystalline silicon, and amorphous silicon. An example of polycrystalline silicon is low-temperature polysilicon (LTPS).

The transistors in which the semiconductor layer 108 and the semiconductor layer 208 include amorphous silicon can be formed over a large-sized glass substrate, thereby reducing the manufacturing cost. The transistors in which the semiconductor layer 108 and the semiconductor layer 208 include polycrystalline silicon have high field-effect mobility and are capable of high-speed operation. The transistors in which the semiconductor layer 108 and the semiconductor layer 208 include microcrystalline silicon have higher field-effect mobility and are capable of higher speed operation than the transistor including amorphous silicon.

The semiconductor layer 108 and the semiconductor layer 208 may each include a layered material functioning as a semiconductor. The layered material generally refers to a group of materials having a layered crystal structure. In the layered crystal structure, layers formed by a covalent bond or an ionic bond are stacked with a bond such as a van der Waals bond, which is weaker than a covalent bond or an ionic bond. The layered material has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The semiconductor layer 108 and the semiconductor layer 208 are formed in different processes. Thus, the material used for the semiconductor layer 108 and the material used for the semiconductor layer 208 can be different from each other.

As described above, electrical characteristics and reliability of the transistors depend on the materials used for the semiconductor layers. For example, in the case where a first metal oxide is used for the semiconductor layer 108 and a second metal oxide is used for the semiconductor layer 208, the content percentage of indium in the first metal oxide can be higher than the content percentage of indium in the second metal oxide. In that case, the transistor 100 can have a higher on-state current. Furthermore, more favorable saturation of the I_{d}-V_{d} characteristics of the transistor 200 can be achieved. Specifically, In—Ga—Zn oxide with an atomic ratio of 4:2:3 or in the neighborhood thereof can be used as the first metal oxide, and In—Ga—Zn oxide with an atomic ratio of 1:1:1 or in the neighborhood thereof can be used as the second metal oxide. Alternatively, In—Zn oxide with an atomic ratio of 1:1 or in the neighborhood thereof can be used as the first metal oxide, and In—Ga—Zn oxide with an atomic ratio of 1:1:1 or in the neighborhood thereof can be used as the second metal oxide. Alternatively, In—Zn oxide with an atomic ratio of 4:1 or in the neighborhood thereof can be used as the first metal oxide, and In—Ga—Zn oxide with an atomic ratio of 1:1:1 or in the neighborhood thereof can be used as the second metal oxide.

In the case where the semiconductor device of one embodiment of the present invention is applied to a display device, the transistor 100 can be suitably used in a driver circuit that requires a high on-state current (e.g., one or both of a gate line driver circuit and a source line driver circuit). The transistor 200 can be suitably used for a pixel circuit that requires favorable saturation. For example, in a pixel circuit of a display device including a light-emitting device, a transistor having a function of controlling a current flowing through the light-emitting device (hereinafter also referred to as a driving transistor) is required to have favorable saturation. The transistor 200 can be suitably used as the driving transistor.

The content percentage of indium in the second metal oxide may be higher than the content percentage of indium in the first metal oxide. In that case, the transistor 200 can have a higher on-state current. More favorable saturation of the I_{d}-V_{d} characteristics of the transistor 100 can be achieved.

By adjusting the channel lengths and the materials used for the semiconductor layers in accordance with the electrical characteristics and reliability required for the transistor 100 and the transistor 200, the semiconductor device can have both excellent electrical characteristics and high reliability.

The difference in indium content percentage between the semiconductor layer 108 and the semiconductor layer 208 can be confirmed by EDX, for example. In EDX, the proportion of the number of atoms of each element contained in the metal oxide can be calculated. When the proportion of the number of indium atoms in the calculated total number of atoms of all the metal elements (indium content percentage) is compared between the semiconductor layer 108 and the semiconductor layer 208, the difference in indium content percentage can be confirmed. In EDX, the number of counts (the detected value) of characteristic X-rays corresponds to the proportion of an element contained in a metal oxide. Thus, from the peak heights of indium in the semiconductor layer 108 and the semiconductor layer 208, the difference in indium content percentage can be confirmed. For example, in the case where the indium content percentage in the semiconductor layer 208 is higher than the indium content percentage in the semiconductor layer 108, the number of counts of characteristic X-rays derived from indium in the semiconductor layer 208 is higher than the number of counts of characteristic X-rays derived from indium in the semiconductor layer 108. Note that in EDX, a peak of a certain element refers to a point at which the number of counts of the element reaches a local maximum value in a spectrum where the horizontal axis represents the energy of characteristic X-rays and the vertical axis represents the number of counts of characteristic X-rays. Alternatively, the number of counts at an energy of a characteristic X-ray unique to the element may be used to confirm a difference in content percentage. For example, the number of counts at 3.287 keV (In-Lα) can be used for indium.

This description of indium content percentage as an example also applies to the content percentage of other elements. In the case where the difference in content percentage is confirmed using the number of counts at an energy of a characteristic X-ray unique to the element, for example, the number of counts at 9.243 keV (Ga-Kα) can be used for gallium and the number of counts at 8.632 keV (Zn-Kα) can be used for zinc.

The semiconductor layer 108 and the semiconductor layer 208 can be formed using metal oxides that are different in at least one of the thickness, crystallinity, carrier concentration, and film quality as well as the composition. For example, the semiconductor layer 108 and the semiconductor layer 208 may have different thicknesses as well as different compositions. For another example, the semiconductor layer 108 and the semiconductor layer 208 may have the same composition and different thicknesses. Furthermore, one of the semiconductor layer 108 and the semiconductor layer 208 may have a single-layer structure and the other may have a stacked-layer structure.

### [Insulating Layer 110]

The layers constituting the insulating layer 110 are preferably formed using inorganic insulating films. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

A composition can be analyzed by secondary ion mass spectrometry (SIMS), X-ray photoelectron spectrometry (XPS), auger electron spectrometry (AES), or energy dispersive X-ray spectrometry (EDX), for example. For example, when the content percentage of a target element is high (e.g., higher than or equal to 0.5 atomic %, or higher than or equal to 1 atomic %), XPS can be suitably used. In contrast, when the content percentage of a target element is low (e.g., lower than 0.5 atomic %, or lower than 1 atomic %), SIMS can be suitably used. For analysis of a composition, a plurality of analysis methods are preferably used. For example, it is preferable to perform combined analysis using both SIMS and XPS.

The insulating layer 110 includes a portion that is in contact with the semiconductor layer 108. In the case where the semiconductor layer 108 is formed using an oxide semiconductor, at least part of the portion of the insulating layer 110 that is in contact with the semiconductor layer 108 is preferably formed using an oxide or an oxynitride to improve the characteristics of the interface between the semiconductor layer 108 and the insulating layer 110. Specifically, the portion of the insulating layer 110 that is in contact with the channel formation region of the semiconductor layer 108 is preferably formed using an oxide or an oxynitride. The channel formation region is a high-resistance region having a low carrier concentration. The channel formation region can be regarded as an i-type (intrinsic) or substantially i-type region.

As the insulating layer 110b, a layer including oxygen is preferably used. It is preferable that the insulating layer 110b include a region having a higher oxygen content than at least one of the insulating layer 110a and the insulating layer 110c. It is particularly preferable that the insulating layer 110b include a region having a higher oxygen content than each of the insulating layer 110a and the insulating layer 110c.

The insulating layer 110b is preferably formed using any one or more of the oxide insulating films and oxynitride insulating films described above. Specifically, the insulating layer 110b is preferably formed using one or both of a silicon oxide film and a silicon oxynitride film. By having a high oxygen content, the insulating layer 110b can facilitate formation of an i-type region in the region of the semiconductor layer 108 that is in contact with the insulating layer 110b and the vicinity of this region.

It is further preferable that a film from which oxygen is released by heating be used for the insulating layer 110b. When the insulating layer 110b releases oxygen by heat applied during the manufacturing process of the transistor 100, the oxygen can be supplied to the semiconductor layer 108. The oxygen supply from the insulating layer 110b to the semiconductor layer 108, particularly to the channel formation region of the semiconductor layer 108, reduces the amounts of oxygen vacancy (V_{O}) and V_{O}H in the semiconductor layer 108, so that the transistor can have favorable electrical characteristics and high reliability.

For example, the insulating layer 110b can be supplied with oxygen when heat treatment or plasma treatment is performed in an oxygen-containing atmosphere. Alternatively, an oxide film may be formed over the top surface of the insulating layer 110b by a sputtering method in an oxygen atmosphere to supply oxygen. After that, the oxide film may be removed.

The insulating layer 110b is preferably formed by a film formation method such as a sputtering method or a plasma-enhanced chemical vapor deposition (PECVD) method. In particular, when the insulating layer 110b is formed by a sputtering method, which is a film formation method that does not use a gas containing hydrogen as a film formation gas, the insulating layer 110b can be a film having an extremely low hydrogen content. In that case, supply of hydrogen to the semiconductor layer 108 is inhibited and the electrical characteristics of the transistor 100 can be stabilized.

As described above, the channel length L100 of the transistor 100 can be extremely small. Particularly in the case where the channel length L100 is short, oxygen vacancies (V_{O}) and V_{O}H in the channel formation region greatly affect the electrical characteristics and reliability. Supply of oxygen from the insulating layer 110b to the semiconductor layer 108 inhibits an increase in the amounts of oxygen vacancy (V_{O}) and V_{O}H in the region of the semiconductor layer 108 that is in contact with the insulating layer 110b. Thus, the transistor with a short channel length can have favorable electrical characteristics and high reliability.

Each of the insulating layer 110a and the insulating layer 110c is preferably formed using a film that does not easily allow diffusion of oxygen. In that case, it is possible to prevent oxygen contained in the insulating layer 110b from being diffused toward the substrate 102 side and the insulating layer 106 side respectively through the insulating layer 110a and the insulating layer 110c owing to heating. In other words, when the insulating layer 110a and the insulating layer 110c that do not easily allow diffusion of oxygen are respectively provided below and above the insulating layer 110b so that the insulating layer 110b is sandwiched therebetween, oxygen can be enclosed in the insulating layer 110b. Accordingly, oxygen can be effectively supplied to the semiconductor layer 108.

For each of the insulating layer 110a and the insulating layer 110c, a film that does not easily allow diffusion of hydrogen is preferably used. In that case, hydrogen can be inhibited from being diffused from outside the transistor to the semiconductor layer 108 through the insulating layer 110a and the insulating layer 110c.

For each of the insulating layer 110a and the insulating layer 110c, any one or more of the oxide insulating film, nitride insulating film, oxynitride insulating film, and nitride oxide insulating film described above are preferably used, and any one or more of a silicon nitride film, a silicon nitride oxide film, a silicon oxynitride film, an aluminum oxide film, an aluminum oxynitride film, an aluminum nitride film, a hafnium oxide film, and a hafnium aluminate film are preferably used. Specifically, a silicon nitride film and a silicon nitride oxide film can be suitably used for each of the insulating layer 110a and the insulating layer 110c because a feature of a silicon nitride film and a silicon nitride oxide film is that they release small amounts of impurities (e.g., water and hydrogen) and do not easily transmit oxygen or hydrogen. For the insulating layer 110a and the insulating layer 110c, the same material or different materials may be used.

Here, the conductive layer 202, the conductive layer 112a, and the conductive layer 112b are oxidized by oxygen included in the insulating layer 110b and have high resistance in some cases. Providing the insulating layer 110a between the insulating layer 110b and the conductive layer 112a can inhibit the conductive layer 112a from being oxidized and having high resistance. Similarly, providing the insulating layer 110a between the insulating layer 110b and the conductive layer 202 can inhibit the conductive layer 202 from being oxidized and having high resistance. Furthermore, providing the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer 108 is increased, whereby the amount of oxygen vacancy in the semiconductor layer 108 can be reduced.

The thickness of each of the insulating layer 110a and the insulating layer 110c is preferably greater than or equal to 5 nm and less than or equal to 150 nm, further preferably greater than or equal to 5 nm and less than or equal to 100 nm, still further preferably greater than or equal to 5 nm and less than or equal to 70 nm, yet still further preferably greater than or equal to 10 nm and less than or equal to 70 nm, yet still further preferably greater than or equal to 10 nm and less than or equal to 50 nm, yet still further preferably greater than or equal to 20 nm and less than or equal to 50 nm. When the thickness of each of the insulating layer 110a and the insulating layer 110c is in the above-described range, the amount of oxygen vacancy in the semiconductor layer 108, or specifically the channel formation region, can be reduced.

It is preferable that, for example, the insulating layer 110a and the insulating layer 110c be formed using silicon nitride films and the insulating layer 110a be formed using a silicon oxynitride film.

Note that although the structure in which the insulating layer 110 has a four-layer structure is described in this embodiment, one embodiment of the present invention is not limited thereto. The insulating layer 110 may have a single-layer structure or a stacked-layer structure of two, three, or five or more layers. The insulating layer 110 preferably includes at least the insulating layer 110b.

### [Insulating Layer 120]

For the insulating layer 120, a material that can be used for the insulating layer 110 can be used. As the insulating layer 120 in contact with the semiconductor layer 208, an insulating layer including oxygen is preferably used. For the insulating layer 120, a material that can be used for the insulating layer 110b can be suitably used. For example, silicon oxide or silicon oxynitride can be suitably used for the insulating layer 120.

Although the insulating layer 120 has a single-layer structure in this embodiment, one embodiment of the present invention is not limited thereto. The insulating layer 120 may have a stacked-layer structure of two or more layers. Alternatively, the insulating layer 120 may be omitted.

[Conductive Layer 112a, Conductive Layer 112b, Conductive Layer 104, Conductive Layer 202, Conductive Layer 204, Conductive Layer 212a, and Conductive Layer 212b]

The conductive layer 112a, the conductive layer 112b, the conductive layer 104, the conductive layer 202, the conductive layer 204, the conductive layer 212a, and the conductive layer 212b may each have a single-layer structure or a stacked-layer structure of two or more layers. The conductive layer 112a, the conductive layer 112b, the conductive layer 104, the conductive layer 202, the conductive layer 204, the conductive layer 212a, and the conductive layer 212b can each be formed using, for example, one or more of chromium, copper, aluminum, gold, silver, zinc, tantalum, titanium, tungsten, manganese, nickel, iron, cobalt, molybdenum, ruthenium, and niobium, or an alloy containing one or more of these metals as its components. For the conductive layer 112a, the conductive layer 112b, the conductive layer 104, the conductive layer 202, the conductive layer 204, the conductive layer 212a, and the conductive layer 212b, a conductive material with low resistance that contains one or more of copper, silver, gold, and aluminum can be suitably used. Copper or aluminum is particularly preferable because of its high mass-productivity.

For the conductive layer 112a, the conductive layer 112b, the conductive layer 104, the conductive layer 202, the conductive layer 204, the conductive layer 212a, and the conductive layer 212b, a conductive metal oxide (also referred to as an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A conductive oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a, the conductive layer 112b, the conductive layer 104, the conductive layer 202, the conductive layer 204, the conductive layer 212a, and the conductive layer 212b may each have a stacked-layer structure of a conductive film including the above-described oxide conductor (metal oxide) and a conductive film including a metal or an alloy. The use of the conductive film including a metal or an alloy can reduce the wiring resistance.

A Cu-X alloy film (X is Mn, Ni, Cr, Fe, Co, Mo, Ta, or Ti) may be used for the conductive layer 112a, the conductive layer 112b, the conductive layer 104, the conductive layer 202, the conductive layer 204, the conductive layer 212a, and the conductive layer 212b. The use of a Cu-X alloy film results in lower manufacturing cost because the film can be processed by a wet etching method.

Note that the conductive layer 112a, the conductive layer 112b, the conductive layer 104, the conductive layer 202, the conductive layer 204, the conductive layer 212a, and the conductive layer 212b may be formed using the same material, or at least one of them may be formed using a different material.

Note that in this specification and the like, different materials mean materials having different constituent elements or materials having the same constituent element(s) and different compositions.

Each of the conductive layer 112a and the conductive layer 112b includes a region that is in contact with the semiconductor layer 108. When the semiconductor layer 108 is formed using an oxide semiconductor and the conductive layer 112a or the conductive layer 112b is formed using a metal that is likely to be oxidized (e.g., aluminum), an insulating oxide (e.g., aluminum oxide) is formed between the conductive layer 112a or the conductive layer 112b and the semiconductor layer 108, which might inhibit continuity between the conductive layer 112a or the conductive layer 112b and the semiconductor layer 108. Therefore, the conductive layer 112a and the conductive layer 112b are preferably formed using a conductive material that is less likely to be oxidized or a conductive material that maintains low electrical resistance even when oxidized.

For the conductive layer 112a and the conductive layer 112b, for example, one or more of titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or conductive materials that maintain low electrical resistance even when oxidized.

The conductive layer 112a and the conductive layer 112b can each be formed using any of the above-described oxide conductors. Specifically, one or more of indium oxide, zinc oxide, ITO, In—Zn oxide, In—W oxide, In—W—Zn oxide, In—Ti oxide, In—Ti—Sn oxide, In—Sn oxide containing silicon, and zinc oxide to which gallium is added can be used.

For the conductive layer 112a and the conductive layer 112b, a nitride conductor may be used. For example, one or more of tantalum nitride and titanium nitride can be used.

The conductive layer 112a and the conductive layer 112b may each have a stacked-layer structure. In the case where the conductive layer 112a and the conductive layer 112b each have a stacked-layer structure, a conductive material that is less likely to be oxidized or a conductive material that maintains low electrical resistance even when oxidized is preferably used for at least the side in contact with the semiconductor layer 108. For example, the conductive layer 112a can have a stacked-layer structure of an aluminum film and a titanium film over the aluminum film. The titanium film includes a region in contact with the semiconductor layer 108. The conductive layer 112a can have a stacked-layer structure of a first titanium film, an aluminum film over the first titanium film, and a second titanium film over the aluminum film. The second titanium film includes a region in contact with the semiconductor layer 108.

### [Insulating Layer 105 and Insulating Layer 106]

The insulating layer 105 and the insulating layer 106 may each have a single-layer structure or a stacked-layer structure of two or more layers. The insulating layer 105 and the insulating layer 106 each preferably include one or more inorganic insulating films. Examples of the inorganic insulating film include an oxide insulating film, a nitride insulating film, an oxynitride insulating film, and a nitride oxide insulating film. For each of the insulating layer 105 and the insulating layer 106, a material that can be used for the insulating layer 110 can be used.

The insulating layer 105 includes a region that is in contact with the semiconductor layer 208. The insulating layer 106 includes a region that is in contact with the semiconductor layer 108 and a region that is in contact with the semiconductor layer 208. In the case where the semiconductor layer 108 and the semiconductor layer 208 are each formed using an oxide semiconductor, at least the films that are included in the insulating layer 105 and the insulating layer 106 and that are in contact with the semiconductor layer 108 or the semiconductor layer 208 are preferably any of the above-described oxide insulating films and oxynitride insulating films. A film from which oxygen is released by heating is further preferably used for each of the insulating layer 105 and the insulating layer 106.

Specifically, in the case where the insulating layer 105 has a single-layer structure, the insulating layer 106 is preferably formed using a silicon oxide film or a silicon oxynitride film. The same applies to the insulating layer 106.

The insulating layer 106 can have a stacked-layer structure of an oxide insulating film or an oxynitride insulating film on the side that is in contact with the semiconductor layer 108 and a nitride insulating film or a nitride oxide insulating film on the side that is in contact with the conductive layer 104 and the conductive layer 204. The insulating layer 105 can have a stacked-layer structure of an oxide insulating film or an oxynitride insulating film on the side that is in contact with the semiconductor layer 208 and a nitride insulating film or a nitride oxide insulating film on the side that is in contact with the insulating layer 106. As the oxide insulating film or the oxynitride insulating film, for example, a silicon oxide film or a silicon oxynitride film is preferably used. As the nitride insulating film or the nitride oxide insulating film, a silicon nitride film or a silicon nitride oxide film is preferably used.

A silicon nitride film and a silicon nitride oxide film can be suitably used for each of the insulating layer 105 and the insulating layer 106 because a feature of a silicon nitride film and a silicon nitride oxide film is that they release small amounts of impurities (e.g., water and hydrogen) and do not easily transmit oxygen or hydrogen. Inhibiting diffusion of impurities from the insulating layer 105 and the insulating layer 106 to the semiconductor layer 108 and the semiconductor layer 208 results in favorable electrical characteristics and high reliability of the transistors.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 105 and the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

The insulating layer 195 functioning as a protective layer of the transistor 100 and the transistor 200 is preferably formed using a material that does not easily allow diffusion of impurities. Providing the insulating layer 195 can effectively inhibit diffusion of impurities into the transistors from the outside and increase the reliability of the display device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of the semiconductor device completed thereover can be separated from the substrate 102 and transferred onto another substrate. In that case, the transistor 100 and the like can be transferred onto a substrate having low heat resistance or a flexible substrate as well.

Structure examples of a semiconductor device and a transistor whose structures are partly different from those in Structure example 1 above will be described below. Note that description of the same portions as those in Structure example 1 above is omitted below in some cases. Furthermore, in diagrams that are referred to later, the same hatching pattern is applied to portions having functions similar to those in Structure example 1 above, and the portions are not denoted by reference numerals in some cases.

### Structure Example 2

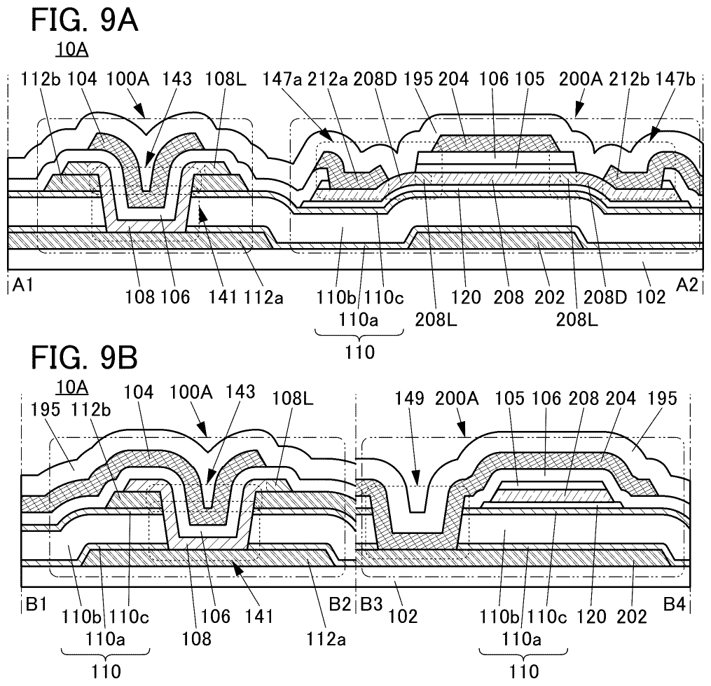

FIG. 9A and FIG. 9B are cross-sectional views of a semiconductor device 10A of one embodiment of the present invention. FIG. 1A can be referred to for a top view of the semiconductor device 10A. FIG. 9A is a cross-sectional view of a cross section along the dashed-dotted line A1-A2 in FIG. 1A, and FIG. 9B is a cross-sectional view of cross sections along the dashed-dotted line B1-B2 and the dashed-dotted line B3-B4 in FIG. 1A.

The semiconductor device 10A includes a transistor 100A and a transistor 200A. The transistor 100A is different from the transistor 100 illustrated in FIG. 1B and the like mainly in not including the insulating layer 120. The transistor 200A is different from the transistor 200 illustrated in FIG. 1B and the like mainly in that the insulating layer 120 has an island shape.

In this specification and the like, the term “island shape” refers to a state where two or more layers formed using the same material in the same process are physically separated from each other.

In the transistor 100A, the conductive layer 112b is provided in contact with the insulating layer 110 (here, the insulating layer 110c). The semiconductor layer 108 is in contact with the top surface of the conductive layer 112a, the side surface of the insulating layer 110, and the top surface and the side surface of the conductive layer 112b.

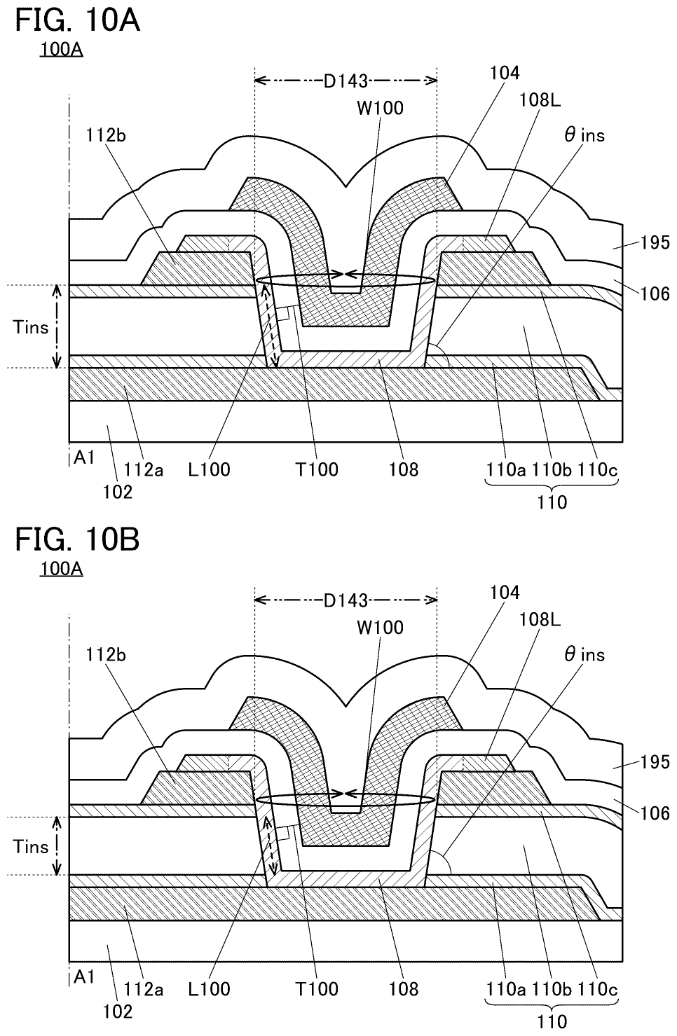

FIG. 10A is an enlarged view of the transistor 100A illustrated in FIG. 9A. The region of the semiconductor layer 108 that is in contact with the insulating layer 110 functions as a channel formation region. In FIG. 10A, the channel length L100 of the transistor 100A is indicated by a dashed double-headed arrow. The channel length L100 of the transistor 100A depends on the thickness Tins of the insulating layer in contact with the channel formation region (here, the thickness of the insulating layer 110) and the angle θins formed by the side surface of the insulating layer on the opening 141 side and the formation surface (here, the top surface of the conductive layer 112a) in a cross-sectional view. The thickness Tins and the angle θins are preferably within the above-described ranges.

In the semiconductor layer 108, at least one of the region in contact with the insulating layer 110a and the region in contact with the insulating layer 110c may be a region having a higher carrier concentration and lower resistance than the channel formation region (hereinafter, also referred to as a low-resistance region). When a material that releases an impurity (e.g., water or hydrogen) is used for the insulating layer 110a, the region of the semiconductor layer 108 that is in contact with the insulating layer 110a can be a low-resistance region. In the semiconductor layer 108, the low-resistance region can be provided between the channel formation region and the region in contact with the conductive layer 112a (one of a source region and a drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be provided between the channel formation region and the region in contact with the conductive layer 112b (the other of the source region and the drain region). The low-resistance region can serve as a buffer region for relieving a drain electric field. Note that these low-resistance regions may function as the source region and the drain region.

When the low-resistance region is provided between the drain region and the channel formation region, a high electric field is not easily generated in the vicinity of the drain region, and generation of hot carriers and degradation of the transistor can be inhibited. For example, in the case where the conductive layer 112a serves as a drain electrode, the conductive layer 112b serves as a source electrode, and the region of the semiconductor layer 108 that is in contact with the insulating layer 110a serves as the low-resistance region, a high electric field is not easily generated in the vicinity of the drain region, and generation of hot carriers and degradation of the transistor can be inhibited. In the case where the conductive layer 112a serves as the source electrode, the conductive layer 112b serves as the drain electrode, and the region of the semiconductor layer 108 that is in contact with the insulating layer 110c serves as the low-resistance region, a high electric field is not easily generated in the vicinity of the drain region, and generation of hot carriers and degradation of the transistor can be inhibited.

A material that releases an impurity (e.g., water or hydrogen) may be used for each of the insulating layer 110a and the insulating layer 110c. In the structure shown in FIG. 10B, the region of the semiconductor layer 108 that is in contact with the insulating layer 110b functions as the channel formation region. The channel length L100 of the transistor 100A depends on the thickness Tins of the insulating layer in contact with the channel formation region (here, the thickness of the insulating layer 110b) and the angle θins formed by a side surface of the insulating layer 110b on the opening 141 side and the formation surface (here, the top surface of the insulating layer 110a) in a cross-sectional view. The thickness Tins is preferably within the above-described range. The angle θins is preferably within the above-described range of the angle θins.

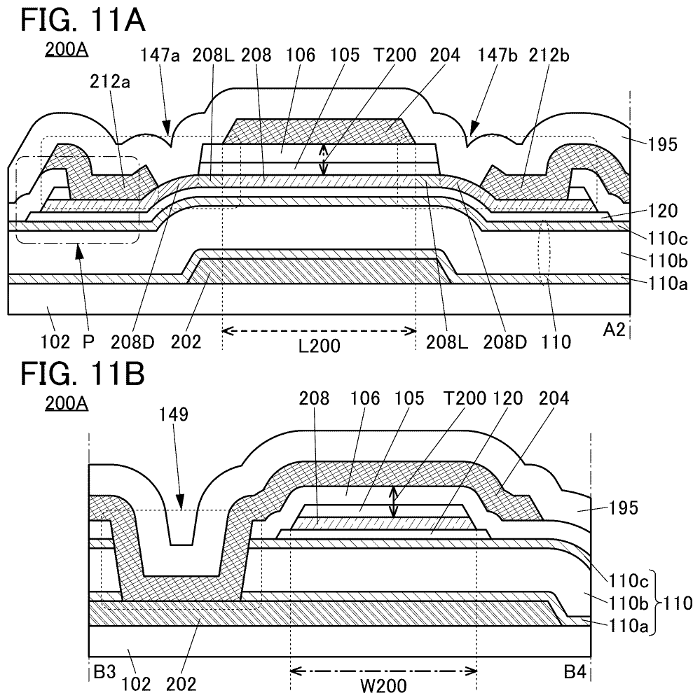

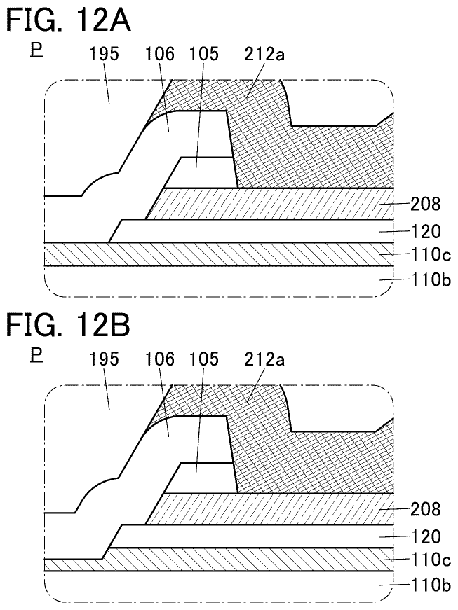

FIG. 11A and FIG. 11B are enlarged views of the transistor 200A illustrated in FIG. 9A and FIG. 9B. FIG. 12A shows an enlarged view of the region P indicated by the dashed-dotted line in FIG. 11A. In the transistor 200A, the semiconductor layer 208 is provided over the insulating layer 120. The insulating layer 120 is preferably provided at least in a region in contact with a channel formation region of the semiconductor layer 208. Alternatively, the entire bottom surface of the semiconductor layer 208 is preferably in contact with the insulating layer 120. It can be said that the end portion of the semiconductor layer 208 is in contact with the top surface of the insulating layer 120. Note that the entire bottom surface of the semiconductor layer 208 is not necessarily in contact with the insulating layer 120. The end portion of the semiconductor layer 108 may be in contact with the top surface of the insulating layer 110.

Here, for the insulating layer 120 in contact with the semiconductor layer 208, a film from which oxygen is released by heating is preferably used. When the insulating layer 120 releases oxygen by heat applied during the manufacturing process of the transistor 200, the oxygen can be supplied to the semiconductor layer 208. The oxygen supply from the insulating layer 120 to the semiconductor layer 208, particularly to the channel formation region of the semiconductor layer 208, reduces the amount of oxygen vacancy in the semiconductor layer 208, so that the transistor can have favorable electrical characteristics and high reliability. However, in the case where the insulating layer 120 includes a region that is in contact with the conductive layer 112b, the conductive layer 112b might be oxidized by oxygen released from the insulating layer 120 and the resistance of the conductive layer 112b might be increased. When the insulating layer 120 does not include a region that is in contact with the conductive layer 112b, an increase in the resistance of the conductive layer 112b can be inhibited.

Although the thickness of the insulating layer 110 is uniform without varying from place to place in the example shown in FIG. 12A or the like, one embodiment of the present invention is not limited to this example. As illustrated in FIG. 12B, the thickness of the insulating layer 110 (here, the insulating layer 110c) in a region overlapping with the insulating layer 120 may be different from the thickness of the insulating layer 110 in a region not overlapping with the insulating layer 120. For example, at the time of forming the insulating layer 120, the insulating layer 110c is sometimes partly removed to have a smaller thickness in the region not overlapping with the insulating layer 120 than in the region overlapping with the insulating layer 120. Note that in the formation of the insulating layer 120, a material having high selectivity is preferably used for the insulating layer 110c. In that case, the reduction in the thickness of the insulating layer 110c can be inhibited.

Note that the structure of the insulating layer 120 described in Structure example 2 can also be applied to other structure examples.

### Structure Example 3

Although the insulating layer 110a, the insulating layer 110c, and the insulating layer 120 each have a single-layer structure in the structure illustrated in FIG. 9(A) and the like, one embodiment of the present invention is not limited thereto. The insulating layer 110a, the insulating layer 110c, and the insulating layer 120 may each have a stacked-layer structure.

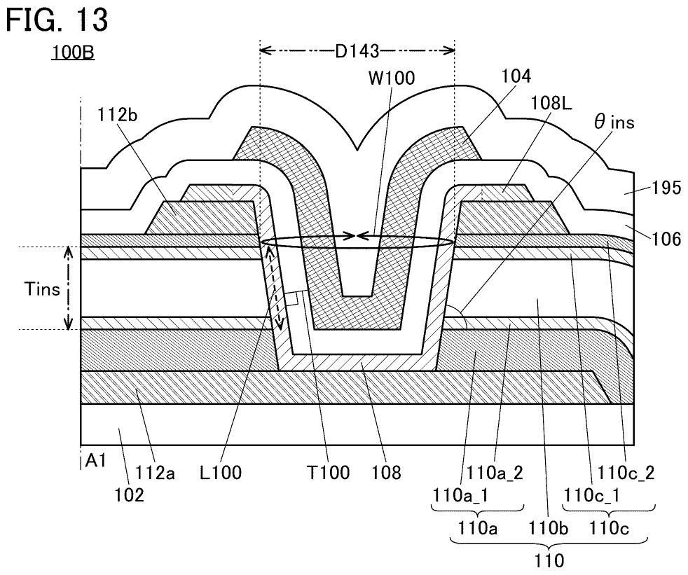

A transistor 100B illustrated in FIG. 13 is different from the transistor 100A mainly in that the insulating layer 110a has a stacked-layer structure of an insulating layer 110a_1 and an insulating layer 110a_2 over the insulating layer 110a_1, and that the insulating layer 110c has a stacked-layer structure of an insulating layer 110c_1 and an insulating layer 110c_2 over the insulating layer 110c_1.

For each of the insulating layer 110a_1 and the insulating layer 110a_2, a material that can be used for the insulating layer 110a can be used. For example, a silicon nitride film or a silicon nitride oxide film can be suitably used for each of the insulating layer 110a_1 and the insulating layer 110a_2.

For each of the insulating layer 110c_1 and the insulating layer 110c_2, a material that can be used for the insulating layer 110c can be used. For example, a silicon nitride film or a silicon nitride oxide film can be suitably used for each of the insulating layer 110c_1 and the insulating layer 110c_2.

When a material that releases an impurity (e.g., water or hydrogen) is used for the insulating layer 110a_1, the region of the semiconductor layer 108 that is in contact with the insulating layer 110a_1 can be a low-resistance region. In the semiconductor layer 108, the low-resistance region can be provided between a channel formation region and the region in contact with the conductive layer 112a (one of a source region and a drain region). Similarly, when a material that releases an impurity is used for the insulating layer 110c_2, the region of the semiconductor layer 108 that is in contact with the insulating layer 110c_2 can be a low-resistance region. In the semiconductor layer 108, the low-resistance region can be provided between the channel formation region and the region in contact with the conductive layer 112b (the other of the source region and the drain region). The low-resistance region can serve as a buffer region for relieving a drain electric field. Note that these low-resistance regions may function as the source region and the drain region.

When the low-resistance region is provided between the drain region and the channel formation region, a high electric field is not easily generated in the vicinity of the drain region, and generation of hot carriers and degradation of the transistor can be inhibited. For example, in the case where the conductive layer 112a serves as a drain electrode, the conductive layer 112b serves as a source electrode, and the region of the semiconductor layer 108 that is in contact with the insulating layer 110a_1 serves as the low-resistance region, a high electric field is not easily generated in the vicinity of the drain region, and generation of hot carriers and degradation of the transistor can be inhibited. In the case where the conductive layer 112a serves as the source electrode, the conductive layer 112b serves as the drain electrode, and the region of the semiconductor layer 108 that is in contact with the insulating layer 110c_2 serves as the low-resistance region, a high electric field is not easily generated in the vicinity of the drain region, and generation of hot carriers and degradation of the transistor can be inhibited.

In the case where the region of the semiconductor layer 108 that is in contact with the insulating layer 110a_1 functions as the source region or the drain region, the source region of the semiconductor layer 108 and the drain region thereof can be more equidistant from a gate electrode. Accordingly, the electric field of the gate electrode applied to the channel formation region can be more uniform.

It is preferable that the insulating layer 110a_2 itself release a small amount of impurity and not easily transmit impurities. In that case, an impurity in the insulating layer 110a_1 and hydrogen can be inhibited from diffusing into the channel formation region of the semiconductor layer 108 and the vicinity thereof through the insulating layer 110a_2 and the insulating layer 110b, whereby the transistor can have excellent electrical characteristics and high reliability.

The insulating layer 110a_1 preferably includes a region including more hydrogen than the insulating layer 110a_2. The hydrogen content of the insulating layer 110a can be analyzed by secondary ion mass spectrometry (SIMS), for example.

When the film formation conditions for the insulating layer 110a_1 are different from those for the insulating layer 110a_2, the amount of released hydrogen can be adjusted. Specifically, the film formation conditions for the insulating layer 110a_1 may be different from those for the insulating layer 110a_2 in any one or more of a film formation power (film formation power density), a film formation pressure, the kind of a film formation gas, the flow rate ratio of a film formation gas, a film formation temperature, and the distance between the substrate and an electrode during formation. For example, the film formation power density for the insulating layer 110a_1 may be lower than that for the insulating layer 110a_2, in which case the insulating layer 110a_1 can have a higher hydrogen content than the insulating layer 110a_2. Accordingly, the amount of hydrogen released from the insulating layer 110a_1 due to heat applied thereto can be increased.

The film formation gas used for the formation of the insulating layer 110a_1 preferably includes more hydrogen than the film formation gas used for the formation of the insulating layer 110a_2. Specifically, in the case where a silicon nitride film or a silicon nitride oxide film is formed for each of the insulating layer 110a_1 and the insulating layer 110a_2 using a PECVD method, the proportion of the flow rate of an ammonia gas to the total flow rate of the film formation gas used for forming the insulating layer 110a_1 (hereinafter also referred to as ammonia flow rate ratio) is preferably higher than the ammonia flow rate ratio of the film formation gas used for forming the insulating layer 110a_2. The formation of the insulating layer 110a_1 under the condition where the ammonia flow rate ratio is high can increase the hydrogen content in the insulating layer 110a_1. Furthermore, the amount of hydrogen released from the insulating layer 110a_1 due to heat applied thereto can be increased.

The film density of the insulating layer 110a_2 is preferably higher than that of the insulating layer 110a_1. In that case, an impurity contained in the insulating layer 110a_1 and hydrogen can be inhibited from diffusing into the channel formation region of the semiconductor layer 108 and the vicinity thereof through the insulating layer 110a_2 and the insulating layer 110b. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Therefore, in a transmission electron (TE) image, the insulating layer 110a_2 is sometimes shown as a dark-colored (dark) image compared to the insulating layer 110a_1. Note that since the insulating layer 110a_1 and the insulating layer 110a_2 have different film densities even when including the same material, it is sometimes possible to identify the boundary between the insulating layers by a difference in contrast in a TEM image of a cross section.

It is preferable that the insulating layer 110c_1 itself release a small amount of impurity and not easily transmit impurities. In that case, an impurity in the insulating layer 110c_2 can be inhibited from diffusing into the channel formation region of the semiconductor layer 108 and the vicinity thereof through the insulating layer 110c_1 and the insulating layer 110b, whereby the transistor can have excellent electrical characteristics and high reliability. The film density of the insulating layer 110c_1 is preferably higher than that of the insulating layer 110c_2. For the insulating layer 110c_1, the description of the insulating layer 110a_2 can be referred to.

Note that although the insulating layer 110 has a five-layer structure here, one embodiment of the present invention is not limited thereto. The insulating layer 110 may have a stacked-layer structure of two, three, four, or six or more layers or a single-layer structure.

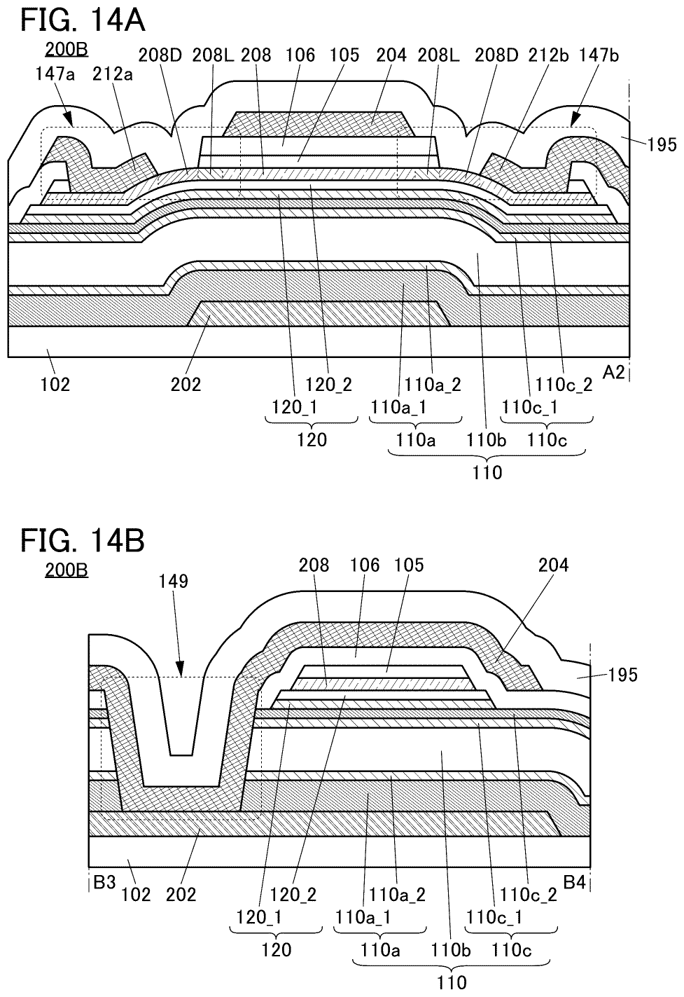

A transistor 200B illustrated in FIG. 14A and FIG. 14B is different from the transistor 200A mainly in that the insulating layer 120 has a stacked-layer structure of an insulating layer 120_1 and an insulating layer 120_2 over the insulating layer 120_1, that the insulating layer 110a has a stacked-layer structure of the insulating layer 110a_1 and the insulating layer 110a_2 over the insulating layer 110a_1, and that the insulating layer 110c has a stacked-layer structure of the insulating layer 110c_1 and the insulating layer 110c_2 over the insulating layer 110c_1.

The above description can be referred to for the insulating layer 110a_1, the insulating layer 110a_2, the insulating layer 110c_1, and the insulating layer 110c_2; thus, detailed description thereof is omitted.

For each of the insulating layer 120_1 and the insulating layer 120_2, a material that can be used for the insulating layer 120 can be used.

It is preferable that the insulating layer 120_1 itself release a small amount of impurity (e.g., water and hydrogen) and not easily transmit impurities. In that case, an impurity contained in the insulating layer 110 and hydrogen can be inhibited from diffusing into the channel formation region of the semiconductor layer 208 and the vicinity thereof through the insulating layer 120_1, whereby the transistor can have excellent electrical characteristics and high reliability. It is particularly preferable to provide the insulating layer 120_1 in the case where a layer that releases impurities (e.g., the insulating layer 110c_2) is provided in the insulating layer 110. For the insulating layer 120_1, a material that can be used for the insulating layer 110a and the insulating layer 110c can be suitably used. For example, silicon nitride can be suitably used for the insulating layer 120_1.

As the insulating layer 120_2, which includes a region in contact with the channel formation region of the semiconductor layer 208, an insulating layer including oxygen is preferably used. For the insulating layer 120_2, a material that can be used for the insulating layer 110b can be suitably used. For example, silicon oxide or silicon oxynitride can be suitably used for the insulating layer 120_2.

Although the insulating layer 120 has a two-layer structure here, one embodiment of the present invention is not limited thereto. The insulating layer 120 may have a stacked-layer structure of three or more layers or a single-layer structure.

Note that the structure of the insulating layer 110 described in Structure example 3 can also be applied to other structure examples. Similarly, the structure of the insulating layer 120 can also be applied to other structure examples.

### Structure Example 4

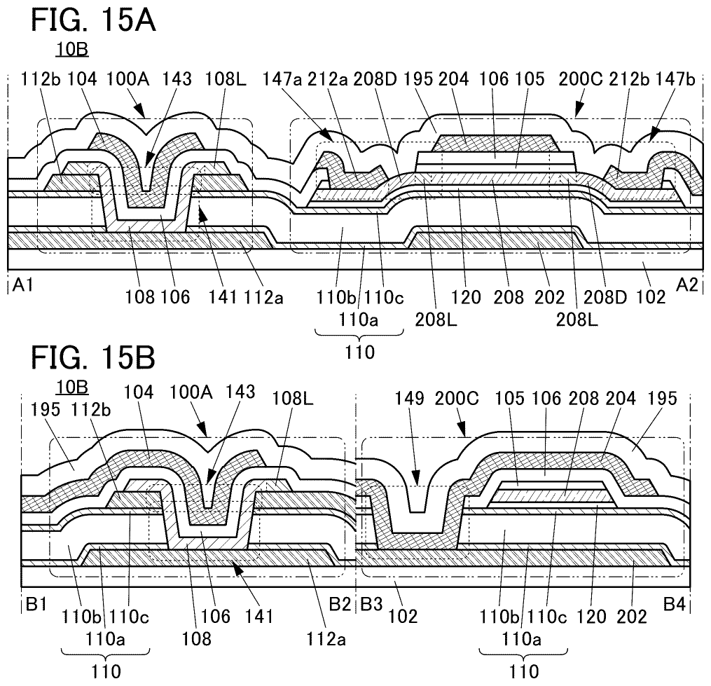

FIG. 15A and FIG. 15B are cross-sectional views of a semiconductor device 10B of one embodiment of the present invention. FIG. 1A can be referred to for a top view of the semiconductor device 10B. FIG. 15A is a cross-sectional view of a cross section along the dashed-dotted line A1-A2 in FIG. 1A, and FIG. 15B is a cross-sectional view of cross sections along the dashed-dotted line B1-B2 and the dashed-dotted line B3-B4 in FIG. 1A.

The semiconductor device 10B includes the transistor 100A and a transistor 200C. The transistor 200C is different from the transistor 200A illustrated in FIG. 9A and the like mainly in that an end portion of the insulating layer 120 is aligned or substantially aligned with the end portion of the semiconductor layer 208 and the end portion of the insulating layer 105.

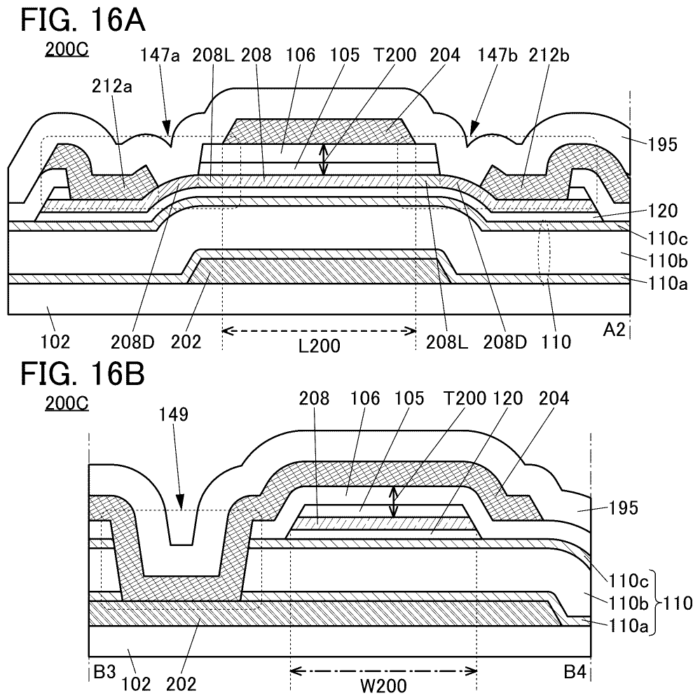

FIG. 16A and FIG. 16B are enlarged views of the transistor 200C illustrated in FIG. 15A and FIG. 15B. The end portion of the insulating layer 120, the end portion of the semiconductor layer 208, and the end portion of the insulating layer 105 are aligned or substantially aligned with each other. The end portion of the insulating layer 120, the end portion of the semiconductor layer 208, and the end portion of the insulating layer 105 can be aligned or substantially aligned with each other in the following manner, for example: a first insulating film to be the insulating layer 120, the semiconductor film to be the semiconductor layer 208 over the first insulating film, a second insulating film to be the insulating layer 105 over the semiconductor film, and a resist mask over the second insulating film are formed, and the second insulating film, the semiconductor film, and the first insulating film are processed using the resist mask. With such a structure, the process can be simplified.

The above description can be referred to for the transistor 100A; thus, the detailed description thereof is omitted.

Note that the structure of the insulating layer 120 described in Structure example 4 can also be applied to other structure examples.

### Structure Example 5

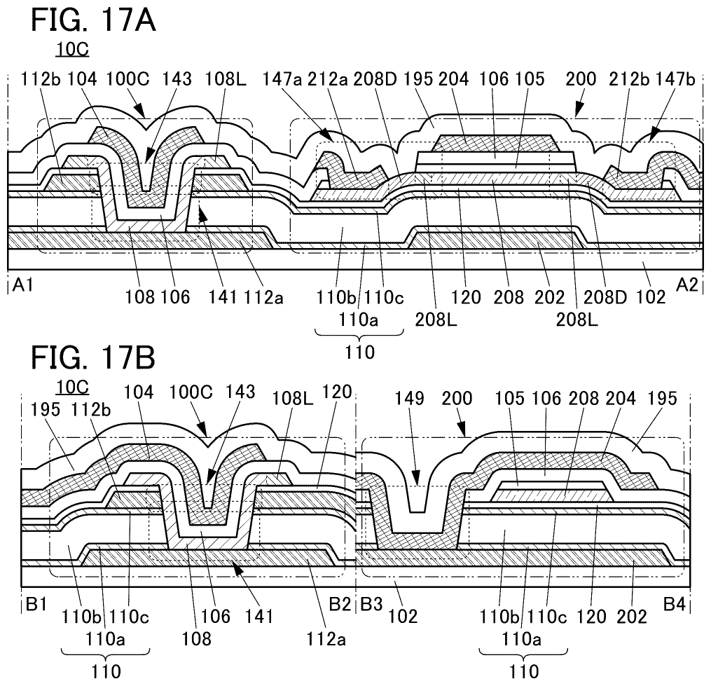

FIG. 17A and FIG. 17B are cross-sectional views of a semiconductor device 10C of one embodiment of the present invention. FIG. 1A can be referred to for a top view of the semiconductor device 10C. FIG. 17A is a cross-sectional view of a cross section along the dashed-dotted line A1-A2 in FIG. 1A, and FIG. 17B is a cross-sectional view of cross sections along the dashed-dotted line B1-B2 and the dashed-dotted line B3-B4 in FIG. 1A.

The semiconductor device 10C includes a transistor 100C and the transistor 200. The transistor 100C is different from the transistor 100 illustrated in FIG. 1B and the like mainly in that the insulating layer 120 is provided between the semiconductor layer 108 and the conductive layer 112b.

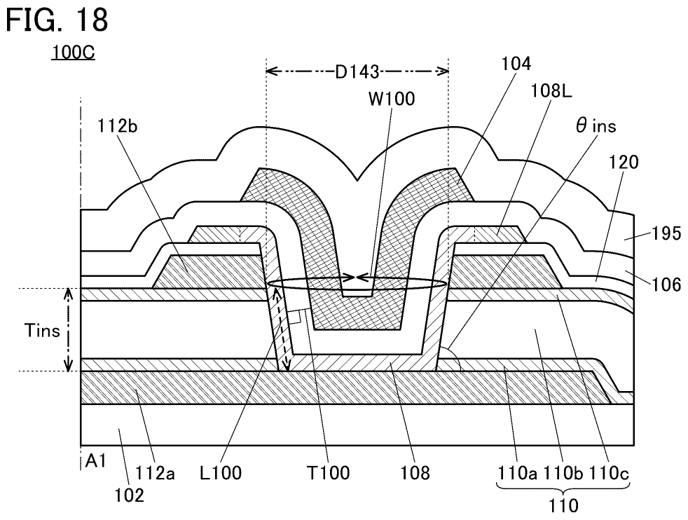

FIG. 18 is an enlarged view of the transistor 100C illustrated in FIG. 17A. The insulating layer 120 is in contact with the top surface of the insulating layer 110 (here, the insulating layer 110c) and the top surface and a side surface of the conductive layer 112b. The opening 143 is provided in the conductive layer 112b and the insulating layer 120. For example, the opening 143 can be provided in the following manner: a conductive film to be the conductive layer 112b and an insulating film to be the insulating layer 120 are formed, and then, the conductive film and the insulating film are partly removed. Note that the opening provided in the insulating layer 120 and the opening provided in the conductive layer 112b may be formed in different steps.

The above description can be referred to for the transistor 200; thus, the detailed description thereof is omitted.

Note that the structure of the insulating layer 120 described in Structure example 5 can also be applied to other structure examples.

### Structure Example 6

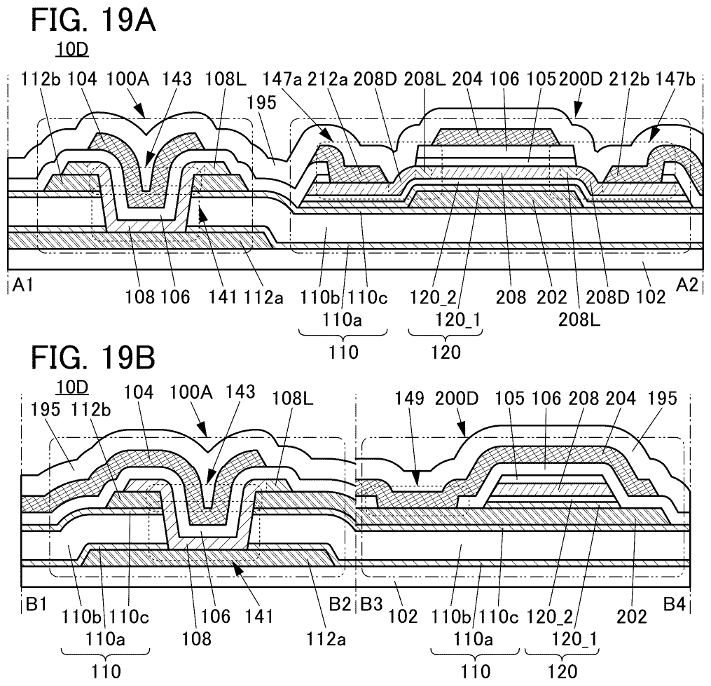

FIG. 19A and FIG. 19B are cross-sectional views of a semiconductor device 10D of one embodiment of the present invention. FIG. 1A can be referred to for a top view of the semiconductor device 10D. FIG. 19A is a cross-sectional view of a cross section along the dashed-dotted line A1-A2 in FIG. 1A, and FIG. 19B is a cross-sectional view of cross sections along the dashed-dotted line B1-B2 and the dashed-dotted line B3-B4 in FIG. 1A.

The semiconductor device 10D includes the transistor 100A and a transistor 200D. The transistor 200D is different from the transistor 200C illustrated in FIG. 15A and the like mainly in that the conductive layer 202 is provided between the insulating layer 110 and the insulating layer 120.

In the transistor 200D, the conductive layer 202 is provided over the insulating layer 110. The conductive layer 202 can be formed using the same material as the conductive layer 112b. The conductive layer 202 can be formed through the same process as the conductive layer 112b.

The insulating layer 120 is provided over the conductive layer 202. The insulating layer 120 is provided to cover part of the top surface and part of a side surface of the conductive layer 202. In a transistor 200H, part of the insulating layer 120 functions as a back gate insulating layer. When the conductive layer 202 is provided between the insulating layer 110 and the insulating layer 120, the thickness of the back gate insulating layer of the transistor 200H can be small. Accordingly, the electric field of a back gate electrode can be intensified. Furthermore, more favorable saturation of the I_{d}-V_{d} characteristics of the transistor 200H can be achieved. In addition, a shift in the threshold voltage can be inhibited. Here, a shift in the threshold voltage of the transistor might increase the drain current flowing at a gate voltage of 0 V (hereinafter, also referred to as cut-off current). When the threshold voltage shift of the transistor 200H is inhibited, the cut-off current can be reduced. Note that characteristics with a low cut-off current are sometimes referred to as normally-off characteristics.

The insulating layer 120 preferably has a stacked-layer structure. In the example shown in FIG. 19A and FIG. 19B, the insulating layer 120 has a stacked-layer structure of the insulating layer 120_1 and the insulating layer 120_2 over the insulating layer 120_1.

A material that does not easily allow diffusion of a metal element contained in the conductive layer 202 is preferably used for the insulating layer 120_1 provided in contact with the conductive layer 202. In that case, the metal element contained in the conductive layer 202 can be inhibited from diffusing into a channel formation region in the semiconductor layer 208 and the vicinity thereof. For the insulating layer 120_1, a material that can be used for the insulating layer 110a and the insulating layer 110c can be suitably used. For example, silicon nitride can be suitably used for the insulating layer 120_1.

As the insulating layer 120_2, which includes a region in contact with the channel formation region of the semiconductor layer 208, an insulating layer including oxygen is preferably used. The above description can be referred to for the insulating layer 120_2.

The above description can be referred to for the transistor 100A; thus, the detailed description thereof is omitted.

Note that the structure of the conductive layer 202 described in Structure example 6 can also be applied to other structure examples. The structure of the insulating layer 120 can also be applied to other structure examples.

### Structure Example 7

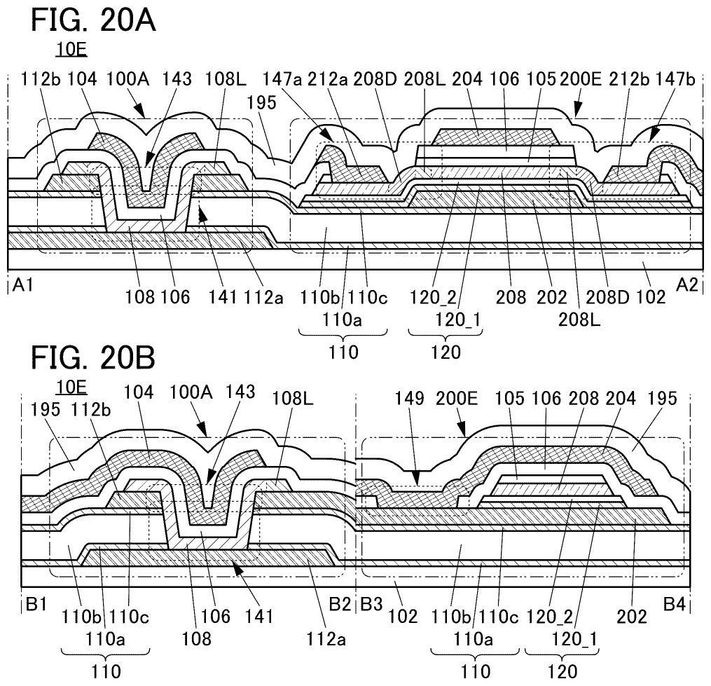

FIG. 20A and FIG. 20B are cross-sectional views of a semiconductor device 10E of one embodiment of the present invention. FIG. 1A can be referred to for a top view of the semiconductor device 10E. FIG. 20A is a cross-sectional view of a cross section along the dashed-dotted line A1-A2 in FIG. 1A, and FIG. 20B is a cross-sectional view of cross sections along the dashed-dotted line B1-B2 and the dashed-dotted line B3-B4 in FIG. 1A.

The semiconductor device 10E includes the transistor 100A and a transistor 200E. The transistor 200E is different from the transistor 200D illustrated in FIG. 19A and the like mainly in that the insulating layer 120 includes a portion extending outward from the end portion of the insulating layer 105 and the end portion of the semiconductor layer 208.

In the transistor 200D, the insulating layer 106 is in contact with the top surface and a side surface of the insulating layer 105, the side surface of the semiconductor layer 208, and the top surface and a side surface of the insulating layer 120. For example, after the insulating layer 120 is formed, the insulating layer 105 and the semiconductor layer 208 are formed such that the insulating layer 120 includes the portion extending outward from the end portion of the insulating layer 105 and the end portion of the semiconductor layer 208.

The above description can be referred to for the transistor 100A; thus, the detailed description thereof is omitted.

Note that the structure of the insulating layer 120 described in Structure example 7 can also be applied to other structure examples.

### Structure Example 8

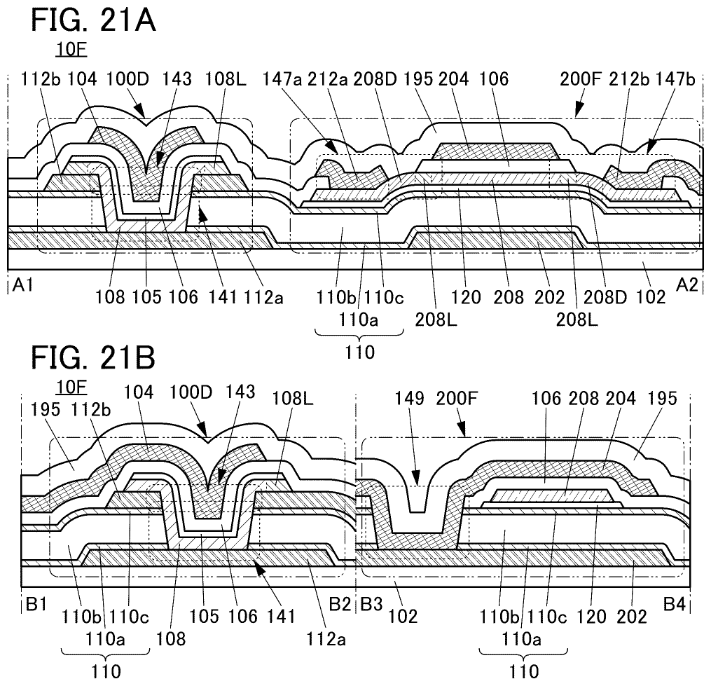

FIG. 21A and FIG. 21B are cross-sectional views of a semiconductor device 10F of one embodiment of the present invention. FIG. 1A can be referred to for a top view of the semiconductor device 10F. FIG. 21A is a cross-sectional view of a cross section along the dashed-dotted line A1-A2 in FIG. 1A, and FIG. 21B is a cross-sectional view of cross sections along the dashed-dotted line B1-B2 and the dashed-dotted line B3-B4 in FIG. 1A.

The semiconductor device 10F includes a transistor 100D and a transistor 200F. The semiconductor device 10F is different from the semiconductor device 10A illustrated in FIG. 9A and the like mainly in that the transistor 100D includes the insulating layer 105 and the transistor 200F does not include the insulating layer 105.

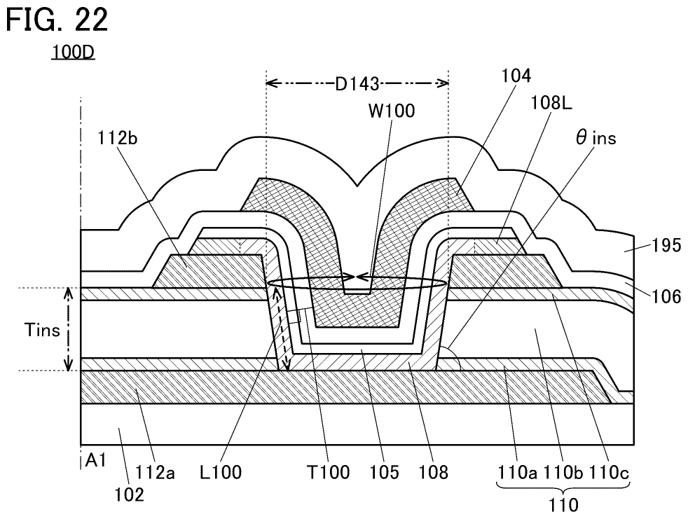

FIG. 22 is an enlarged view of the transistor 100D illustrated in FIG. 21A. The insulating layer 105 is provided over the semiconductor layer 108. The insulating layer 106 is provided over the insulating layer 105. The end portion of the semiconductor layer 108 is aligned or substantially aligned with an end portion of the insulating layer 105. The end portion of the semiconductor layer 108 and the end portion of the insulating layer 105 can be aligned or substantially aligned with each other in the following manner, for example: a semiconductor film to be the semiconductor layer 108, an insulating film to be the insulating layer 105 over the semiconductor film, and a resist mask over the insulating film are formed, and the insulating film and the semiconductor film are processed using the resist mask. The insulating layer 106 is provided to cover the semiconductor layer 108 and the insulating layer 105. In the transistor 100D, the insulating layer 106 is in contact with the top surface and the side surface of the insulating layer 105, a side surface of the semiconductor layer 108, and the top surface and the side surface of the conductive layer 112b.

The end portion of the semiconductor layer 108 is not necessarily aligned with the end portion of the insulating layer 105. For example, in the case where a dry etching method is used to form the insulating layer 105 and a wet etching method is used to form the semiconductor layer 108, the end portion of the semiconductor layer 108 is positioned inward from the end portion of the insulating layer 105 in some cases. Alternatively, the end portion of the semiconductor layer 108 may be positioned outward from the end portion of the insulating layer 105. Note that the side surface of the semiconductor layer 108 is not necessarily linear in a cross-sectional view. The side surface of the semiconductor layer 208 may be curved.

The insulating layer 105 and the insulating layer 106 sandwiched between the semiconductor layer 108 and the conductive layer 104 that functions as a gate electrode of the transistor 100D function as a gate insulating layer. The thickness T100 of the gate insulating layer is the shortest distance between the conductive layer 104 and the semiconductor layer 108 in a cross-sectional view. Since the insulating layer 105 and the insulating layer 106 are provided to cover the opening 141 and the opening 143 with the semiconductor layer 108 therebetween, the thickness T100 of the gate insulating layer sometimes varies depending on the angle θins and the formation methods of the insulating layer 105 and the insulating layer 106. The angle θins and the formation conditions of the insulating layer 105 and insulating layer 106 are preferably adjusted to achieve the desired thickness T100.

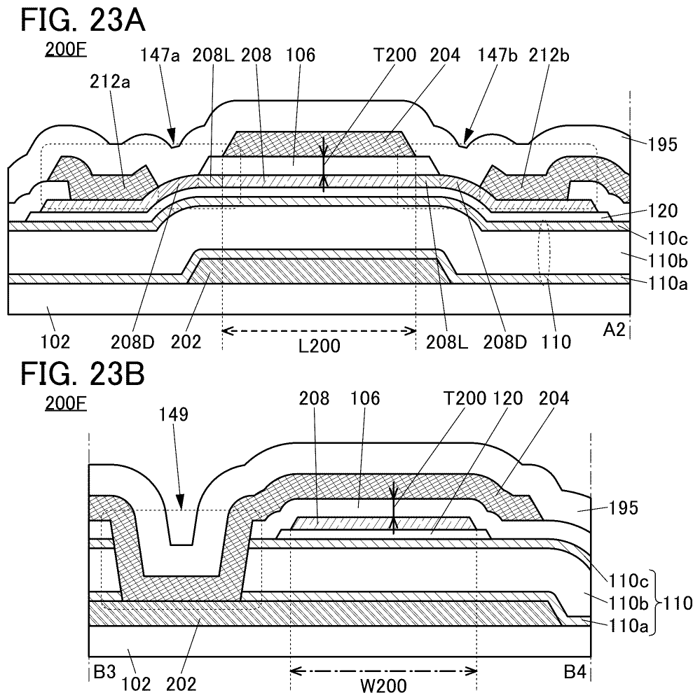

FIG. 23A and FIG. 23B are enlarged views of the transistor 200F illustrated in FIG. 21A and FIG. 21B. The insulating layer 106 is provided over the semiconductor layer 208. The conductive layer 204 is provided over the insulating layer 106. The insulating layer 106 includes the opening 147a and the opening 147b reaching the semiconductor layer 208, and the conductive layer 212a and the conductive layer 212b are provided to cover the opening 147a and the opening 147b.

The insulating layer 106 sandwiched between the conductive layer 204 that functions as a gate electrode of the transistor 200F and the semiconductor layer 208 functions as a gate insulating layer. The thickness T200 of the gate insulating layer is the shortest distance between the conductive layer 204 and the semiconductor layer 208 in a cross-sectional view.

As illustrated in FIG. 21A and the like, the gate insulating layer of the transistor 100D has a stacked-layer structure of the insulating layer 105 and the insulating layer 106. Meanwhile, the gate insulating layer of the transistor 200F has a single-layer structure of the insulating layer 106. With such a structure, the thickness of the gate insulating layer of the transistor 100D can be larger than the thickness of the gate insulating layer of the transistor 200F. Thus, the gate breakdown voltage of the transistor 100D can be increased. The transistor 200F can have a higher on-state current and a higher operation speed.

Note that the structures of the insulating layer 105 and the insulating layer 106 described in Structure example 8 can also be applied to other structure examples.

### Structure Example 9

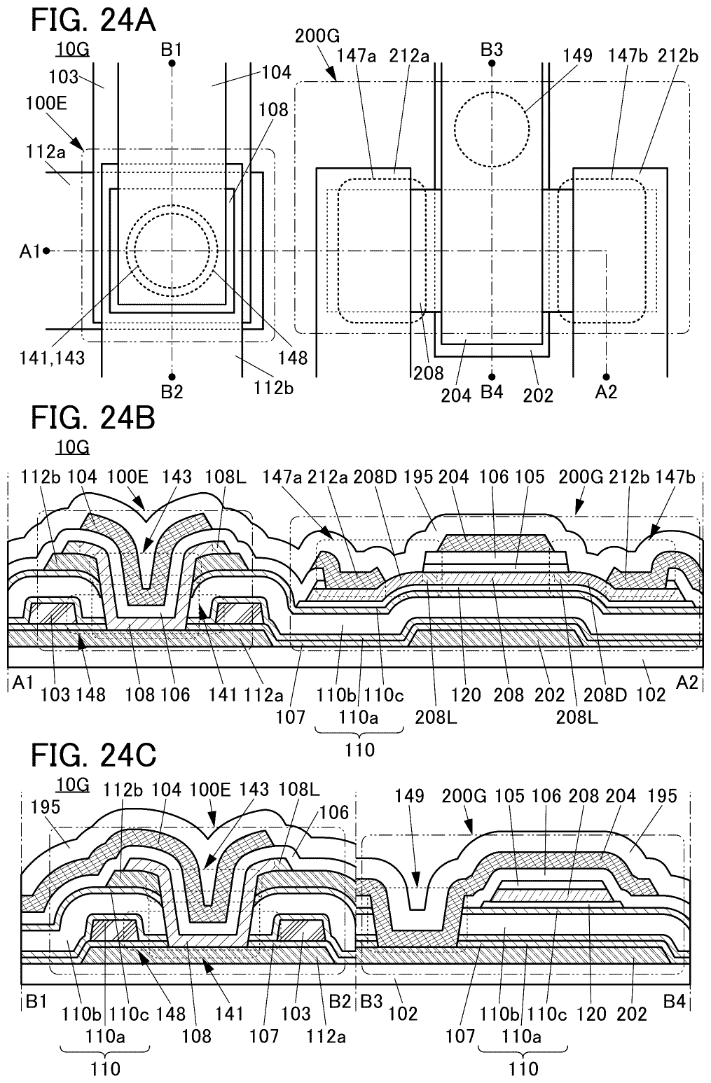

FIG. 24A is a top view of a semiconductor device 10G of one embodiment of the present invention. FIG. 24B is a cross-sectional view of a cross section along the dashed-dotted line A1-A2 in FIG. 24A, and FIG. 24C is a cross-sectional view of cross sections along the dashed-dotted line B1-B2 and the dashed-dotted line B3-B4 in FIG. 24A.

The semiconductor device 10G includes a transistor 100E and a transistor 200G. The semiconductor device 10G is different from the semiconductor device 10A illustrated in FIG. 9A and the like mainly in including a conductive layer 103 and an insulating layer 107.

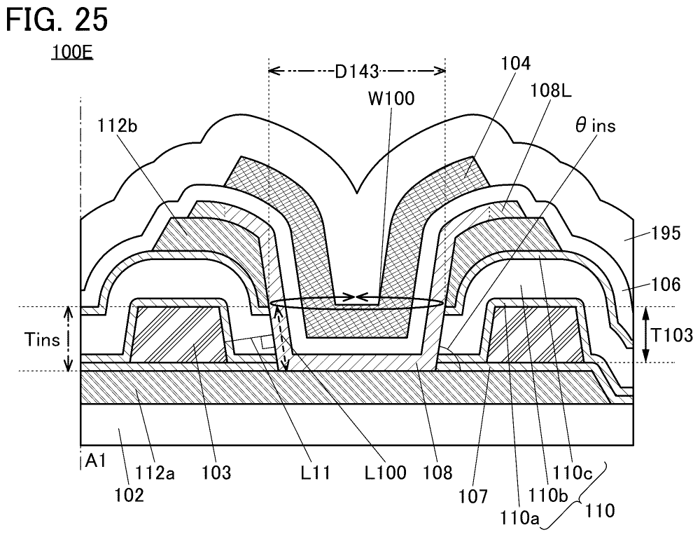

FIG. 25 is an enlarged view of the transistor 100E illustrated in FIG. 24B. The transistor 100E includes the conductive layer 103 and the insulating layer 107 between the conductive layer 112a and the insulating layer 110.

The insulating layer 107 is positioned over the conductive layer 112a. The insulating layer 107 is provided to cover the top surface and the side surface of the conductive layer 112a.

The conductive layer 103 is positioned over the insulating layer 107. The conductive layer 112a and the conductive layer 103 are electrically insulated from each other by the insulating layer 107. An opening 148 reaching the insulating layer 107 is provided in the region of the conductive layer 103 that overlaps with the conductive layer 112a.

The insulating layer 110 is provided over the insulating layer 107 and the conductive layer 103. The insulating layer 110 is provided to cover the top surface and a side surface of the conductive layer 103 and the top surface of the insulating layer 107. The opening 141 reaching the conductive layer 112a is provided in the insulating layer 110 and the insulating layer 107.

The insulating layer 110a is positioned over the insulating layer 107 and the conductive layer 103. The insulating layer 110a is provided to cover the top surface and the side surface of the conductive layer 103. The insulating layer 110a is provided to cover part of the opening 148. The insulating layer 110a is in contact with the insulating layer 107 in the opening 148.

There is no particular limitation on the top-view shape of the opening 148. The top-view shape of the opening 148 can be any of the shapes that can be used for the opening 141 and the opening 143. The top-view shapes of the opening 141, the opening 143, and the opening 148 are preferably circular as illustrated in FIG. 24A. When the top-view shapes of the openings are circular, processing accuracy at the time of formation of the openings can be high, whereby the openings can be formed to have minute sizes.

In this specification and the like, the top-view shape of the opening 148 refers to the shape of an end portion of the top surface or the bottom surface of the conductive layer 103 on the opening 148 side.

When the top-view shape of each of the opening 141 and the opening 148 is circular, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

The semiconductor layer 108 of the transistor 100 includes a region that overlaps with the conductive layer 104 with the insulating layer 106 positioned between the region and the conductive layer 104 and that overlaps with the conductive layer 103 with part (specifically, the insulating layer 110a and the insulating layer 110b) of the insulating layer 110 positioned between the region and the conductive layer 103. In other words, the semiconductor layer 108 includes a region sandwiched between the conductive layer 104 and the conductive layer 103 with the insulating layer 106 positioned between the region and the conductive layer 104 and with part (specifically, the insulating layer 110a and the insulating layer 110b) of the insulating layer 110 positioned between the region and the conductive layer 103.

The conductive layer 103 functions as a back gate electrode of the transistor 100E. Part of the insulating layer 110 functions as a back gate insulating layer of the transistor 100. For the conductive layer 103, any of the materials that can be used for the conductive layer 112a, the conductive layer 112b, the conductive layer 104, the conductive layer 202, the conductive layer 204, the conductive layer 212a, and the conductive layer 212b can be used. Note that the conductive layer 103 is not necessarily provided.

Since the transistor 100E is provided with the back gate electrode, the potential of a back channel side of the semiconductor layer 108 can be fixed, so that more favorable saturation of the I_{d}-V_{d} characteristics of the transistor 100E can be achieved.

Since the transistor 100E includes the back gate electrode, the potential of the back channel side of the semiconductor layer 108 can be fixed, so that a shift of the threshold voltage can be inhibited. When the threshold voltage shift of the transistor 100E is inhibited, the cut-off current can be reduced.

For the insulating layer 107, a material that can be used for the insulating layer 110 can be used. An insulating layer including nitrogen is preferably used as the insulating layer 107, which is in contact with the conductive layer 112a, the conductive layer 103, and the conductive layer 202. For the insulating layer 107, a material that can be used for the insulating layer 110a and the insulating layer 110c can be suitably used. For example, silicon nitride can be suitably used for the insulating layer 107. Although the insulating layer 107 has a single-layer structure in this embodiment, one embodiment of the present invention is not limited thereto. The insulating layer 107 may have a stacked-layer structure of two or more layers.

The conductive layer 103 may be electrically connected to the conductive layer 112a. The conductive layer 103 and the conductive layer 112a can be in contact with each other when, for example, an opening is provided in the region of the insulating layer 107 that overlaps with the conductive layer 112a, and the conductive layer 103 is provided to cover the opening. When the conductive layer 112a functioning as a source electrode or a drain electrode and the conductive layer 103 functioning as the back gate electrode are electrically connected to each other, the source electrode or the drain electrode can have the same potential as a gate electrode. For example, in the case where the conductive layer 112a functions as the source electrode, a shift in the threshold voltage of the transistor 100E can be inhibited. In addition, the reliability of the transistor 100E can be increased. Note that the insulating layer 107 may be omitted and the conductive layer 103 may be formed in contact with the top surface of the conductive layer 112a.

The conductive layer 103 may be electrically connected to the conductive layer 112b. The conductive layer 103 and the conductive layer 112b can be in contact with each other when, for example, an opening is provided in the region of the insulating layer 110 that overlaps with the conductive layer 103, and the conductive layer 112b is provided to cover the opening.

The conductive layer 103 may be electrically connected to the conductive layer 104. The conductive layer 103 and the conductive layer 104 can be in contact with each other when, for example, an opening is provided in the regions of the insulating layer 106 and the insulating layer 110 that overlap with the conductive layer 103, and the conductive layer 104 is provided to cover the opening. When the conductive layer 104 functioning as the gate electrode and the conductive layer 103 functioning as the back gate electrode are electrically connected to each other, the back gate electrode can have the same potential as the gate electrode, and the transistor 100E can have a high on-state current.

A thickness T103 of the conductive layer 103 is preferably greater than or equal to 0.5 times, further preferably greater than or equal to 1.0 times, still further preferably greater than 1.0 times the channel length L100, and preferably less than or equal to 2.0 times, further preferably less than or equal to 1.5 times, still further preferably less than or equal to 1.2 times the channel length L100. In that case, a sufficiently wide region of the semiconductor layer 108 can overlap with the conductive layer 104 with the insulating layer 106 provided between the region and the conductive layer 104, and overlap with the conductive layer 103 with the insulating layer 110 and the insulating layer 120 provided between the region and the conductive layer 103. As a result, the potential of the back channel side of the semiconductor layer 108 can be controlled more reliably.

The thickness T103 of the conductive layer 103 may be larger than the thickness Tins. In that case, the potential of the back channel side of the semiconductor layer 108 can be fixed in a wide range between a source region and a drain region of the semiconductor layer 108.

In a region of the transistor 100E, the conductive layer 103, the insulating layer 110, the semiconductor layer 108, the insulating layer 106, and the conductive layer 104 are stacked in this order in one direction with no any other layer provided between these layers. The one direction can be perpendicular to the channel length L100 direction. When the above region is wide, the potential of the back channel side of the semiconductor layer 108 can be controlled more reliably. The thickness T103 of the conductive layer 103 can be larger than the sum of the thickness of the portion of the semiconductor layer 108 that is in contact with the conductive layer 112a inside the opening 141 and the thickness of the insulating layer 106 that is in contact with the portion.

A distance L11, which is the shortest distance between the conductive layer 103 and the semiconductor layer 108 in a cross-sectional view, is preferably shorter than the channel length L100, further preferably less than or equal to 0.5 times the channel length L100, still further preferably less than or equal to 0.1 times the channel length L100. The shorter the distance between the conductive layer 103 and the semiconductor layer 108 is, the more favorable the saturation of the I_{d}-V_{d} characteristics of the transistor 100 can be.

In a cross-sectional view, the shortest distance between the conductive layer 103 and the semiconductor layer 108 on the left side of the opening 141 may be different from the shortest distance between the conductive layer 103 and the semiconductor layer 108 on the right side of the opening 141. In that case, the distance L11 is in the above-described range preferably on at least one of the left side and the right side of the opening 141, further preferably on both the left side and the right side of the opening 141. In a freely selected cross section, the shortest distance between the conductive layer 103 and the semiconductor layer 108 on the left side of the opening 141 is preferably greater than or equal to 50% and less than or equal to 150%, further preferably greater than or equal to 30% and less than or equal to 130%, still further preferably greater than or equal to 10% and less than or equal to 110% of the shortest distance on the right side of the opening 141.

In the transistor 200G, the insulating layer 107 is provided over the conductive layer 202, the insulating layer 110 is provided over the insulating layer 107, and the insulating layer 120 is provided over the insulating layer 110. Part of the insulating layer 107, part of the insulating layer 110, and part of the insulating layer 120 function as a back gate insulating layer of the transistor 200G.

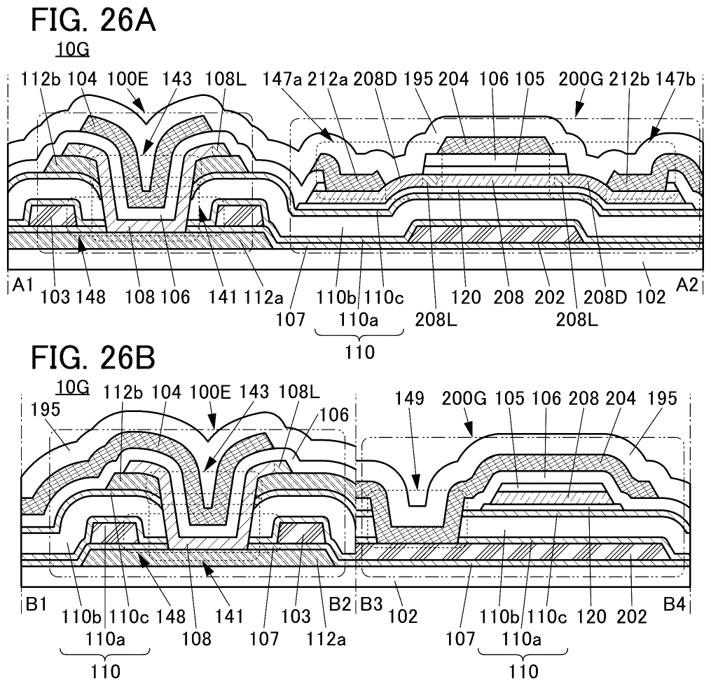

Although the insulating layer 107 is provided over the conductive layer 202 in the structure illustrated in FIG. 24B and FIG. 24C, one embodiment of the present invention is not limited thereto. As illustrated in FIG. 26A and FIG. 26B, the conductive layer 202 may be provided between the insulating layer 107 and the insulating layer 110.

The conductive layer 202 is provided over the insulating layer 107, and the insulating layer 110 is provided over the conductive layer 202. The insulating layer 110 is in contact with the top surface and the side surface of the conductive layer 202.

The conductive layer 202 can be formed using the same material as the conductive layer 103. The conductive layer 202 can be formed through the same process as the conductive layer 103. For example, the conductive layer 202 and the conductive layer 103 can be formed by forming and processing a conductive film to be the conductive layer 202 and the conductive layer 103.

Note that the structures of the conductive layer 103 and the insulating layer 107 described in Structure example 9 can also be applied to other structure examples.

### Structure Example 10

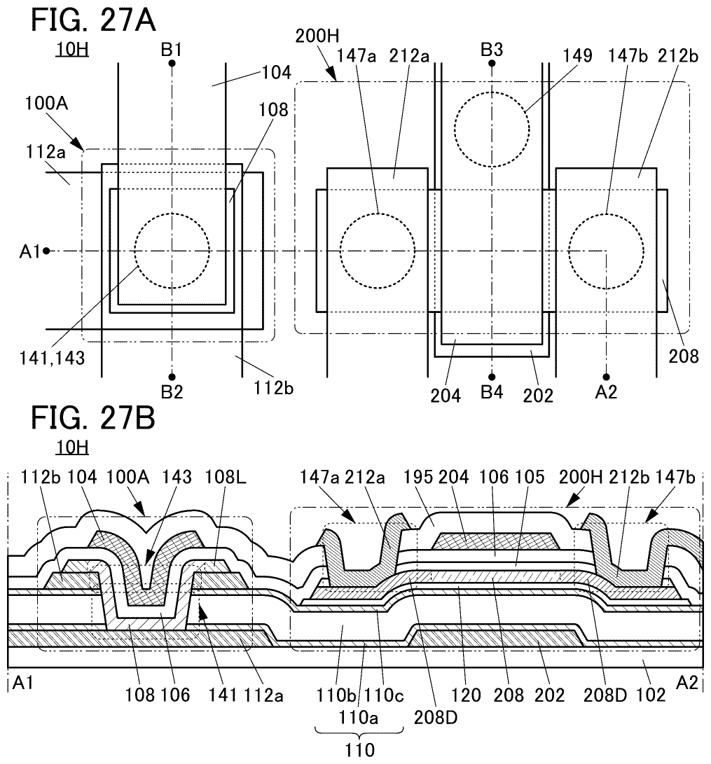

FIG. 27A is a top view of a semiconductor device 10H of one embodiment of the present invention. FIG. 27B is a cross-sectional view of a cross section along the dashed-dotted line A1-A2 in FIG. 27A. FIG. 9B can be referred to for a cross-sectional view of cross sections along the dashed-dotted line B1-B2 and the dashed-dotted line B3-B4.

The semiconductor device 10H includes the transistor 100A and the transistor 200H. The semiconductor device 10H is different from the semiconductor device 10A illustrated in FIG. 9A and the like mainly in the structures of the conductive layer 212a and the conductive layer 212b.

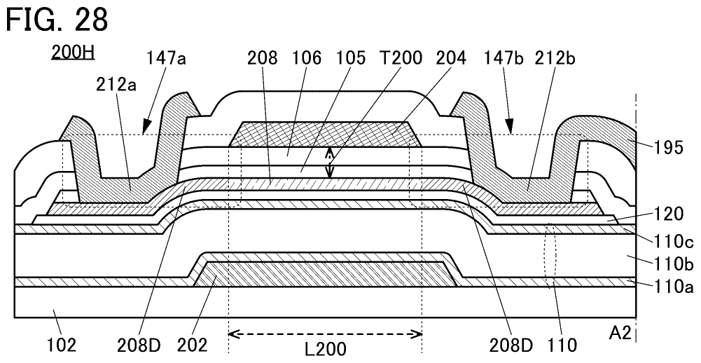

FIG. 28 is an enlarged view of the transistor 200H illustrated in FIG. 27A and FIG. 27B. In the transistor 200H, the conductive layer 212a and the conductive layer 212b are provided to cover the opening 147a and the opening 147b provided in the insulating layer 106 and the insulating layer 195. The conductive layer 212a and the conductive layer 212b are formed in steps different from those for the conductive layer 104 and the conductive layer 204. Note that the conductive layer 212a and the conductive layer 212b may be formed using the same material as the conductive layer 104 and the conductive layer 204 or may be formed using a material different from that for the conductive layer 104 and the conductive layer 204.

For example, the conductive layer 204 can be formed over the insulating layer 106, the insulating layer 195 can be formed over the conductive layer 204, the opening 147a and the opening 147b can be formed in the insulating layer 106 and the insulating layer 195, and the conductive layer 212a and the conductive layer 212b can be formed to cover the opening 147a and the opening 147b. When the conductive layer 212a and the conductive layer 212b are provided on a plane different from a plane on which the conductive layer 204 is provided, the layout flexibility can be increased.

The regions 208D are provided in the regions of the semiconductor layer 208 that do not overlap with the conductive layer 204. The regions 208D can be formed by adding an impurity element to the semiconductor layer 208 using the conductive layer 204 as a mask after formation of the conductive layer 204, for example. The impurity element is added to the regions of the semiconductor layer 208 that do not overlap with the conductive layer 204, through the insulating layer 106. The opening 147a and the opening 147b are provided in regions overlapping with the regions 208D, and the conductive layer 212a and the conductive layer 212b are in contact with the regions 208D in the opening 147a and the opening 147b. There is no particular limitation on the top-view shapes of the opening 147a and the opening 147b.

When the regions 208D are formed by adding the impurity element to the semiconductor layer 208, the impurity element may be supplied to the semiconductor layer 108 through the insulating layer 106 with the use of the conductive layer 104 as a mask. In that case, the region 108L is formed in the region of the semiconductor layer 108 that does not overlap with the conductive layer 104.

The above description can be referred to for the transistor 100A; thus, the detailed description thereof is omitted.

Note that the structures of the conductive layer 212a and the conductive layer 212b described in Structure example 10 can also be applied to other structure examples.

Although the semiconductor devices given as examples in Structure example 1 to Structure example 10 above each include one of the transistor 100 to the transistor 100E that are VFETs and one of the transistor 200 to the transistor 200H with a planar structure, one embodiment of the present invention is not limited thereto. Any two or more of the transistor 100 to the transistor 100E and the transistor 200 to the transistor 200H can be combined with each other. For example, a semiconductor device can include two or more of the transistor 100 to the transistor 100E that are VFETs.

### Structure Example 11

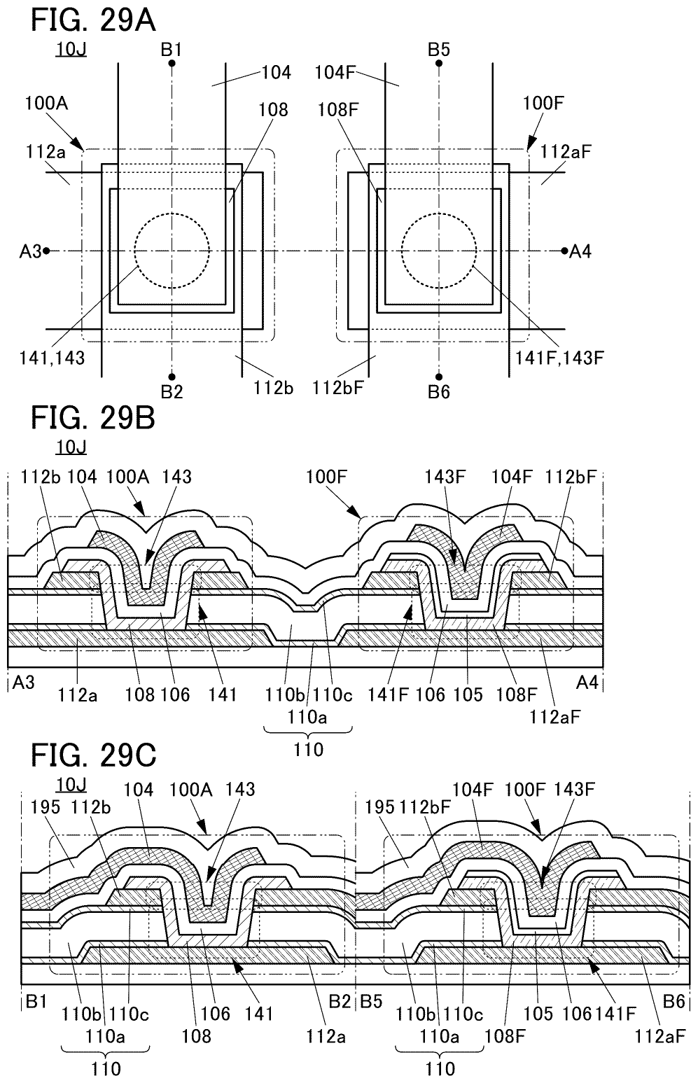

FIG. 29A is a top view of a semiconductor device 10J of one embodiment of the present invention. FIG. 29B is a cross-sectional view of a cross section along the dashed-dotted line A3-A4 in FIG. 29A, and FIG. 29C is a cross-sectional view of cross sections along the dashed-dotted line B1-B2 and the dashed-dotted line B5-B6 in FIG. 29A.

The semiconductor device 10J includes the transistor 100A and a transistor 100F. The semiconductor device 10J is different from the semiconductor device 10A illustrated in FIG. 9A and the like mainly in including the transistor 100F that is a VFET instead of the transistor 200A with a planar structure.

The transistor 100A illustrated in FIG. 29B and FIG. 29C has a structure similar to that of the transistor 100A illustrated in FIG. 9A and FIG. 9B except that the region 108L is not provided. Note that the transistor 100A may include the region 108L.

The transistor 100F includes a conductive layer 112aF, the insulating layer 110, a semiconductor layer 108F, a conductive layer 112bF, the insulating layer 106, and a conductive layer 104F. The transistor 100F corresponds to the transistor 100D illustrated in FIG. 21A and FIG. 21B. For the conductive layer 112aF, the conductive layer 112bF, the conductive layer 104F, the semiconductor layer 108F, an opening 141F, and an opening 143F of the transistor 100F, the description of the conductive layer 112a, the conductive layer 112b, the conductive layer 104, the semiconductor layer 108, the opening 141, and the opening 143 of the transistor 100D can be referred to. In the structure illustrated in FIG. 29B and FIG. 29C, the transistor 100F does not include the region 108L. Note that the transistor 100F may include the region 108L.

Some steps can be shared in forming the transistor 100A and the transistor 100F. Specifically, the conductive layer 112a and the conductive layer 112aF can be formed in the same process. The conductive layer 112b and the conductive layer 112bF can be formed in the same process. The conductive layer 104 and the conductive layer 104F can be formed in the same process.

The semiconductor layer 108 and the semiconductor layer 108F are formed in different processes. Thus, the material used for the semiconductor layer 108 and the material used for the semiconductor layer 108F can be different from each other. For example, in the case where the first metal oxide is used for the semiconductor layer 108 and the second metal oxide is used for the semiconductor layer 108F, the content percentage of indium in the first metal oxide can be higher than the content percentage of indium in the second metal oxide. In that case, the transistor 100A can have a higher on-state current. More favorable saturation of the I_{d}-V_{d} characteristics of the transistor 100F can be achieved. Alternatively, the content percentage of indium in the second metal oxide may be higher than the content percentage of indium in the first metal oxide. In that case, the transistor 100F can have a higher on-state current. More favorable saturation of the I_{d}-V_{d} characteristics of the transistor 100A can be achieved. Note that the semiconductor layer 108 and the semiconductor layer 108F may be formed using the same material. The semiconductor layer 108 and the semiconductor layer 108F may be different in at least one of the thickness, crystallinity, carrier concentration, and film quality. One of the semiconductor layer 108 and the semiconductor layer 108F may have a single-layer structure and the other may have a stacked-layer structure.

As illustrated in FIG. 29A and the like, a gate insulating layer of the transistor 100F has a stacked-layer structure of the insulating layer 105 and the insulating layer 106. Meanwhile, a gate insulating layer of the transistor 100A has a single-layer structure of the insulating layer 106. With such a structure, the thickness of the gate insulating layer can be different between the transistor 100A and the transistor 100F. Specifically, the thickness of the gate insulating layer of the transistor 100F can be larger than that of the gate insulating layer of the transistor 100A. Thus, the gate breakdown voltage of the transistor 100F can be increased. The transistor 100A can have a higher on-state current and a higher operation speed.

Since the common insulating layer 110 is sandwiched between the conductive layer 112a and the conductive layer 112b in the transistor 100A and is sandwiched between the conductive layer 112aF and the conductive layer 112bF in the transistor 100F, the channel length of the transistor 100A and the channel length of the transistor 100F are the same or substantially the same. When the opening 143 and the opening 143F have the same top-view shape and the same size, the channel width of the transistor 100A and the channel width of the transistor 100F can be the same or substantially the same. Note that the transistor 100A and the transistor 100F may have different channel widths by making the opening 143 and the opening 143F different in one or both of the top-view shape and the size.

This embodiment can be combined with the other embodiments as appropriate. In this specification, in the case where a plurality of structure examples are shown in one embodiment, the structure examples can be combined as appropriate.

### Embodiment 2

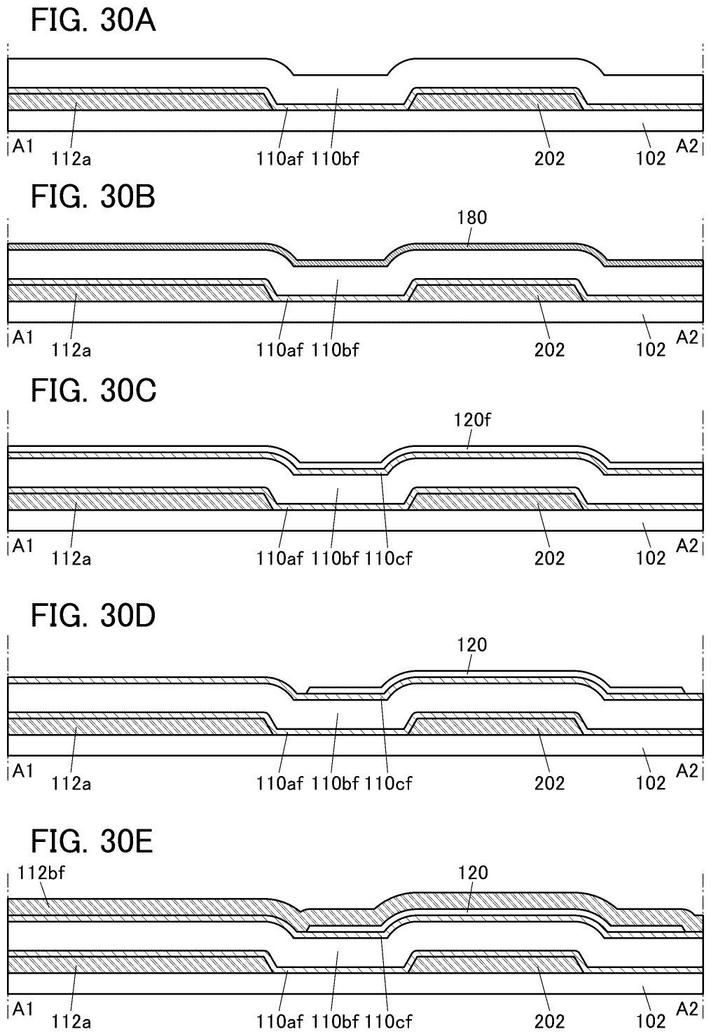

In this embodiment, a method for manufacturing the semiconductor device of one embodiment of the present invention will be described with reference to FIG. 30 to FIG. 44. Note that as for a material and a formation method of each component, portions similar to those described in Embodiment 1 are not described in some cases.

Thin films included in the semiconductor device (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. An example of the thermal CVD method is a metal organic chemical vapor deposition (MOCVD: Metal Organic CVD) method.

Thin films included in the semiconductor device (e.g., insulating films, semiconductor films, and conductive films) can be formed by a wet film-formation method such as spin coating, dipping, spray coating, ink-jetting, dispensing, screen printing, offset printing, a doctor knife method, slit coating, roll coating, curtain coating, or knife coating.

To process the thin films included in the semiconductor device, a photolithography method or the like can be used. Alternatively, a nanoimprinting method, a sandblasting method, a lift-off method, or the like may be used for the processing of the thin films. Island-shaped thin films may be directly formed by a film formation method using a blocking mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is formed and then the thin film is processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. In addition, light exposure may be performed by liquid immersion exposure technique. As the light used for the light exposure, extreme ultraviolet (EUV) light, X-rays, or the like may be used. Instead of the light used for light exposure, an electron beam can be used. Extreme ultraviolet light, X-rays, or an electron beam is preferably used to perform extremely minute processing. Note that in the case of performing light exposure by scanning of a beam such as an electron beam, a photomask is not needed.

For etching of the thin film, a dry etching method, a wet etching method, a sandblasting method, or the like can be used.

### Manufacturing Method Example 1

A manufacturing method is described below using the semiconductor device 10A in FIG. 9A and the like as an example.

Each of FIG. 30A to FIG. 33C is a diagram illustrating the method for manufacturing the semiconductor device 10A. Each diagram is a cross-sectional view taken along the dashed-dotted line A1-A2.

First, the conductive layer 112a and the conductive layer 202 are formed over the substrate 102, and an insulating film 110af to be the insulating layer 110a and an insulating film 110bf to be the insulating layer 110b are formed over the conductive layer 112a and the conductive layer 202 (FIG. 30A).

For the formation of the conductive film to be the conductive layer 112a and the conductive layer 202, a sputtering method can be suitably used, for example. The conductive layer 112a and the conductive layer 202 can be formed in the following manner: a resist mask is formed over the conductive film by a photolithography process and then, the conductive film is processed.

For the formation of the insulating film 110af and the insulating film 110bf, a sputtering method or a PECVD method can be suitably used, for example. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, the transistor can have favorable electrical characteristics and high reliability.

After the formation of the insulating film 110bf, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide.

Note that the plasma treatment may be successively performed in a vacuum without exposure of a surface of the insulating film 110bf to the air. For example, in the case where a PECVD apparatus is used to form the insulating film 110bf, the plasma treatment is preferably performed with the PECVD apparatus. In that case, the productivity can be increased. Next, a metal oxide layer 180 is preferably formed over the insulating film 110bf (FIG. 30B). The formation of the metal oxide layer 180 enables oxygen supply to the insulating film 110bf.

There is no limitation on the conductivity of the metal oxide layer 180. For the metal oxide layer 180, at least one of an insulating film, a semiconductor film, and a conductive film can be used. For the metal oxide layer 180, aluminum oxide, hafnium oxide, hafnium aluminate, indium oxide, indium tin oxide (ITO), or indium tin oxide containing silicon (ITSO) can be used, for example.

An oxide material containing one or more elements that are the same as those in the semiconductor layer 108 and the semiconductor layer 208 is preferably used for the metal oxide layer 180. It is particularly preferable to use an oxide semiconductor material that can be used for the semiconductor layer 108 and the semiconductor layer 208.

At the time of forming the metal oxide layer 180, a larger amount of oxygen can be supplied into the insulating film 110af when the oxygen flow rate ratio of the film formation gas introduced into a treatment chamber of a film formation apparatus or the oxygen partial pressure in the treatment chamber is higher. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 180 is formed by a sputtering method in an oxygen-containing atmosphere in the above manner, oxygen can be supplied to the insulating film 110bf and release of oxygen from the insulating film 110bf can be prevented during the formation of the metal oxide layer 180. As a result, a large amount of oxygen can be enclosed in the insulating film 110bf. Moreover, a large amount of oxygen can be supplied to the semiconductor layer 108 by heat treatment performed later. As a result, the amounts of oxygen vacancy and V_{O}H in the semiconductor layer 108 can be reduced, so that a highly reliable transistor exhibiting favorable electrical characteristics can be obtained.

After the metal oxide layer 180 is formed, heat treatment may be performed. By the heat treatment performed after the formation of the metal oxide layer 180, oxygen can be effectively supplied from the metal oxide layer 180 to the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point lower than or equal to −60° C., preferably lower than or equal to −100° C. is preferably used. With the use of an atmosphere where the content of hydrogen, water, or the like is as low as possible, entry of hydrogen, water, or the like into the insulating film 110bf can be prevented as much as possible. An oven, a rapid thermal annealing (RTA) apparatus, or the like can be used for the heat treatment. The use of the RTA apparatus can shorten the heat treatment time.

After the formation of the metal oxide layer 180 or after the above-described heat treatment, oxygen may be further supplied to the insulating film 110bf through the metal oxide layer 180. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 180 is removed. There is no particular limitation on a method for removing the metal oxide layer 180, and wet etching can be suitably used. With the use of a wet etching method, the insulating film 110bf can be inhibited from being etched during the removal of the metal oxide layer 180. This can inhibit a reduction in the thickness of the insulating film 110bf, and the thickness of the insulating layer 110a can be uniform.

The treatment for supplying oxygen to the insulating film 110bf is not necessarily performed in the above-described manner. An oxygen radical, an oxygen atom, an oxygen atomic ion, an oxygen molecular ion, or the like is supplied to the insulating film 110bf by an ion doping method, an ion implantation method, plasma treatment, or the like. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, an insulating film 110cf to be the insulating layer 110c and an insulating film 120f to be the insulating layer 120 are formed over the insulating film 110bf (FIG. 30C).

For the formation of the insulating film 110cf and the insulating film 120f, a sputtering method or a PECVD method can be suitably used, for example. It is preferable that the insulating film 120f be formed in a vacuum successively after the formation of the insulating film 110cf, without exposure of a surface of the insulating film 110cf to the air. By forming the insulating film 110cf and the insulating film 120f successively, attachment of impurities derived from the air to the surface of the insulating film 110cf can be inhibited.

Next, the insulating film 120f is processed to form the insulating layer 120 (FIG. 30D). The insulating layer 120 is provided in a region where the semiconductor layer 208 is to be provided. A dry etching method can be suitably used for the formation of the insulating layer 120.

In the case where the insulating film 120f is not processed, the transistor 100 and the transistor 200 illustrated in FIG. 1B and the like can be formed.

Then, a conductive film 112bf to be the conductive layer 112b is formed over the insulating film 110cf and the insulating layer 120 (FIG. 30E). For the formation of the conductive film 112bf, a sputtering method can be suitably used, for example.

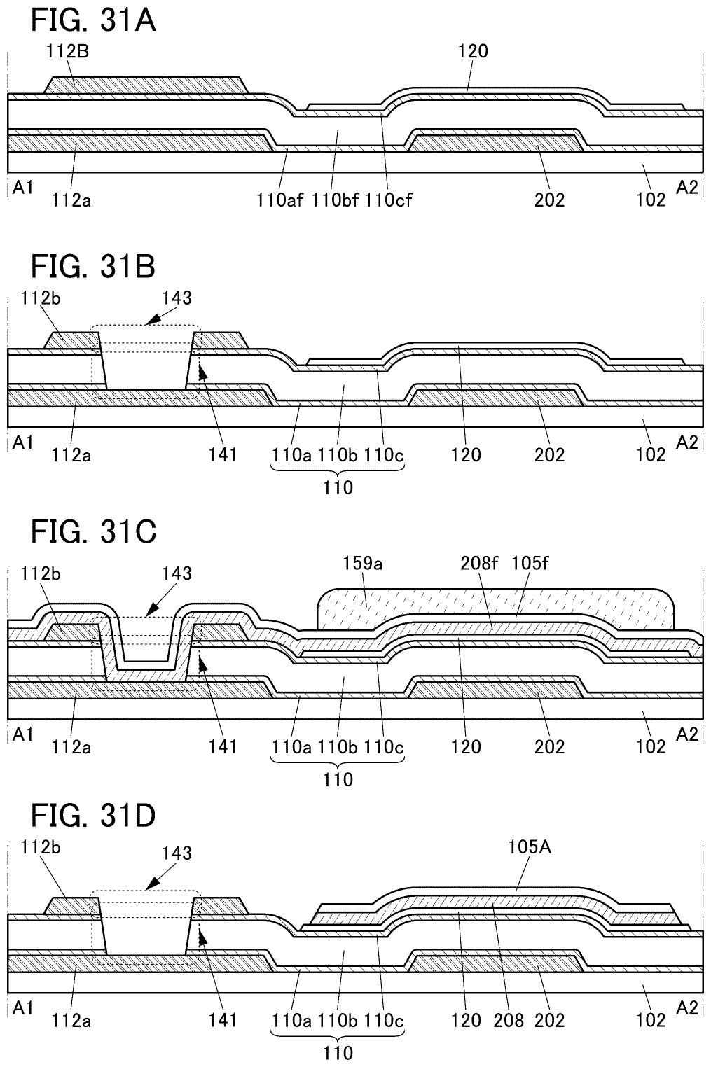

Next, the conductive film 112bf is processed to form a conductive layer 112B (FIG. 31A). The conductive layer 112B becomes the conductive layer 112b later. For the formation of the conductive layer 112B, a wet etching method can be suitably used, for example.

Next, part of the conductive layer 112B is removed, so that the conductive layer 112b having the opening 143 is formed. For the formation of the conductive layer 112b, a wet etching method can be suitably used.

Next, part of the insulating film 110af, part of the insulating film 110bf, and part of the insulating film 110cf are removed, so that the insulating layer 110 including the opening 141 is formed (FIG. 31B). The opening 141 is provided in a region overlapping with the opening 143. The conductive layer 112a is exposed by the formation of the opening 141. A dry etching method can be suitably used for the formation of the insulating layer 110.

The opening 141 can be formed using a resist mask used for the formation of the opening 143, for example. Specifically, the resist mask is formed over the conductive layer 112B, part of the conductive layer 112B is removed with the use of the resist mask to form the opening 143, and part of the insulating film 110af, part of the insulating film 110bf, and part of the insulating film 110cf are removed with the use of the resist mask, so that the opening 141 can be formed. The opening 141 may be formed using a resist mask that is different from the resist mask used for the formation of the opening 143.

Note that in the formation of the opening 141 or after the formation of the opening 141, part of the conductive layer 112a in a region overlapping with the opening 141 may be removed. When the thickness of the region of the conductive layer 112a that is in contact with the bottom surface of the semiconductor layer 108 is smaller than the thickness of the region of the conductive layer 112a that is not in contact with the semiconductor layer 108, the electric field of the gate electrode applied to the channel formation region in the vicinity of the conductive layer 112a can be intensified, leading to a high on-state current of the transistor.

Next, a metal oxide film 208f to be the semiconductor layer 208 is formed, an insulating film 105f to be the insulating layer 105 is formed over the metal oxide film 208f, and a resist mask 159a is formed over the insulating film 105f (FIG. 31C). The resist mask 159a is provided in a region overlapping with the insulating layer 120. An end portion of the resist mask 159a is preferably provided over the insulating layer 120. The metal oxide film 208f is provided in contact with the top surface and the side surface of the conductive layer 112b, the top surface and the side surface of the insulating layer 120, the top surface and the side surface of the insulating layer 110, and the top surface of the conductive layer 112a.

The metal oxide film 208f is preferably formed by a sputtering method using a metal oxide target. Alternatively, the metal oxide film 208f is preferably formed by an ALD method.

The metal oxide film 208f is preferably a dense film having as few defects as possible. The metal oxide film 208f is preferably a high-purity film in which impurities including a hydrogen element are reduced as much as possible. It is particularly preferable to use a metal oxide film having crystallinity as the metal oxide film 208f.

In forming the metal oxide film 208f, an oxygen gas is preferably used. In the case of using an oxygen gas at the time of forming the metal oxide film 208f, oxygen can be suitably supplied into the insulating layer 110 and the insulating layer 120. For example, in the case of using an oxide or an oxynitride for the insulating layer 110b and the insulating layer 120, oxygen can be suitably supplied into the insulating layer 110b.

By the supply of oxygen to the insulating layer 110b, oxygen is supplied to the semiconductor layer 108 in a later step, so that the amounts of oxygen vacancy and V_{O}H in the semiconductor layer 108 can be reduced. Similarly, by the supply of oxygen to the insulating layer 120, oxygen is supplied to the semiconductor layer 208 in a later step, so that the amounts of oxygen vacancy and V_{O}H in the semiconductor layer 208 can be reduced.

In forming the metal oxide film 208f, an oxygen gas and an inert gas (e.g., a helium gas, an argon gas, or a xenon gas) may be mixed. Note that when the oxygen flow rate ratio of the film formation gas or the oxygen partial pressure in the treatment chamber is higher at the time of forming the metal oxide film, the crystallinity of the metal oxide film can be higher and the transistor can have higher reliability. On the other hand, when the oxygen flow rate ratio or the oxygen partial pressure is lower, the crystallinity of the metal oxide film is lower and the transistor can have a higher on-state current. For example, with the use of different oxygen flow rate ratios or different oxygen partial pressures, a stacked-layer structure of two or more metal oxide layers having different crystallinities can be formed.

When the substrate temperature is higher at the time of forming the metal oxide film, the metal oxide film can have higher crystallinity and can be denser. On the other hand, when the substrate temperature is lower, the metal oxide film can have lower crystallinity and higher electric conductivity.

The substrate temperature at the time of forming the metal oxide film 208f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably higher than or equal to room temperature and lower than or equal to 140° C., in which case high productivity is achieved. Furthermore, when the metal oxide film is formed with the substrate temperature set at room temperature or without heating the substrate, the crystallinity can be made low.

In the case of employing an ALD method for the formation of the metal oxide film 208f, a film formation method such as a thermal ALD method or a plasma enhanced ALD (PEALD) method is preferably employed. A thermal ALD method is preferable because of its capability of forming a film with extremely high step coverage. A PEALD method is preferable because of its capability of forming a film at low temperatures, in addition to its capability of forming a film with high step coverage.

The metal oxide film can be formed by an ALD method using an oxidizing agent and a precursor that contains a metal element to constitute the metal oxide film, for example.

For example, In—Ga—Zn oxide can be formed using three precursors of a precursor containing indium, a precursor containing gallium, and a precursor containing zinc. Alternatively, two precursors of a precursor containing indium and a precursor containing gallium and zinc may be used.

As examples of the precursor containing indium, triethylindium, tris(2,2,6,6-tetramethyl-3,5-heptanedionato)indium, cyclopentadienylindium, indium(III) chloride, and (3-(dimethylamino)propyl) dimethylindium can be given.

As examples of the precursor containing gallium, trimethylgallium, triethylgallium, tris(dimethylamido)gallium(III), gallium(III)acetylacetonate, tris(2,2,6,6-tetramethyl-3,5-heptanedionato)gallium, dimethylchlorogallium, diethylchlorogallium, and gallium(III) chloride can be given.

As examples of the precursor containing zinc, dimethylzinc, diethylzinc, bis(2,2,6,6-tetramethyl-3,5-heptanedionato) zinc, and zinc chloride can be given.

As examples of the oxidizing agent, ozone, oxygen, and water can be given.

As an example of a method for controlling the composition of a film to be formed, adjusting one or more of the kinds of source gases, the flow rate ratio between the source gases, the flowing time of the source gases, and the order in which the source gases flow is given. By adjusting such conditions, a film whose composition is continuously changed can be formed. Furthermore, films having different compositions can be formed successively.

Note that in the case where the semiconductor layer 208 has a stacked-layer structure, it is preferable that after the metal oxide film formed earlier is formed, the next metal oxide film be formed successively without exposure of a surface of the metal oxide film formed earlier to the air.

Before the formation of the metal oxide film 208f, at least one of treatment for desorbing water, hydrogen, an organic substance, and the like adsorbed on surfaces of the insulating layer 110 and the insulating layer 120, and treatment for supplying oxygen into the insulating layer 110 and the insulating layer 120 is preferably performed. For example, heat treatment can be performed at a temperature higher than or equal to 70° C. and lower than or equal to 200° C. in a reduced-pressure atmosphere. Alternatively, plasma treatment in an oxygen-containing atmosphere may be performed. Alternatively, oxygen may be supplied to the insulating layer 110 and the insulating layer 120 by performing plasma treatment in an atmosphere containing an oxidizing gas such as dinitrogen monoxide (N₂O). When plasma treatment is performed using a dinitrogen monoxide gas, an organic substance on the surfaces of the insulating layer 110 and the insulating layer 120 can be favorably removed and oxygen can be supplied to the insulating layer 110 and the insulating layer 120. The metal oxide film 208f is preferably formed successively after such treatment without exposure of the surfaces of the insulating layer 110 and the insulating layer 120 to the air.

Next, the insulating film 105f and the metal oxide film 208f are processed into island shapes using the resist mask 159a as a mask to form an insulating layer 105A and the semiconductor layer 208. For example, a dry etching method can be suitably used for the formation of the insulating layer 105A, and a wet etching method can be suitably used for the formation of the semiconductor layer 208. Note that the insulating layer 105A and the semiconductor layer 208 may be formed by different methods or the same method.

When the insulating layer 105A and the semiconductor layer 208 are formed in the same process, the end portion of the semiconductor layer 208 and the end portion of the insulating layer 105 can be aligned or substantially aligned with each other. As illustrated in FIG. 7B and FIG. 7C, the end portion of the semiconductor layer 208 is not necessarily aligned with the end portion of the insulating layer 105.

In the case where the formation of the insulating layer 105A and the semiconductor layer 208 is accompanied by removal of the insulating layer 120 in a region not overlapping with the resist mask 159a, the transistor 200C illustrated in FIG. 15A and the like can be formed.

Next, the resist mask 159a is removed (FIG. 31D).

It is preferable that heat treatment be performed after the metal oxide film 208f is formed, after the insulating film 120f is formed, or after the metal oxide film 208f is processed into the semiconductor layer 208. By the heat treatment, hydrogen or water contained in the metal oxide film 208f or the semiconductor layer 208 or adsorbed onto a surface thereof can be removed. Furthermore, the film quality of the metal oxide film 208f or the semiconductor layer 208 is improved (e.g., the number of defects is reduced or the crystallinity is increased) by the heat treatment in some cases.

Oxygen can be supplied from the insulating layer 110b and the insulating layer 120 to the metal oxide film 208f or the semiconductor layer 208 by heat treatment. Here, it is further preferable that the heat treatment be performed after the metal oxide film 208f is formed but before the metal oxide film 208f is processed into the semiconductor layer 208. In that case, the area of the region where the insulating layer 120 and the metal oxide film 208f are in contact with each other can be increased, so that oxygen can be effectively supplied from the insulating layer 120 to the metal oxide film 208f. The above description can be referred to for the heat treatment; thus, the detailed description thereof is omitted.

Note that the heat treatment is not necessarily performed. The heat treatment in this step may be omitted, and heat treatment performed in a later step may also serve as the heat treatment in this step. In some cases, treatment at a high temperature in a later step (e.g., a film formation step) can serve as the heat treatment.

Although the semiconductor layer 208 and the insulating layer 105A are formed after the opening 141 and the opening 143 are formed in the example described here, one embodiment of the present invention is not limited thereto. The opening 141 and the opening 143 may be formed after the semiconductor layer 208 and the insulating layer 105A are formed.

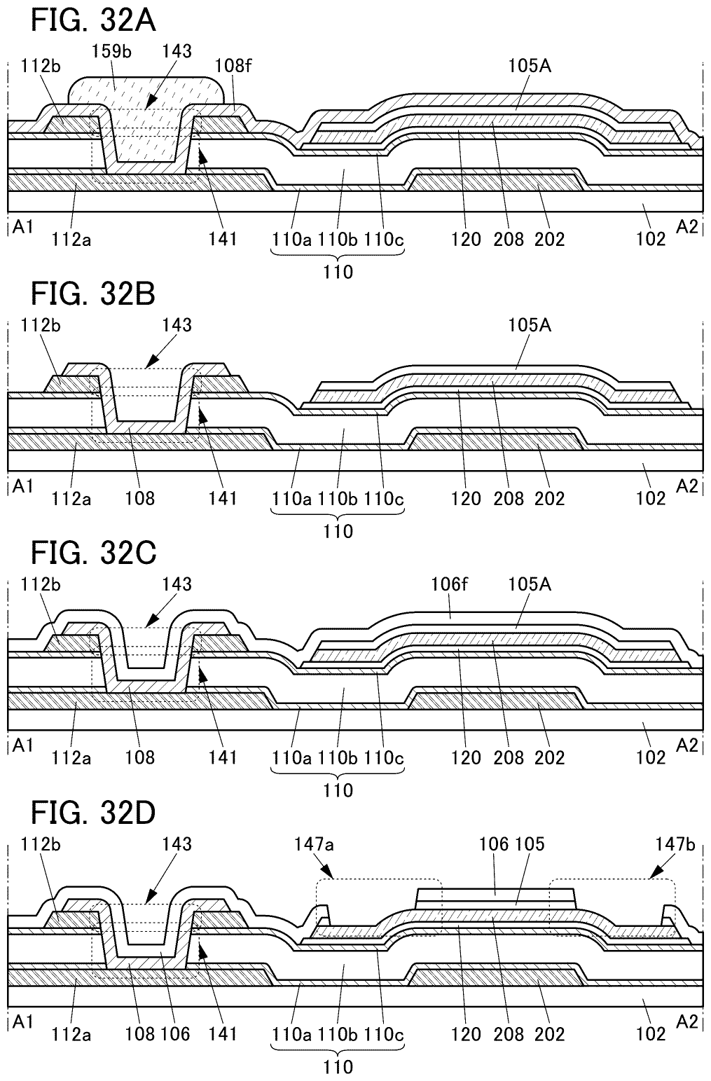

Next, a metal oxide film 108f to be the semiconductor layer 108 is formed to cover the opening 141 and the opening 143, and a resist mask 159b is formed over the metal oxide film 108f (FIG. 32A). The resist mask 159b is provided to cover at least the opening 141 and the opening 143. The metal oxide film 108f is provided in contact with the top surface and the side surface of the conductive layer 112b, the top surface and a side surface of the insulating layer 105A, the top surface and the side surface of the insulating layer 110, and the top surface of the conductive layer 112a.

In forming the metal oxide film 108f, an oxygen gas is preferably used. In the case of using an oxygen gas at the time of forming the metal oxide film 108f, oxygen can be suitably supplied into the insulating layer 110 and the insulating layer 105A. For example, in the case of using an oxide or an oxynitride for the insulating layer 110b and the insulating layer 105A, oxygen can be suitably supplied into the insulating layer 110b and the insulating layer 105A.

By the supply of oxygen to the insulating layer 110b, oxygen is supplied to the semiconductor layer 108 in a later step, so that the amounts of oxygen vacancy and V_{O}H in the semiconductor layer 108 can be reduced. Similarly, by the supply of oxygen to the insulating layer 105A, oxygen is supplied to the semiconductor layer 208 in a later step, so that the amounts of oxygen vacancy and V_{O}H in the semiconductor layer 208 can be reduced. The description of the formation of the metal oxide film 208f can be referred to for the formation of the metal oxide film 108f.

Subsequently, the metal oxide film 108f is processed into an island shape using the resist mask 159b as a mask to form the semiconductor layer 108. For the formation of the semiconductor layer 108, a wet etching method can be suitably used.

Next, the resist mask 159b is removed (FIG. 32B).

It is preferable that heat treatment be performed after the metal oxide film 108f is formed or after the metal oxide film 108f is processed into the semiconductor layer 108. By the heat treatment, hydrogen or water contained in the metal oxide film 108f or the semiconductor layer 108 or adsorbed onto a surface thereof can be removed. Furthermore, the film quality of the metal oxide film 108f or the semiconductor layer 108 is improved (e.g., the number of defects is reduced or the crystallinity is increased) by the heat treatment in some cases.

Oxygen can be supplied from the insulating layer 110b to the metal oxide film 108f or the semiconductor layer 108 by heat treatment. Here, it is further preferable that the heat treatment be performed after the metal oxide film 108f is formed but before the metal oxide film 108f is processed into the semiconductor layer 108. For the heat treatment, the above description can be referred to.

Note that the heat treatment is not necessarily performed. The heat treatment in this step may be omitted, and heat treatment performed in a later step may also serve as the heat treatment in this step. In some cases, treatment at a high temperature in a later step (e.g., a film formation step) can serve as the heat treatment.

Next, an insulating film 106f to be the insulating layer 106 is formed to cover the semiconductor layer 108, the semiconductor layer 208, the conductive layer 112b, the insulating layer 105A, the insulating layer 120, and the insulating layer 110 (FIG. 32C). For the formation of the insulating film 106f, a PECVD method or an ALD method can be suitably used, for example.

In the case of using an oxide semiconductor for the semiconductor layer 108, the insulating layer 106 preferably functions as a barrier film that inhibits diffusion of oxygen. The insulating layer 106 having a function of inhibiting diffusion of oxygen inhibits diffusion of oxygen to the conductive layer 104 from above the insulating layer 106 and thus can inhibit oxidation of the conductive layer 104. Consequently, the transistor can have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

When the temperature at the time of forming the insulating film 106f to be the insulating layer 106 functioning as the gate insulating layer is increased, defects in the insulating layer can be reduced. However, the high temperature at the time of forming the insulating film 106f sometimes allows release of oxygen from the semiconductor layer 108 and the semiconductor layer 208, which increases the amounts of oxygen vacancy and V_{O}H in the semiconductor layer 108 and the semiconductor layer 208 in some cases. The substrate temperature at the time of forming the insulating film 106f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 106f is in the above range, release of oxygen from the semiconductor layer 108 and the semiconductor layer 208 can be inhibited while the defects in the insulating layer 106 can be reduced. Consequently, the transistors can have favorable electrical characteristics and high reliability.

Before the formation of the insulating film 106f, the semiconductor layer 108, the side surface of the semiconductor layer 208, and a surface of the insulating layer 105A may be subjected to plasma treatment. By the plasma treatment, an impurity such as water adsorbed on the semiconductor layer 108, the side surface of the semiconductor layer 208, and the surface of the insulating layer 105A can be reduced. Accordingly, impurities at the interface between the semiconductor layer 108 and the insulating layer 106, the interface between the semiconductor layer 208 and the insulating layer 106, and the interface between the insulating layer 105A and the insulating layer 106 can be reduced, enabling formation of highly reliable transistors. The plasma treatment is particularly favorable in the case where a surface of the semiconductor layer 108 is exposed to the air after the formation of the semiconductor layer 108 but before the formation of the insulating layer 106. The plasma treatment can be performed in an atmosphere of oxygen, ozone, nitrogen, dinitrogen monoxide, argon, or the like. The plasma treatment and the formation of the insulating film 106f are preferably performed successively without exposure to the air.

Next, the insulating film 106f and the insulating layer 105A are processed to form the insulating layer 106 and the insulating layer 105 (FIG. 32D). The opening 147a and the opening 147b reaching the semiconductor layer 208 are provided in the insulating layer 106 and the insulating layer 105. A dry etching method can be suitably used for the formation of the insulating layer 106 and the insulating layer 105.

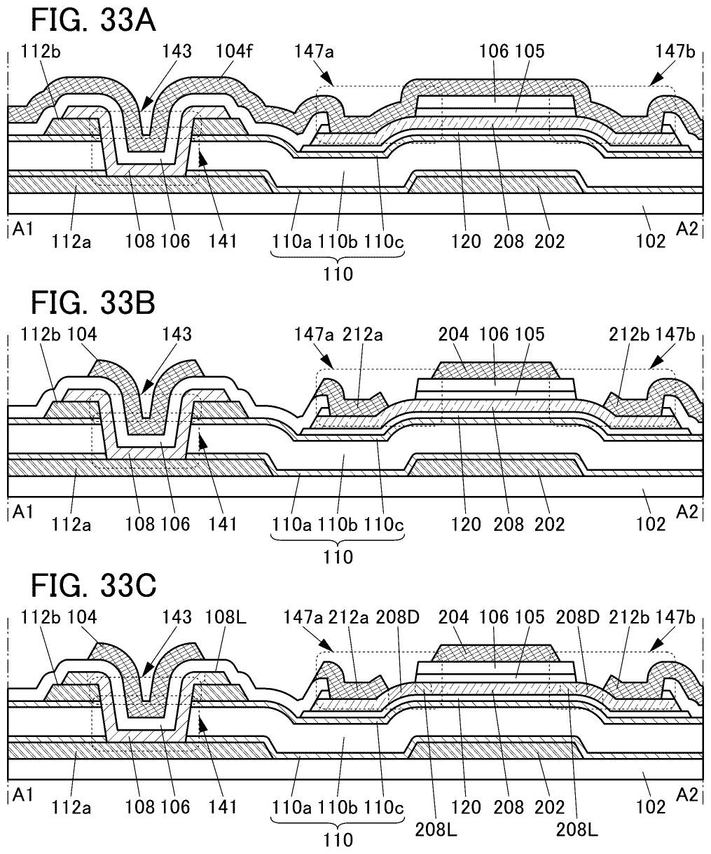

Next, a conductive film 104f to be the conductive layer 104, the conductive layer 204, the conductive layer 212a, and the conductive layer 212b is formed over the insulating layer 106 (FIG. 33A). The conductive film 104f is provided to cover the opening 147a and the opening 147b. For the formation of the conductive film 104f, a sputtering method or an ALD method can be suitably used, for example.

Next, the conductive film 104f is processed to form the conductive layer 104, the conductive layer 204, the conductive layer 212a, and the conductive layer 212b (FIG. 33B).

Next, an impurity is supplied (or added or implanted) to the semiconductor layer 208 using the conductive layer 204, the conductive layer 212a, and the conductive layer 212b as masks. Thus, the regions 208D are formed in the regions of the semiconductor layer 208 that overlap with none of the conductive layer 204, the conductive layer 212a, the conductive layer 212b, and the insulating layer 106, and the regions 208L are formed in the regions of the semiconductor layer 208 that overlap with none of the conductive layer 204, the conductive layer 212a, and the conductive layer 212b and overlap with the insulating layer 106 (FIG. 33C). At this time, the conditions for supplying the impurity are preferably determined in consideration of the material and thickness of the conductive layer 204 serving as the mask so that the impurity is supplied as little as possible to the region of the semiconductor layer 208 that overlaps with the conductive layer 204. In that case, a channel formation region with a sufficiently reduced impurity concentration can be formed in the region of the semiconductor layer 208 that overlaps with the conductive layer 204. Similarly, the semiconductor layer 108 may also be supplied with an impurity using the conductive layer 104 as a mask. The region 108L is formed in the region of the semiconductor layer 108 that does not overlap with the conductive layer 104 and overlaps with the insulating layer 106.

A plasma ion doping method or an ion implantation method can be suitably used for the supply of the impurity. In these methods, the concentration profile in the depth direction can be controlled with high accuracy by the acceleration voltage and the dosage of ions, or the like. Using a plasma ion doping method can increase productivity. In addition, using an ion implantation method with mass separation can increase the purity of the impurity to be supplied.

The conditions for the supply of the impurity are preferably adjusted such that the impurity concentration is highest at a surface of the semiconductor layer 208 or a portion near the surface.

As a source material used for supplying the impurity, a gas containing the above impurity element can be used, for example. In the case where boron is supplied, typically, one or more of a B₂H₆ gas and a BF₃ gas can be used. In the case where phosphorus is supplied, typically, a PH₃ gas can be used. A mixed gas in which any of these source gases is diluted with a noble gas may be used.

For example, any of CH₄, N₂, NH₃, AlH₃, AlCl₃, SiH₄, Si₂H₆, F₂, HF, H₂, (C₅H₅)₂Mg, and a noble gas can be used as the source material used for supplying the impurity. Note that the source material is not limited to a gas, and a solid or a liquid that is vaporized by heating may be used.

Addition of the impurity can be controlled by setting the conditions such as the acceleration voltage and the dosage in consideration of the compositions, densities, thicknesses, and the like of the insulating layer 106 and the semiconductor layer 208.

For example, in the case where boron is added by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus is added by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity is not limited thereto; plasma treatment, treatment using thermal diffusion by heating, or the like may be used, for example. In a plasma treatment method, plasma is generated in a gas atmosphere containing an impurity element to be added and plasma treatment is performed, so that the impurity can be added. A dry etching apparatus, an ashing apparatus, a plasma CVD apparatus, a high-density plasma CVD apparatus, or the like can be used as an apparatus for generating the plasma.

For example, when plasma treatment is performed with a plasma CVD apparatus in an atmosphere containing a hydrogen gas, hydrogen can be supplied as the impurity to the region of the semiconductor layer 208 that does not overlap with the conductive layer 204. With the use of a plasma CVD apparatus for the supply of the impurity and the formation of the insulating layer 195, the supply of the impurity and the formation of the insulating layer 195 can be successively performed in the apparatus, so that the productivity can be increased.

Next, the insulating layer 195 is formed to cover the conductive layer 104, the conductive layer 204, the conductive layer 212a, the conductive layer 212b, the insulating layer 106, and the semiconductor layer 208 (FIG. 9A and FIG. 9B). For the formation of the insulating layer 195, a PECVD method can be favorably used.

If the film formation temperature of the insulating layer 195 is too high, impurities contained in the region 108L, the regions 208L, and the regions 208D might diffuse into peripheral portions, which include the channel formation regions of the semiconductor layer 108 and the semiconductor layer 208. Furthermore, the electrical resistance of the region 108L, the regions 208L, and the regions 208D might be increased. Thus, the film formation temperature of the insulating layer 195 may be determined in consideration of the impurity diffusion.

The film formation temperature of the insulating layer 195 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Formation of the insulating layer 195 at low temperatures enables the transistors to have favorable electrical characteristics even when they each have a short channel length.

Heat treatment may be performed after the formation of the insulating layer 195. The heat treatment allows the region 108L, the regions 208L, and the regions 208D to have lower resistance, in some cases. For example, by the heat treatment, the impurity diffuses moderately, so that the region 108L, the regions 208L, and the regions 208D each having an ideal concentration gradient of the impurity can be formed. The above description can be referred to for the heat treatment; thus, the detailed description thereof is omitted. Note that when the temperature of the heat treatment is too high (e.g., higher than or equal to 500° C.), the impurity might also be diffused into the channel formation regions to degrade the electrical characteristics and reliability of the transistors.

Note that the heat treatment is not necessarily performed. The heat treatment in this step may be omitted, and heat treatment performed in a later step may also serve as the heat treatment in this step. In the case where treatment at a high temperature (e.g., film formation step) is performed in a later step, such treatment can serve as the heat treatment in this step in some cases.

Through the above process, the semiconductor device 10A can be manufactured.

### Manufacturing Method Example 2

A manufacturing method is described using the semiconductor device 10C in FIG. 17A and the like as an example.

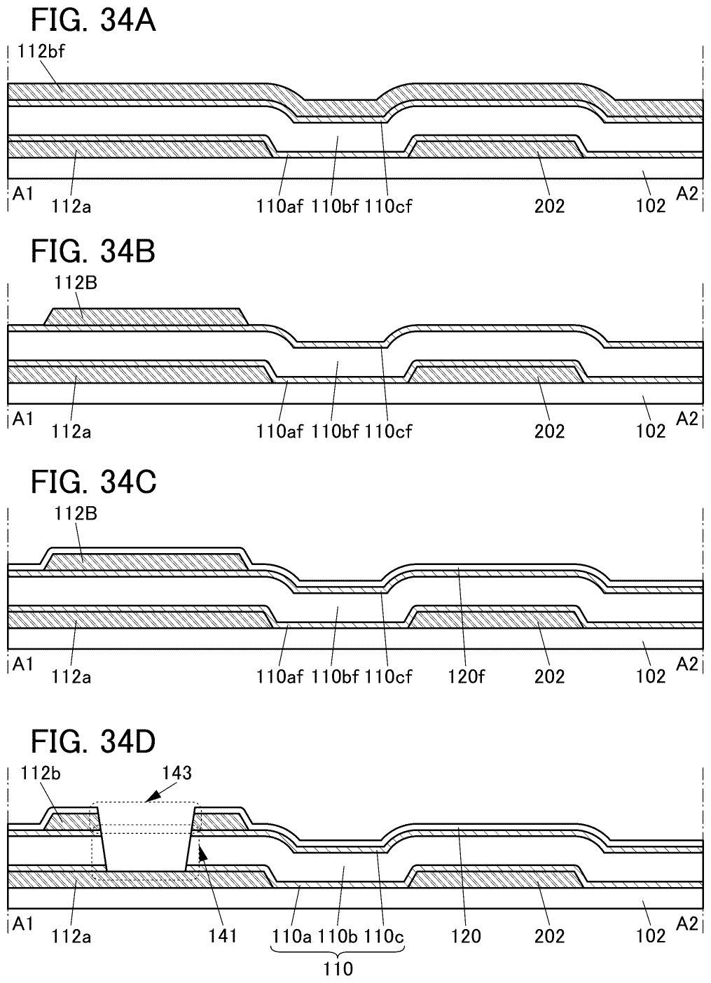

Each of FIG. 34A to FIG. 36D is a diagram illustrating the method for manufacturing the semiconductor device 10C. Each diagram is a cross-sectional view taken along the dashed-dotted line A1-A2.

First, as in <Manufacturing method example 1>, the steps up to the formation of the insulating film 110bf are performed. The description of FIG. 30A can be referred to for the steps up to the formation of the insulating film 110bf; thus, the detailed description thereof is omitted.

Then, oxygen may be supplied to the insulating film 110bf. The description in <Manufacturing method example 1> can be referred to for a method for supplying oxygen; thus, the detailed description thereof is omitted.

Next, the insulating film 110cf to be the insulating layer 110c is formed over the insulating film 110bf.

Then, the conductive film 112bf to be the conductive layer 112b is formed over the insulating film 110cf (FIG. 34A).

Next, the conductive film 112bf is processed to form the conductive layer 112B (FIG. 34B).

Subsequently, the insulating film 120f to be the insulating layer 120 is formed over the conductive layer 112B and the insulating film 110cf (FIG. 34C).

The description in <Manufacturing method example 1> can be referred to for the steps from the formation of the insulating film 110cf to the formation of the insulating layer 120; thus, the detailed description thereof is omitted.

Next, part of the insulating film 120f and part of the conductive layer 112B are removed to form the insulating layer 120 and the conductive layer 112b that include the opening 143, and part of the insulating film 110af, part of the insulating film 110bf, and part of the insulating film 110cf are removed to form the insulating layer 110 that includes the opening 141 (FIG. 34D).

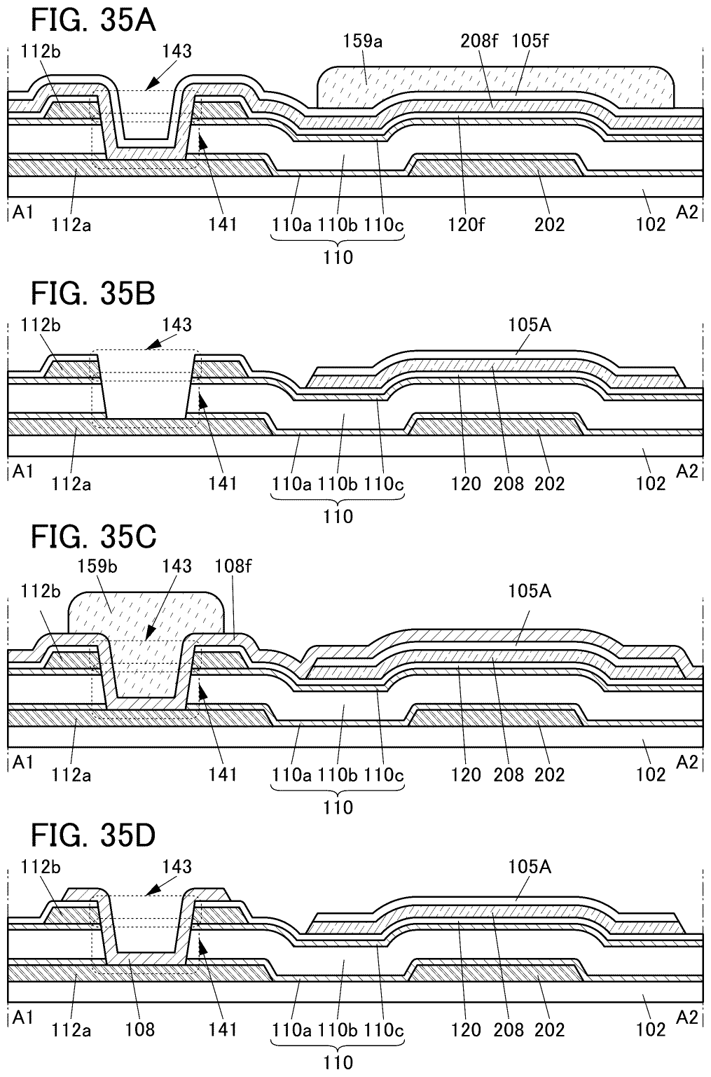

Subsequently, the metal oxide film 208f to be the semiconductor layer 208 is formed, the insulating film 105f to be the insulating layer 105 is formed over the metal oxide film 208f, and the resist mask 159a is formed over the insulating film 105f (FIG. 35A).

Next, the insulating film 105f and the metal oxide film 208f are processed into island shapes using the resist mask 159a as a mask to form the insulating layer 105A and the semiconductor layer 208.

Subsequently, the resist mask 159a is removed (FIG. 35B).

Next, the metal oxide film 108f to be the semiconductor layer 108 is formed to cover the opening 141 and the opening 143, and the resist mask 159b is formed over the metal oxide film 108f (FIG. 35C). The metal oxide film 108f is provided in contact with the side surface of the conductive layer 112b, the top surface and the side surface of the insulating layer 120, the top surface and the side surface of the insulating layer 110, and the top surface of the conductive layer 112a.

Subsequently, the metal oxide film 108f is processed into an island shape using the resist mask 159b as a mask to form the semiconductor layer 108.

Next, the resist mask 159b is removed (FIG. 35D).

Note that in the case of manufacturing the transistor 200A illustrated in FIG. 9A and the like, the insulating film 120f may be processed into an island shape after the formation of the insulating film 120f but before the formation of the metal oxide film 108f, to form the insulating layer 120.

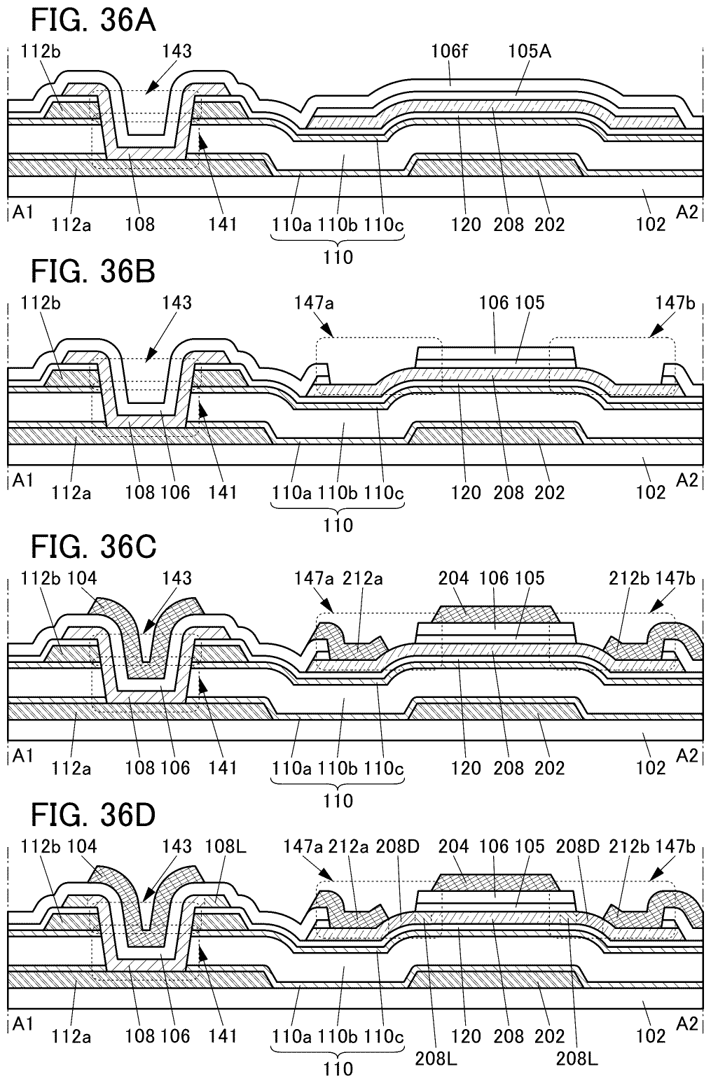

Next, the insulating film 106f to be the insulating layer 106 is formed to cover the semiconductor layer 108, the semiconductor layer 208, the conductive layer 112b, the insulating layer 105A, the insulating layer 120, and the insulating layer 110 (FIG. 36A).

Subsequently, the insulating film 106f and the insulating layer 105A are processed to form the insulating layer 106 and the insulating layer 105 (FIG. 36B).

Next, the conductive film to be the conductive layer 104, the conductive layer 204, the conductive layer 212a, and the conductive layer 212b is processed over the insulating layer 106 and is processed, so that the conductive layer 104, the conductive layer 204, the conductive layer 212a, and the conductive layer 212b are formed (FIG. 36C).

Then, an impurity is supplied to the semiconductor layer 208 using the conductive layer 204, the conductive layer 212a, and the conductive layer 212b as masks, so that the regions 208D and the regions 208L are formed (FIG. 36D).

Next, the insulating layer 195 is formed to cover the conductive layer 104, the conductive layer 204, the conductive layer 212a, the conductive layer 212b, the insulating layer 106, and the semiconductor layer 208 (FIG. 17A and FIG. 17B).

Through the above process, the semiconductor device 10C can be manufactured.

### Manufacturing Method Example 3

A manufacturing method is described using the semiconductor device 10B in FIG. 15A and the like as an example.

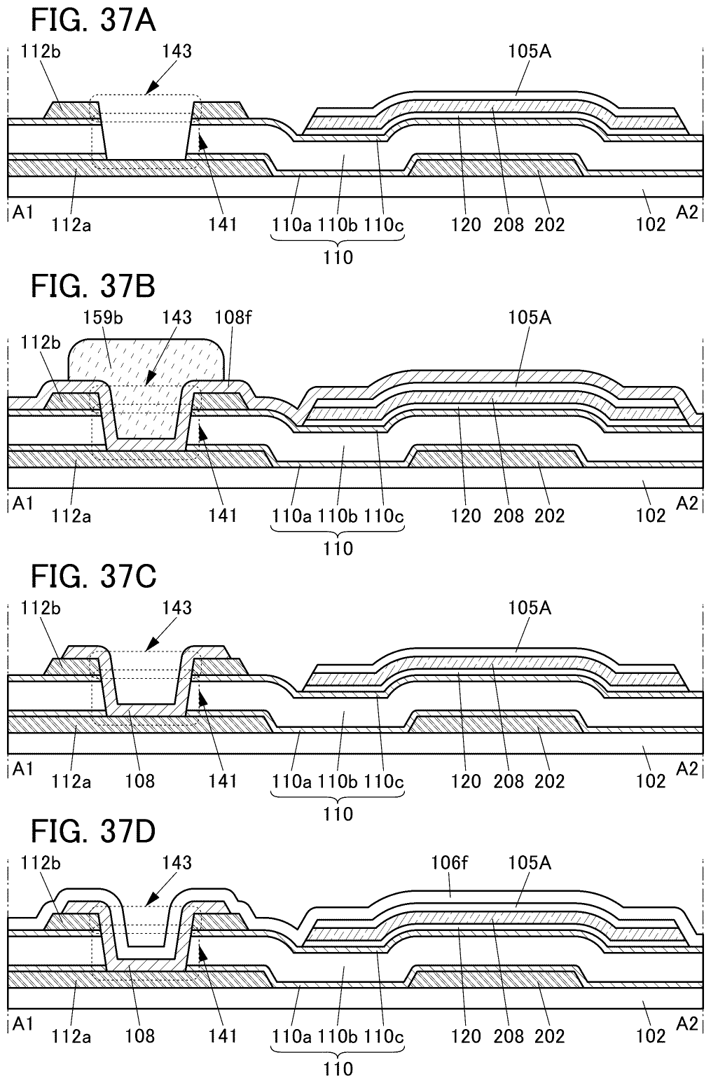

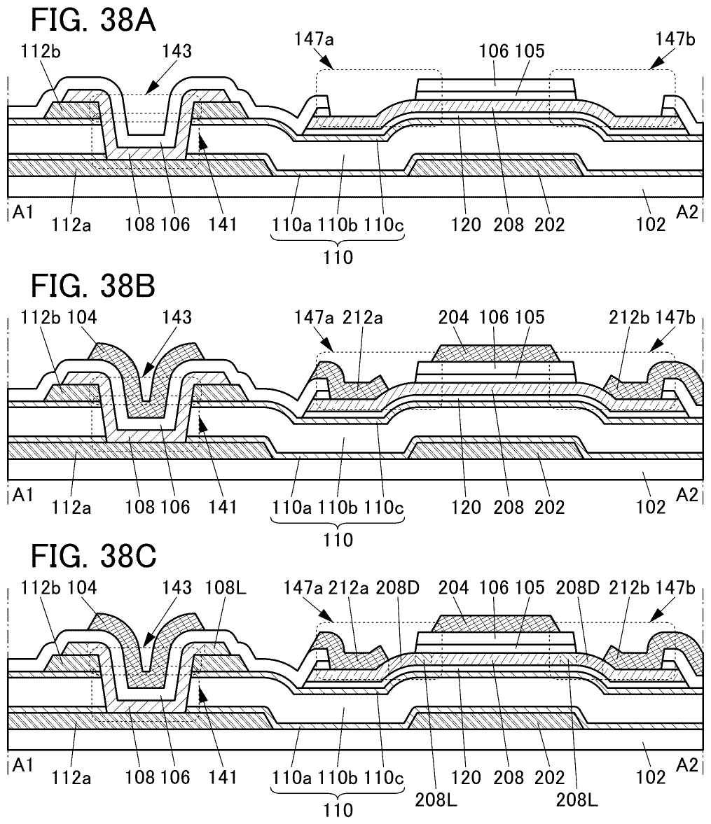

Each of FIG. 37A to FIG. 38C is a diagram illustrating the method for manufacturing the semiconductor device 10B. Each diagram is a cross-sectional view taken along the dashed-dotted line A1-A2.

First, as in <Manufacturing method example 2>, the steps up to the formation of the resist mask 159a over the insulating film 105f are performed. The description of FIG. 34A to FIG. 35A can be referred to for the steps up to the formation of the insulating film 120f; thus, the detailed description thereof is omitted.

Then, the insulating film 105f, the metal oxide film 208f, and the insulating film 120f are processed into island shapes using the resist mask 159a as a mask to form the insulating layer 105A, the semiconductor layer 208, and the insulating layer 105.

Next, the resist mask 159a is removed (FIG. 37A).

Subsequently, the metal oxide film 108f to be the semiconductor layer 108 is formed to cover the opening 141 and the opening 143, and the resist mask 159b is formed over the metal oxide film 108f (FIG. 37B). The metal oxide film 108f is provided in contact with the side surface of the conductive layer 112b, the top surface and the side surface of the insulating layer 110, and the top surface of the conductive layer 112a.

Next, the metal oxide film 108f is processed into an island shape using the resist mask 159b as a mask to form the semiconductor layer 108.

Subsequently, the resist mask 159b is removed (FIG. 37C).

Next, the insulating film 106f to be the insulating layer 106 is formed to cover the semiconductor layer 108, the semiconductor layer 208, the conductive layer 112b, the insulating layer 105A, the insulating layer 120, and the insulating layer 110 (FIG. 37D).

Subsequently, the insulating film 106f and the insulating layer 105A are processed to form the insulating layer 106 and the insulating layer 105 (FIG. 38A).

Next, the conductive film to be the conductive layer 104, the conductive layer 204, the conductive layer 212a, and the conductive layer 212b is processed over the insulating layer 106 and is processed, so that the conductive layer 104, the conductive layer 204, the conductive layer 212a, and the conductive layer 212b are formed (FIG. 38B).

Then, an impurity is supplied to the semiconductor layer 208 using the conductive layer 204, the conductive layer 212a, and the conductive layer 212b as masks, so that the regions 208D and the regions 208L are formed (FIG. 38C).

Next, the insulating layer 195 is formed to cover the conductive layer 104, the conductive layer 204, the conductive layer 212a, the conductive layer 212b, the insulating layer 106, and the semiconductor layer 208 (FIG. 15A and FIG. 15B).

Through the above process, the semiconductor device 10B can be manufactured.

### Manufacturing Method Example 4

A manufacturing method is described using the semiconductor device 10D in FIG. 19A and the like as an example.

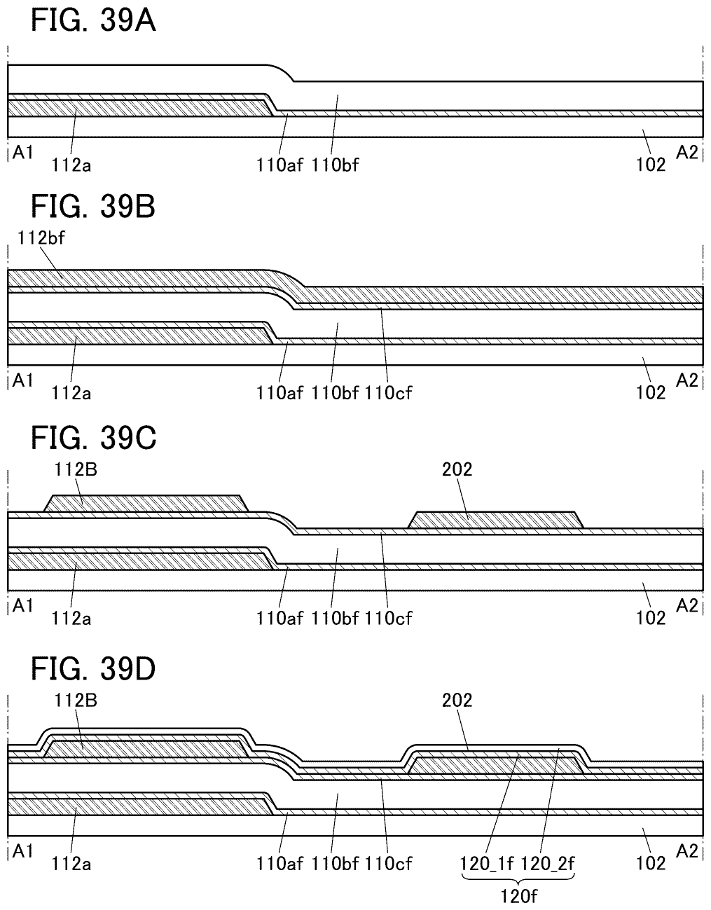

Each of FIG. 39A to FIG. 41D is a diagram illustrating the method for manufacturing the semiconductor device 10D. Each diagram is a cross-sectional view taken along the dashed-dotted line A1-A2.

First, the conductive layer 112a is formed over the substrate 102, and the insulating film 110af to be the insulating layer 110a and the insulating film 110bf to be the insulating layer 110b are formed over the conductive layer 112a (FIG. 39A).

Then, oxygen may be supplied to the insulating film 110bf. The description in <Manufacturing method example 1> can be referred to for a method for supplying oxygen; thus, the detailed description thereof is omitted.

Next, the insulating film 110cf to be the insulating layer 110c is formed over the insulating film 110bf.

Then, the conductive film 112bf to be the conductive layer 112b and the conductive layer 202 is formed over the insulating film 110cf (FIG. 39B).

Next, the conductive film 112bf is processed to form the conductive layer 112B and the conductive layer 202 (FIG. 39C).

Subsequently, the insulating film 120f to be the insulating layer 120 is formed over the conductive layer 112B, the conductive layer 202, and the insulating film 110cf (FIG. 39D). Here, as the insulating film 120f, an insulating film 120_1f to be the insulating layer 120_1 and an insulating film 120_2f to be the insulating layer 120_2 are formed.

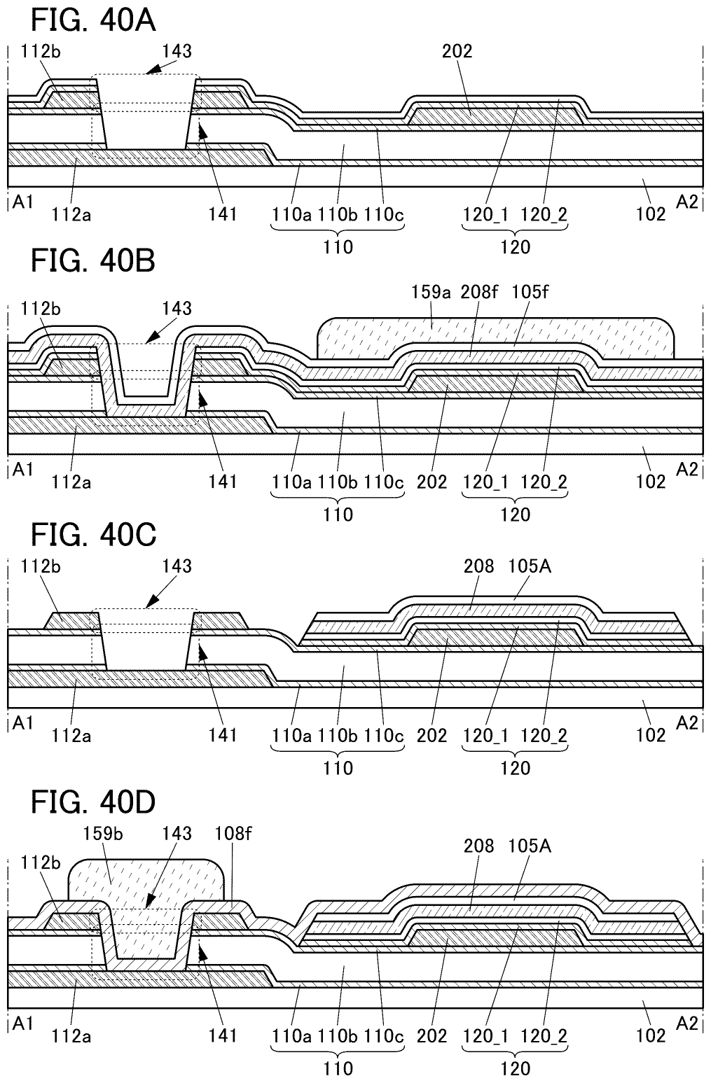

Next, part of the insulating film 120f and part of the conductive layer 112B are removed to form the insulating layer 120 and the conductive layer 112b that include the opening 143, and part of the insulating film 110af, part of the insulating film 110bf, and part of the insulating film 110cf are removed to form the insulating layer 110 that includes the opening 141 (FIG. 40A).

Subsequently, the metal oxide film 208f to be the semiconductor layer 208 is formed, the insulating film 105f to be the insulating layer 105 is formed over the metal oxide film 208f, and the resist mask 159a is formed over the insulating film 105f (FIG. 40B).

Next, the insulating film 105f, the metal oxide film 208f, and the insulating film 120f are processed into island shapes using the resist mask 159a as a mask to form the insulating layer 105A, the semiconductor layer 208, and the insulating layer 120.

Subsequently, the resist mask 159a is removed (FIG. 40C).

Note that in the case of manufacturing the transistor 200E illustrated in FIG. 20A and the like, the insulating film 120f may be processed into an island shape after the formation of the insulating film 120f but before the formation of the metal oxide film 108f, to form the insulating layer 120. Furthermore, the insulating layer 120 is formed not by using the resist mask 159a.

Next, the metal oxide film 108f to be the semiconductor layer 108 is formed to cover the opening 141 and the opening 143, and the resist mask 159b is formed over the metal oxide film 108f (FIG. 40D). The metal oxide film 108f is provided in contact with the top surface and the side surface of the conductive layer 112b, the top surface and the side surface of the insulating layer 110, and the top surface of the conductive layer 112a.

Next, the metal oxide film 108f is processed into an island shape using the resist mask 159b as a mask to form the semiconductor layer 108.

Subsequently, the resist mask 159b is removed.

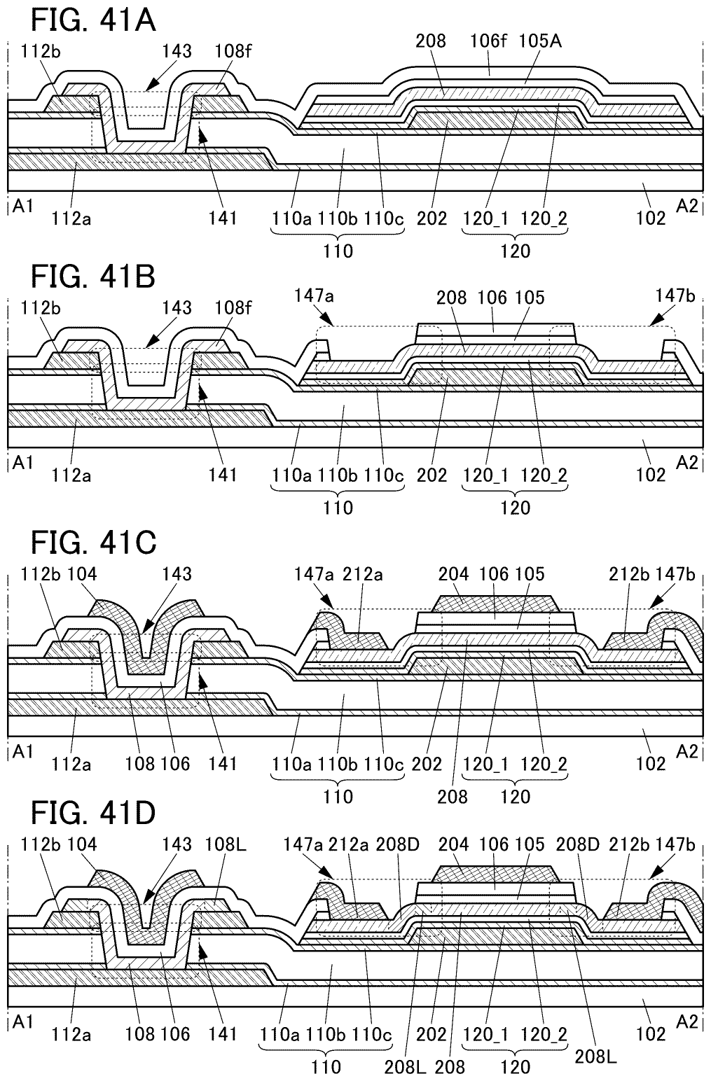

Next, the insulating film 106f to be the insulating layer 106 is formed to cover the semiconductor layer 108, the semiconductor layer 208, the conductive layer 112b, the insulating layer 105A, the insulating layer 120, and the insulating layer 110 (FIG. 41A).

Subsequently, the insulating film 106f and the insulating layer 105A are processed to form the insulating layer 106 and the insulating layer 105 (FIG. 41B).

Next, the conductive film to be the conductive layer 104, the conductive layer 204, the conductive layer 212a, and the conductive layer 212b is processed over the insulating layer 106 and is processed, so that the conductive layer 104, the conductive layer 204, the conductive layer 212a, and the conductive layer 212b are formed (FIG. 41C).

Then, an impurity is supplied to the semiconductor layer 208 using the conductive layer 204, the conductive layer 212a, and the conductive layer 212b as masks, so that the regions 208D and the regions 208L are formed (FIG. 41D).

Next, the insulating layer 195 is formed to cover the conductive layer 104, the conductive layer 204, the conductive layer 212a, the conductive layer 212b, the insulating layer 106, and the semiconductor layer 208 (FIG. 19A and FIG. 19B).

Through the above process, the semiconductor device 10D can be manufactured.

### Manufacturing Method Example 5

A manufacturing method is described using the semiconductor device 10J in FIG. 29B and the like as an example.

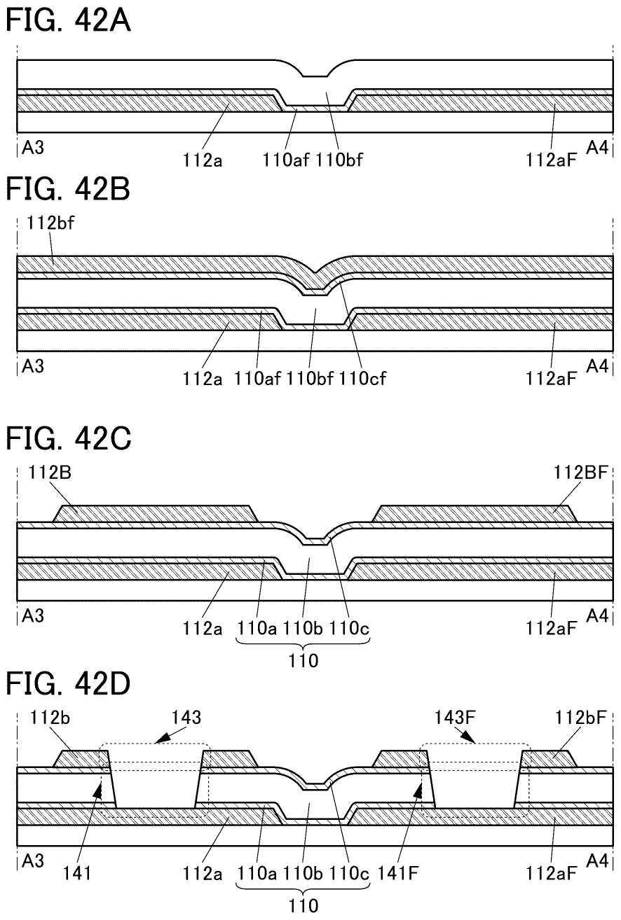

Each of FIG. 42A to FIG. 44B is a diagram illustrating the method for manufacturing the semiconductor device 10J. Each diagram is a cross-sectional view taken along the dashed-dotted line A3-A4.

First, the conductive layer 112a and the conductive layer 112aF are formed over the substrate 102, and the insulating film 110af to be the insulating layer 110a and the insulating film 110bf to be the insulating layer 110b are formed over the conductive layer 112a and the conductive layer 112aF (FIG. 42A).

Then, oxygen may be supplied to the insulating film 110bf. The description in <Manufacturing method example 1> can be referred to for a method for supplying oxygen; thus, the detailed description thereof is omitted.

Next, the insulating film 110cf to be the insulating layer 110c is formed over the insulating film 110bf.

Then, the conductive film 112bf to be the conductive layer 112b and the conductive layer 112bF is formed over the insulating film 110cf (FIG. 42B).

Next, the conductive film 112bf is processed to form the conductive layer 112B and a conductive layer 112BF (FIG. 42C).

Next, part of the conductive layer 112B and part of the conductive layer 112bF are removed to form the conductive layer 112B that includes the opening 143 and the conductive layer 112bF that includes the opening 143F, and part of the insulating film 110af, part of the insulating film 110bf, and part of the insulating film 110cf are removed to form the insulating layer 110 that includes the opening 141 and the opening 141F (FIG. 42D).

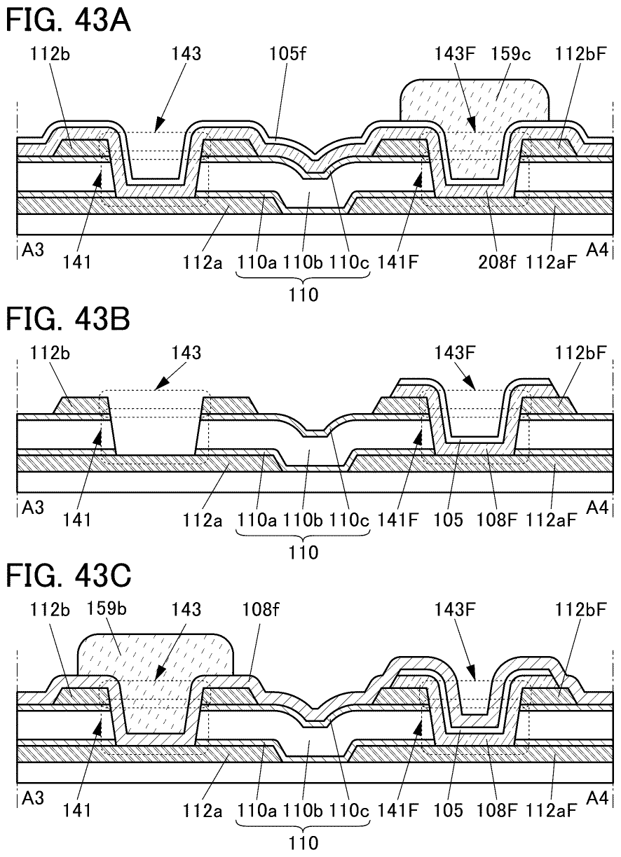

Subsequently, the metal oxide film 208f to be the semiconductor layer 108F is formed, the insulating film 105f to be the insulating layer 105 is formed over the metal oxide film 208f, and a resist mask 159c is formed over the insulating film 105f (FIG. 43A).

Next, the insulating film 105f and the metal oxide film 208f are processed into island shapes using the resist mask 159c as a mask to form the insulating layer 105 and the semiconductor layer 108F.

Subsequently, the resist mask 159c is removed (FIG. 43B).

Next, the metal oxide film 108f to be the semiconductor layer 108 is formed to cover the opening 141 and the opening 141F, and the resist mask 159b is formed over the metal oxide film 108f (FIG. 43C). The metal oxide film 108f is provided in contact with the top surface and the side surface of the conductive layer 112b, the top surface and the side surface of the insulating layer 110, and the top surface of the conductive layer 112a.

Then, the metal oxide film 108f is processed into an island shape using the resist mask 159b as a mask to form the semiconductor layer 108.

Subsequently, the resist mask 159b is removed.

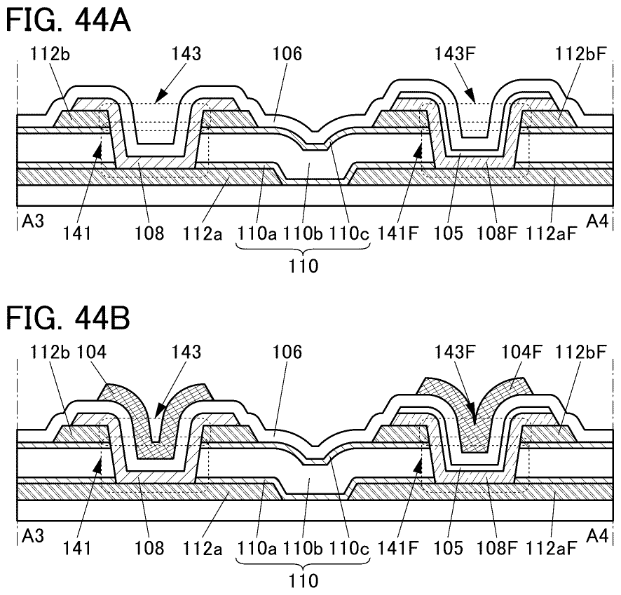

Next, the insulating layer 106 is formed to cover the semiconductor layer 108, the semiconductor layer 108F, the conductive layer 112b, the conductive layer 112bF, the insulating layer 105, and the insulating layer 110 (FIG. 44A).

Then, a conductive film to be the conductive layer 104 and the conductive layer 104F is processed over the insulating layer 106 and is processed, so that the conductive layer 104 and the conductive layer 104F are formed (FIG. 44B).

Next, the insulating layer 195 is formed to cover the conductive layer 104, the conductive layer 104F, and the insulating layer 106 (FIG. 29B and FIG. 29C).

Through the above process, the semiconductor device 10J can be manufactured.

This embodiment can be combined with the other embodiments as appropriate.

### Embodiment 3

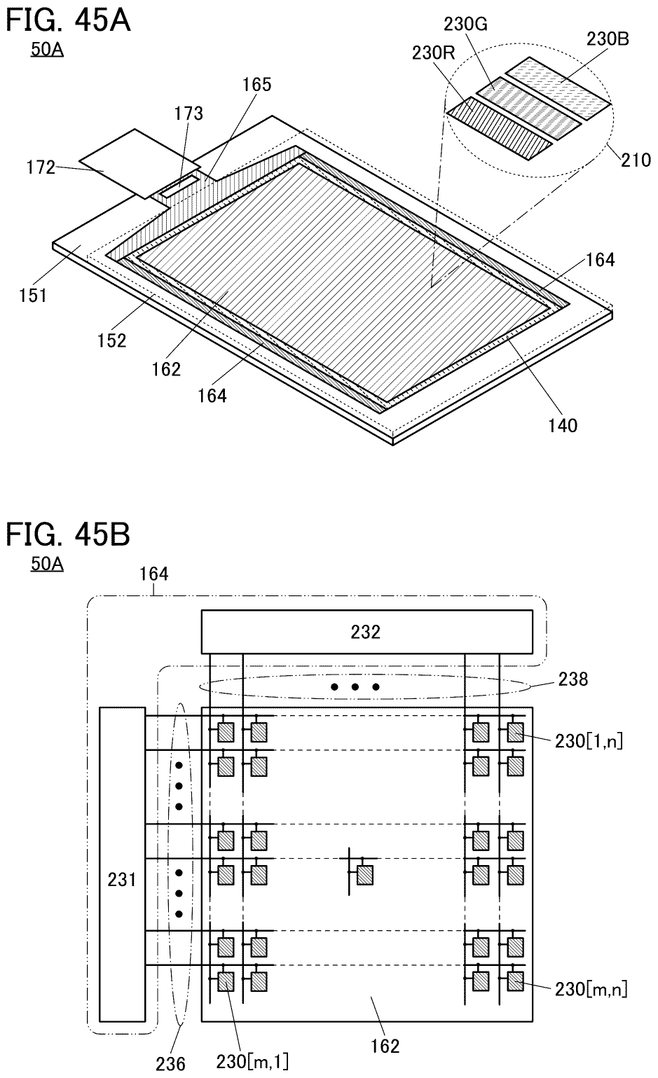

In this embodiment, a display device for which the semiconductor device of one embodiment of the present invention can be used will be described with reference to FIG. 45 to FIG. 55.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

FIG. 45A is a perspective view of a display device 50A.

In the display device 50A, a substrate 152 and a substrate 151 are bonded to each other. In FIG. 45A, the substrate 152 is indicated by a dashed line.

The display device 50A includes a display portion 162, a connection portion 140, a peripheral circuit portion 164, a wiring 165, and the like. FIG. 45A illustrates an example where an IC 173 and an FPC 172 are implemented onto the display device 50A. Thus, the structure illustrated in FIG. 45A can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 45A illustrates an example where the connection portion 140 is provided to surround the four sides of the display portion. In the connection portion 140, a common electrode of a display element is electrically connected to a conductive layer so that a potential can be supplied to the common electrode.

The peripheral circuit portion 164 includes a scan line driver circuit (also referred to as a gate driver), for example. The peripheral circuit portion 164 may include both a scan line driver circuit and a signal line driver circuit (also referred to as a source driver).

The wiring 165 has a function of supplying a signal and power to the display portion 162 and the peripheral circuit portion 164. The signal and power are input to the wiring 165 from the outside through the FPC 172 or input to the wiring 165 from the IC 173.

FIG. 45A illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The semiconductor device of one embodiment of the present invention can be used for one or both of the display portion 162 and the peripheral circuit portion 164 of the display device 50A, for example.

The display portion 162 of the display device 50A is a region where an image is to be displayed, and includes a plurality of pixels 210 that are periodically arranged. FIG. 45A shows an enlarged view of one of the pixels 210.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 45A includes a pixel 230R that emits red light, a pixel 230G that emits green light, and a pixel 230B that emits blue light. The pixel 230R, the pixel 230G, and the pixel 230B each serve as a subpixel.

The pixel 230R, the pixel 230G, and the pixel 230B each include a display element and a circuit for controlling the driving of the display element.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

As examples of a display device that includes a liquid crystal element, a transmissive liquid crystal display device, a reflective liquid crystal display device, and a transflective liquid crystal display device can be given.

As examples of the light-emitting element, self-luminous light-emitting elements such as an LED (Light Emitting Diode), an OLED (Organic LED), and a semiconductor laser can be given. As the LED, a mini LED, a micro LED, or the like can be used, for example.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, or white, for example. When the light-emitting element has a microcavity structure, higher color purity can be achieved.

One of a pair of electrodes of the light-emitting element functions as an anode, and the other electrode functions as a cathode.

In this embodiment, the case where a light-emitting element is used as the display element is mainly described as an example.

FIG. 45B is a block diagram illustrating the display device 50A. The display device 50A includes the display portion 162 and the peripheral circuit portion 164. The display portion 162 includes a plurality of pixels 230 arranged periodically. The peripheral circuit portion includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 162 positioned therebetween. Some sort of circuit may be provided at a position facing the second driver circuit portion 232 with the display portion 162 positioned therebetween.

Any of various circuits such as a shift register circuit, a level shifter circuit, an inverter circuit, a latch circuit, an analog switch circuit, a demultiplexer circuit, and a logic circuit can be used as the peripheral circuit portion 164. In the peripheral circuit portion 164, a transistor, a capacitor, and the like can be used. Transistors included in the peripheral circuit portion 164 may be formed in the same process as the transistors included in the pixels 230.

The display device 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 45B illustrates an example in which the wirings 236 and the wirings 238 are connected to the pixels 230. Note that the wirings 236 and the wirings 238 are examples, and the wirings connected to the pixels 230 are not limited to the wirings 236 and the wirings 238.

### Structure Example of Peripheral Circuit Portion

Using a latch circuit as an example, a structure example of a circuit that can be used in the peripheral circuit portion will be described.

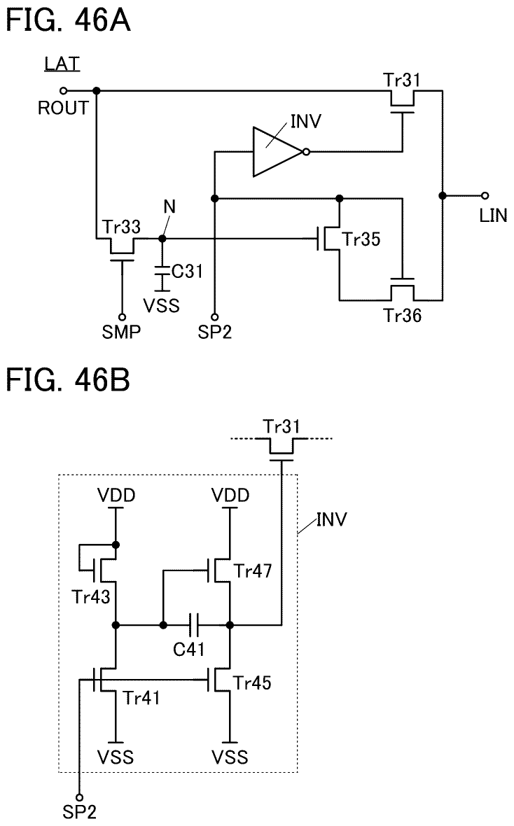

FIG. 46A is a circuit diagram illustrating a structure example of a latch circuit LAT. The latch circuit LAT illustrated in FIG. 46A includes a transistor Tr31, a transistor Tr33, a transistor Tr35, a transistor Tr36, a capacitor C31, and an inverter circuit INV. In FIG. 46A, a node that is electrically connected to one of a source and a drain of the transistor Tr33, a gate of the transistor Tr35, and one electrode of the capacitor C31 is referred to as a node N.

In the latch circuit LAT illustrated in FIG. 46A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is held and the data written to the latch circuit LAT is held. Specifically, when the potential of the node N is a low potential, data having a value “O” is held in the latch circuit LAT and when the potential of the node N is a high potential, data having a value “1” is held in the latch circuit LAT, for example.

A transistor with a low off-state current is preferably used as the transistor Tr33. An OS transistor can be suitably used as the transistor Tr33. In that case, the latch circuit LAT can hold data for a long period. Thus, the frequency of rewriting data in the latch circuit LAT can be lowered.

In this specification and the like, writing data to the latch circuit LAT such that a signal input from a terminal SP2 is output to the terminal LIN is simply referred to as “writing data to the latch circuit LAT”, in some cases. That is, writing data having a value “1”, for example, to the latch circuit LAT is simply referred to as “writing data to the latch circuit LAT”, in some cases. The semiconductor device of one embodiment of the present invention can be suitably used for the latch circuit LAT. For example, the transistor 100 or the transistor 200 illustrated in FIG. 1B or the like can be used as one or more of the transistor Tr31, the transistor Tr33, the transistor Tr35, and the transistor Tr36.

FIG. 46B illustrates a structure example of the inverter circuit INV. The inverter circuit INV includes a transistor Tr41, a transistor Tr43, a transistor Tr45, a transistor Tr47, and a capacitor C41.

When the latch circuit LAT has the structure illustrated in FIG. 46A and the inverter circuit INV has the structure illustrated in FIG. 46B, all the transistors included in the latch circuit LAT can be transistors having the same polarity, for example, n-channel transistors. In that case, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same process.

The semiconductor device of one embodiment of the present invention can be suitably used for the inverter circuit INV. For example, the transistor 100 or the transistor 200 illustrated in FIG. 1B or the like can be used as one or more of the transistor Tr41, the transistor Tr43, the transistor Tr45, and the transistor Tr47.

Using one or more types of transistors among the transistor 100 to the transistor 100F can reduce the occupied area, so that a display device with a narrow bezel can be obtained. One or more types of transistors among the transistor 100 to the transistor 100F can be suitably used as the transistors that need to have a high on-state current. Furthermore, one or more types of transistors among the transistor 200 to the transistor 200H can be suitably used as the transistors that need to have favorable saturation. In that case, a high-performance display device can be provided.

### Structure Example of Pixel Circuit

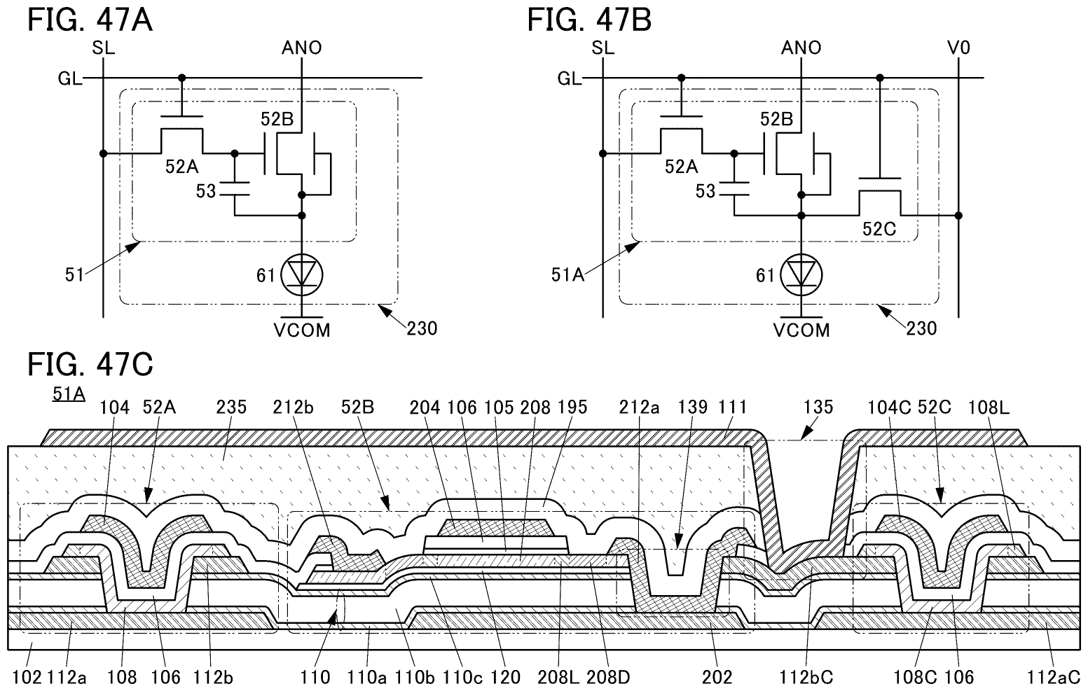

FIG. 47A illustrates a structure example of the pixel 230. The pixel 230 includes a pixel circuit 51 and a light-emitting device 61.

The pixel circuit 51 illustrated in FIG. 47A is a 2Tr1C-type pixel circuit including a transistor 52A, a transistor 52B, and a capacitor 53.

One of a source and a drain of the transistor 52A is electrically connected to a gate of the transistor 52B and one terminal of the capacitor 53, and the other of the source and the drain of the transistor 52A is electrically connected to a wiring SL. A gate of the transistor 52A is electrically connected to a wiring GL. One of a source and a drain of the transistor 52B and the other terminal of the capacitor 53 are electrically connected to an anode of the light-emitting device 61. The other of the source and the drain of the transistor 52B is electrically connected to a wiring ANO. A cathode of the light-emitting device 61 is electrically connected to a wiring VCOM.

The wiring GL corresponds to the wiring 236, and the wiring SL corresponds to the wiring 238. The wiring VCOM is a wiring for supplying a potential for supplying a current to the light-emitting device 61. The transistor 52A has a function of controlling the conduction state and non-conduction state between the wiring SL and the gate of the transistor 52B in accordance with the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of holding a gate potential of the transistor 52B. The intensity of light emitted by the light-emitting device 61 is controlled in accordance with an image signal supplied to the gate of the transistor 52B.

Some or all of the transistors included in the pixel circuit 51 may be provided with a back gate. In the pixel circuit 51 illustrated in FIG. 47A, the transistor 52B includes a back gate, and the back gate is electrically connected to one of a source and a drain of the transistor 52B. Note that the back gate electrode of the transistor 52B may be electrically connected to the gate of the transistor 52B.

The above-described semiconductor device can be suitably used for the pixel circuit 51. For example, the transistor 100 illustrated in FIG. 1B or the like can be used as the transistor 52A, and the transistor 200 can be used as the transistor 52B.

FIG. 47B shows a structure example different from that of the pixel 230 shown in FIG. 47A. The pixel 230 includes a pixel circuit 51A and the light-emitting device 61.

The pixel circuit 51A illustrated in FIG. 47B is different from the pixel circuit 51 illustrated in FIG. 47A mainly in including a transistor 52C. The pixel circuit 51A is a 3Tr1C-type pixel circuit including the transistor 52A, the transistor 52B, the transistor 52C, and the capacitor 53.

One of a source and a drain of the transistor 52C is electrically connected to the one of the source and the drain of the transistor 52B. The other of the source and the drain of the transistor 52C is electrically connected to a wiring V0. For example, a reference potential is supplied to the wiring V0.

The transistor 52C has a function of controlling the conduction state and non-conduction state between the wiring V0 and the one of the source and the drain of the transistor 52B in accordance with the potential of the wiring GL. Furthermore, variations in the gate-source potential of the transistor 52B can be inhibited by the reference potential of the wiring V0 supplied through the transistor 52C.

A current value that can be used for setting of pixel parameters can be obtained with the use of the wiring V0. Specifically, the wiring V0 can function as a monitor line for outputting, to the outside, a current flowing through the transistor 52B or a current flowing through the light-emitting device 61. A current output to the wiring V0 is converted into a voltage by a source follower circuit and can be output to the outside. Alternatively, the current is converted into a digital signal by an A/D converter, and can be output to the outside.

The above-described semiconductor device can be suitably used for the pixel circuit 51A. For example, the transistor 100A illustrated in FIG. 9A or the like can be used as each of the transistor 52A and the transistor 52C, and the transistor 200A can be used as the transistor 52B.

Note that there is no particular limitation on the pixel circuit that can be used for the display device of one embodiment of the present invention.

A structure example of the pixel circuit 51A is illustrated in FIG. 47C. FIG. 47C is a cross-sectional view of the pixel circuit 51A.

In a structure illustrated in FIG. 47C, the pixel circuit 51A employs the semiconductor device 10A illustrated in FIG. 9A or the like. Specifically, the transistor 100A is used as each of the transistor 52A and the transistor 52C, and the transistor 200A is used as the transistor 52B.

The transistor 52B functioning as a driving transistor that controls a current flowing through the light-emitting device 61 preferably has more favorable saturation than the transistor 52A functioning as a selection transistor for controlling a selection state of the pixel 230. The use of the transistor 200A having a long channel length as the transistor 52B enables the display device to have high reliability. Furthermore, the use of the transistor 100A as each of the transistor 52A and the transistor 52C can reduce the area occupied by the pixel circuit 51A, so that the display device can have high resolution.

Note that the transistor 100A may also be used as the transistor 52B. The use of the transistor 100A having a short channel length as the transistor 52B enables the display device to have high luminance. Furthermore, the area occupied by the pixel circuit 51A can be reduced, so that a high-resolution display device can be obtained.

The transistor 52A includes the conductive layer 112a, the semiconductor layer 108, the conductive layer 112b, the insulating layer 106, and the conductive layer 104. The transistor 52C includes a conductive layer 112aC, a semiconductor layer 108C, a conductive layer 112bC, the insulating layer 106, and a conductive layer 104C. The conductive layer 112aC, the semiconductor layer 108C, the conductive layer 112bC, and the conductive layer 104C of the transistor 52C respectively correspond to the conductive layer 112a, the semiconductor layer 108, the conductive layer 112b, and the conductive layer 104 of the transistor 100A illustrated in FIG. 9A and the like. The transistor 52B includes the semiconductor layer 208, the insulating layer 105, the insulating layer 106, the conductive layer 204, the conductive layer 202, the insulating layer 110, and the insulating layer 120.

The conductive layer 212a is electrically connected to the conductive layer 202 through an opening 139 provided in the insulating layer 120 and the insulating layer 110. The conductive layer 212a is electrically connected to the conductive layer 112bC. Note that the electrical connection between the transistor 52A and the transistor 52B is not shown in FIG. 47C. For example, a first opening reaching the conductive layer 112b and a second opening reaching the conductive layer 204 are provided in the insulating layer 195. A first wiring is provided over the insulating layer 195 to cover the first opening and the second opening, whereby the conductive layer 112b and the conductive layer 204 can be electrically connected to each other through the first wiring.

In FIG. 47C, the capacitor 53 is not shown. The capacitor 53 can be formed in a region where the insulating layer 106 is sandwiched between the conductive layer 204 and the conductive layer 112bC, for example. Note that there is no particular limitation on the structure of the capacitor 53.

The insulating layer 195 is provided to cover the transistor 52A, the transistor 52B, the transistor 52C, and the capacitor 53, and an insulating layer 235 is provided to cover the insulating layer 195. The light-emitting device 61 can be provided over the insulating layer 235. FIG. 47C illustrates a pixel electrode 111 functioning as one electrode of the light-emitting device 61. The pixel electrode 111 is electrically connected to the conductive layer 112bC through an opening 135 provided in the insulating layer 106, the insulating layer 195, and the insulating layer 235. The above description can be referred to for the insulating layer 195; thus, the detailed description thereof is omitted. The insulating layer 235 has a function of reducing unevenness due to the transistor 52A, the transistor 52B, and the transistor 52C and making the formation surface of the light-emitting device 61 flatter. Note that in this specification and the like, the insulating layer 235 is referred to as a planarization layer in some cases.

An organic insulating film is suitable for the insulating layer 235. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably has a function of an etching protective layer. In that case, a depressed portion can be inhibited from being formed in the insulating layer 235 in formation of the pixel electrode 111. Alternatively, a depressed portion may be formed in the insulating layer 235 in the formation of the pixel electrode 111.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided as the outermost surface of the insulating layer 235 can function as an etching protective layer. This can inhibit a decrease in the flatness of the insulating layer 235, which is caused by etching of part of the insulating layer 235 in the formation of the pixel electrode 111.

The display device of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

### Structure Example 1 of Display Device

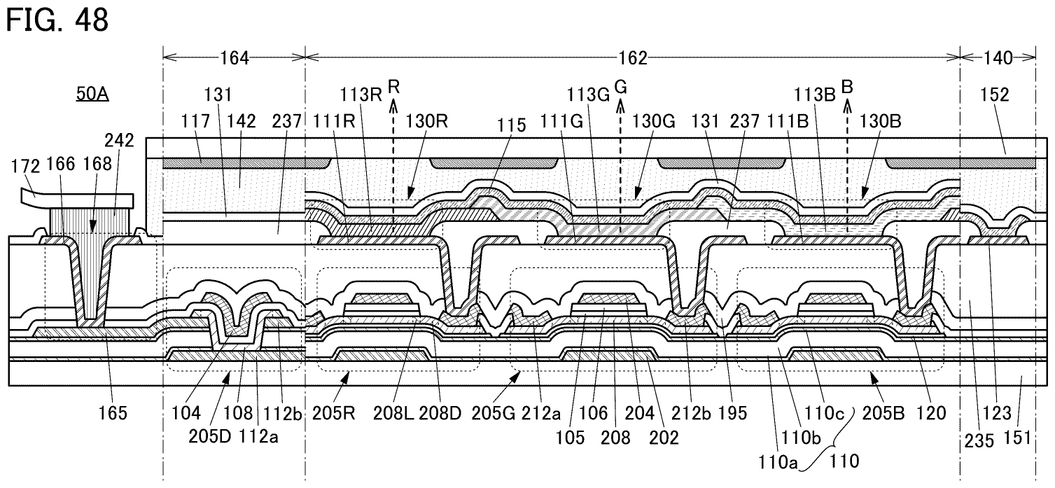

FIG. 48A illustrates examples of cross sections of part of a region including the FPC 172, part of the peripheral circuit portion 164, part of the display portion 162, part of the connection portion 140, and part of a region including an end portion of the display device 50A.

The display device 50A illustrated in FIG. 48A includes transistors 205D, 205R, 205G, and 205B, a light-emitting element 130R, a light-emitting element 130G, a light-emitting element 130B, and the like between the substrate 151 and the substrate 152. The light-emitting element 130R is a display element included in the pixel 230R that emits red light, the light-emitting element 130G is a display element included in the pixel 230G that emits green light, and the light-emitting element 130B is a display element included in the pixel 230B that emits blue light.

The display device 50A employs an SBS structure. The SBS structure can optimize materials and structures of light-emitting elements and thus can extend freedom of choice of materials and structures, whereby the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistor 205D, the transistor 205R, the transistor 205G, and the transistor 205B are formed over the substrate 151. The fabrication processes of these transistors can share some steps.

One or more types of transistors among the transistor 100 to the transistor 100F and the transistor 200 to the transistor 200H described above can be used as one or more of the transistor 205D, the transistor 205R, the transistor 205G, and the transistor 205B. For example, in the display portion 162, one or more types of transistors among the transistor 200 to the transistor 200H with favorable saturation can be suitably used as the transistor 205R, the transistor 205G, and the transistor 205B functioning as driving transistors for the light-emitting element 130R, the light-emitting element 130G, and the light-emitting element 130B. In that case, the display device can be highly reliable. When one or more types of transistors among the transistor 100 to the transistor 100F described above are used in the peripheral circuit portion 164, the display device can operate at high speed. Furthermore, the area occupied by the peripheral circuit portion 164 can be reduced, and the bezel can be narrowed.

The transistor provided in the peripheral circuit portion 164 is sometimes required to have a higher on-state current than the transistor provided in the display portion 162. The peripheral circuit portion 164 preferably includes a transistor with a short channel length. For example, one or more types of transistors among the transistor 100 to the transistor 100F described above can be suitably used in the peripheral circuit portion 164. When one or more types of transistors among the transistor 100 to the transistor 100F are used in the peripheral circuit portion 164, the occupied area can be reduced, so that the display device can have a narrow bezel. One or more types of transistors among the transistor 200 to the transistor 200H described above can be suitably used as the transistor provided in the display portion 162. In the structure shown in FIG. 48, the transistor 100A described above is used as the transistor 205D, and the transistor 200A is used as each of the transistor 205R, the transistor 205G, and the transistor 205B. Note that one or more types of transistors among the transistor 100 to the transistor 100F may be used in the display portion 162, and one or more types of transistors among the transistor 200 to the transistor 200G may be used in the peripheral circuit portion 164.

Note that the transistor included in the display device of this embodiment is not limited to the transistor included in the semiconductor device of one embodiment of the present invention. For example, the display device of this embodiment may include the transistor included in the semiconductor device of one embodiment of the present invention and a transistor having another structure in combination. The display device of this embodiment may include one or more of a planar transistor, a staggered transistor, and an inverted staggered transistor. The transistor included in the display device of this embodiment may have a top-gate structure or a bottom-gate structure. Gates may be provided above and below a semiconductor layer where a channel is formed.

An OS transistor can be suitably used as each of the transistor 205D, the transistor 205R, the transistor 205G, and the transistor 205B.

A transistor including silicon in its channel formation region (a Si transistor) may be included in the display device of this embodiment. Examples of silicon include single crystal silicon, polycrystalline silicon, and amorphous silicon. In particular, a transistor including LTPS in its semiconductor layer (hereinafter also referred to as an LTPS transistor) can be used. The LTPS transistor has high field-effect mobility and excellent frequency characteristics.

To increase the emission luminance of the light-emitting element included in the pixel circuit, it is necessary to increase the amount of current flowing through the light-emitting element. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When transistors operate in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled. Therefore, the number of gray levels in the pixel circuit can be increased.

Regarding saturation characteristics of a current flowing when a transistor operates in a saturation region, a current (saturation current) can flow more stably in an OS transistor than in a Si transistor even when the source-drain voltage gradually increases. Thus, with the use of an OS transistor as a driving transistor, a current can be made to flow stably through the light-emitting element, for example, even when a variation in current-voltage characteristics of the light-emitting element occurs. In other words, when the OS transistor operates in the saturation region, the source-drain current hardly changes with a change in the source-drain voltage; hence, the emission luminance of the light-emitting element can be stable.

The transistor included in the peripheral circuit portion 164 and the transistor included in the display portion 162 may have the same structure or different structures. One structure or two or more kinds of structures may be employed for a plurality of transistors included in the peripheral circuit portion 164. Similarly, one structure or two or more kinds of structures may be employed for a plurality of transistors included in the display portion 162.

All of the transistors included in the display portion 162 may be OS transistors, all of the transistors included in the display portion 162 may be Si transistors, or some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. Likewise, all of the transistors included in the peripheral circuit portion 164 may be OS transistors, all of the transistors included in the peripheral circuit portion 164 may be Si transistors, or some of the transistors included in the peripheral circuit portion 164 may be OS transistors and the others may be Si transistors.

The insulating layer 195 is provided to cover the transistor 205D, the transistor 205R, the transistor 205G, and the transistor 205B, and the insulating layer 235 is provided over the insulating layer 195.

The light-emitting element 130R, the light-emitting element 130G, and the light-emitting element 130B are provided over the insulating layer 235.

The light-emitting element 130R includes a pixel electrode 111R over the insulating layer 235, an EL layer 113R over the pixel electrode 111R, and a common electrode 115 over the EL layer 113R. The light-emitting element 130R illustrated in FIG. 48 emits red light (R). The EL layer 113R includes a light-emitting layer that emits red light.

The light-emitting element 130G includes a pixel electrode 111G over the insulating layer 235, an EL layer 113G over the pixel electrode 111G, and the common electrode 115 over the EL layer 113G. The light-emitting element 130G illustrated in FIG. 48 emits green light (G). The EL layer 113G includes a light-emitting layer that emits green light.

The light-emitting element 130B includes a pixel electrode 111B over the insulating layer 235, an EL layer 113B over the pixel electrode 111B, and the common electrode 115 over the EL layer 113B. The light-emitting element 130B illustrated in FIG. 48 emits blue light (B). The EL layer 113B includes a light-emitting layer that emits blue light.

Although the EL layers 113R, 113G, and 113B have the same thickness in FIG. 48, the present invention is not limited thereto. The EL layers 113R, 113G, and 113B may have different thicknesses. For example, the thicknesses of the EL layers 113R, 113G, and 113B are preferably set to be an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 195 and the insulating layer 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can have a single-layer structure or a stacked-layer structure including one or both of an inorganic insulating material and an organic insulating material. The insulating layer 237 can be formed using a material that can be used for the insulating layer 235, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting elements 130R, 130G, and 130B. The common electrode 115 shared by the light-emitting elements is electrically connected to a conductive layer 123 provided in the connection portion 140. A conductive layer formed using the same material through the same process as the pixel electrodes 111R, 111G, and 111B is preferably used as the conductive layer 123.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of a pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element that belongs to Group 1 or Group 2 of the periodic table and that is not listed above as an example (e.g., lithium, cesium, calcium, or strontium), a rare earth metal such as europium or ytterbium, an alloy containing an appropriate combination of any of these elements, and graphene.

The light-emitting element preferably employs a micro-optical resonator (microcavity) structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 48, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 48; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (e.g., a host material or an assist material) in addition to the light-emitting substance (a guest material). As one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (a substance with a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a good hole-injection property (a hole-injection layer), a layer including a hole-transport material (a hole-transport layer), a layer including a substance having a good electron-blocking property (an electron-blocking layer), a layer including a substance having a good electron-injection property (an electron-injection layer), a layer including an electron-transport material (an electron-transport layer), and a layer including a substance having a good hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an ink-jet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 48, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 48, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting elements. Alternatively, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the peripheral circuit portion 164. It is preferable that the protective layer 131 be provided to extend to the end portion of the display device 50A. Meanwhile, a connection portion 168 has a portion not provided with the protective layer 131 so that the FPC 172 and a conductive layer 166 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a good visible-light-transmitting property. For example, ITO, IGZO, and aluminum oxide are preferable because they are inorganic materials having a good visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) to the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 168 is provided in the region of the substrate 151 that does not overlap with the substrate 152. In the connection portion 168, the wiring 165 is electrically connected to the FPC 172 through the conductive layer 166 and a connection layer 242. In this example, the conductive layer 166 is a single conductive layer obtained by processing the same conductive film as the pixel electrode 111R, the pixel electrode 111G, and the pixel electrode 111B. On the top surface of the connection portion 168, the conductive layer 166 is exposed. Thus, the connection portion 168 and the FPC 172 can be electrically connected to each other through the connection layer 242.

The wiring 165 is electrically connected to a transistor included in the peripheral circuit portion 164. In the structure illustrated in FIG. 48, the conductive layer 112b included in the transistor 205D extends and functions as the wiring 165. Note that the structure of the wiring 165 is not limited thereto.

The display device 50A has a top-emission structure. Light from the light-emitting element is emitted toward the substrate 152. For the substrate 152, a material having a good visible-light-transmitting property is preferably used. The pixel electrode 111R, the pixel electrode 111G, and the pixel electrode 111B include a material that reflects visible light, and the counter electrode (the common electrode 115) includes a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the peripheral circuit portion 164, for example.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer side of the substrate 152. For example, a glass layer or a silica layer (SiOₓ layer) is preferably provided as the surface protective layer to inhibit the surface contamination and damage. The surface protective layer may be formed using DLC (diamond-like carbon), aluminum oxide (AlOₓ), a polyester-based material, a polycarbonate-based material, or the like. For the surface protective layer, a material having a high visible light transmittance is preferably used. The surface protective layer is preferably formed using a material with high hardness.

For each of the substrate 151 and the substrate 152, glass, quartz, ceramic, sapphire, a resin, a metal, an alloy, a semiconductor, or the like can be used. The substrate on the side from which light from the light-emitting element is extracted is formed using a material that transmits the light. When a flexible material is used for the substrate 151 and the substrate 152, the display device can have increased flexibility and a flexible display can be obtained. Furthermore, a polarizing plate may be used as at least one of the substrate 151 and the substrate 152.

For each of the substrate 151 and the substrate 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

The adhesive layer 142 can be formed using any of a variety of curable adhesives, e.g., a reactive curable adhesive, a thermosetting curable adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet or the like may be used.

For the connection layer 242, an anisotropic conductive film (ACF), an anisotropic conductive paste (ACP), or the like can be used.

### Structure Example 2 of Display Device

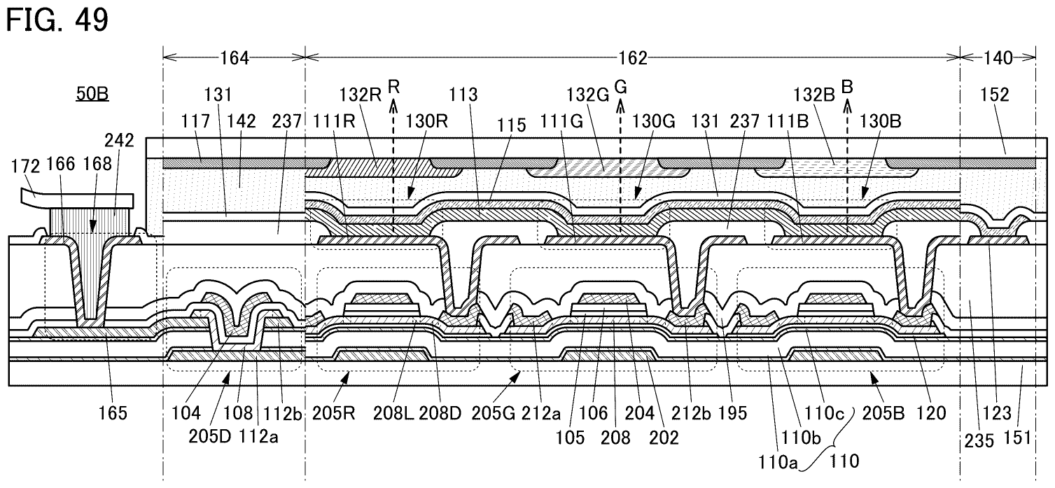

A display device 50B illustrated in FIG. 49 is different from the display device 50A mainly in that the subpixels of different colors include respective coloring layers (color filters or the like) and the light-emitting elements that share an EL layer 113. Note that in the following description of display devices, the description of portions similar to those of the above-described display device may be omitted.

In the display device 50B illustrated in FIG. 49, the transistors 205D, 205R, 205G, and 205B, the light-emitting elements 130R, 130G, and 130B, a coloring layer 132R transmitting red light, a coloring layer 132G transmitting green light, a coloring layer 132B transmitting blue light, and the like are provided between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to outside the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to outside the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to outside the display device 50B through the coloring layer 132B.

The EL layer 113 and the common electrode 115 are shared by the light-emitting elements 130R, 130G, and 130B. The number of manufacturing steps can be smaller in the structure where the EL layer 113 is provided to be shared by the subpixels of different colors than in the structure where the subpixels of different colors are provided with different EL layers.

The light-emitting elements 130R, 130G, and 130B illustrated in FIG. 49 emit white light, for example. When white light emitted from the light-emitting elements 130R, 130G, and 130B passes through the coloring layers 132R, 132G, and 132B, light of desired colors can be obtained.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting elements 130R, 130G, and 130B illustrated in FIG. 49 emit blue light, for example. In this case, the EL layer 113 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Structure Example 3 of Display Device

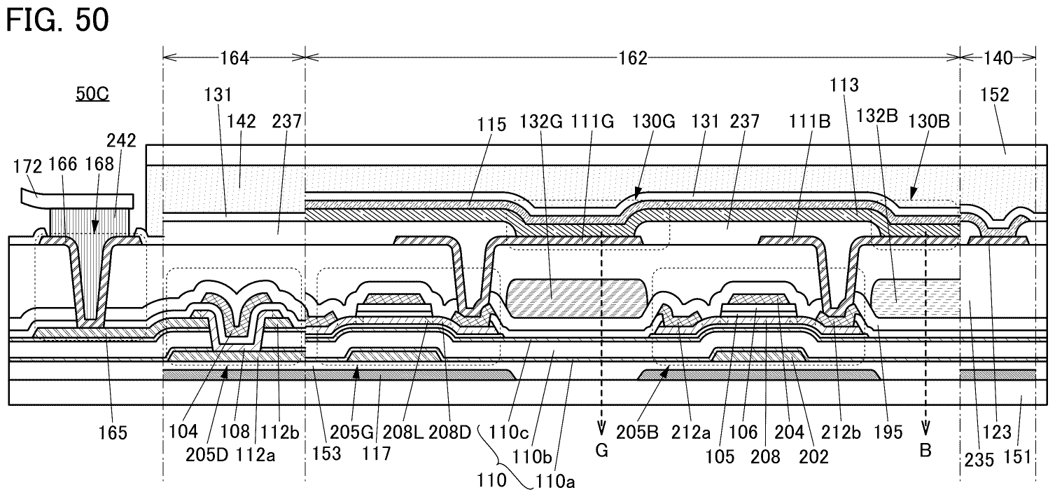

A display device 50C illustrated in FIG. 50 is different from the display device 50B mainly in having a bottom-emission structure.

Light from the light-emitting element is emitted toward the substrate 151. For the substrate 151, a material having a good visible-light-transmitting property is preferably used. By contrast, there is no limitation on the light-transmitting property of a material used for the substrate 152.

The light-blocking layer 117 is preferably formed between the substrate 151 and the transistor. FIG. 50 illustrates an example where the light-blocking layers 117 are provided over the substrate 151, the insulating layer 153 is provided over the light-blocking layers 117, and the transistor 205D, the transistor 205R (not shown), the transistor 205G, the transistor 205B, and the like are provided over the insulating layer 153. In addition, the coloring layer 132R (not shown), the coloring layer 132G, and the coloring layer 132B are provided over the insulating layer 195, and the insulating layer 235 is provided over the coloring layer 132R (not shown), the coloring layer 132G, and the coloring layer 132B.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a good visible-light-transmitting property is used for each of the pixel electrodes 111G and 111B. A material that reflects visible light is preferably used for the common electrode 115. In the display device having a bottom-emission structure, a metal or the like having low resistivity can be used for the common electrode 115; thus, a voltage drop due to the resistance of the common electrode 115 can be inhibited and the display quality can be high.

### Structure Example 4 of Display Device

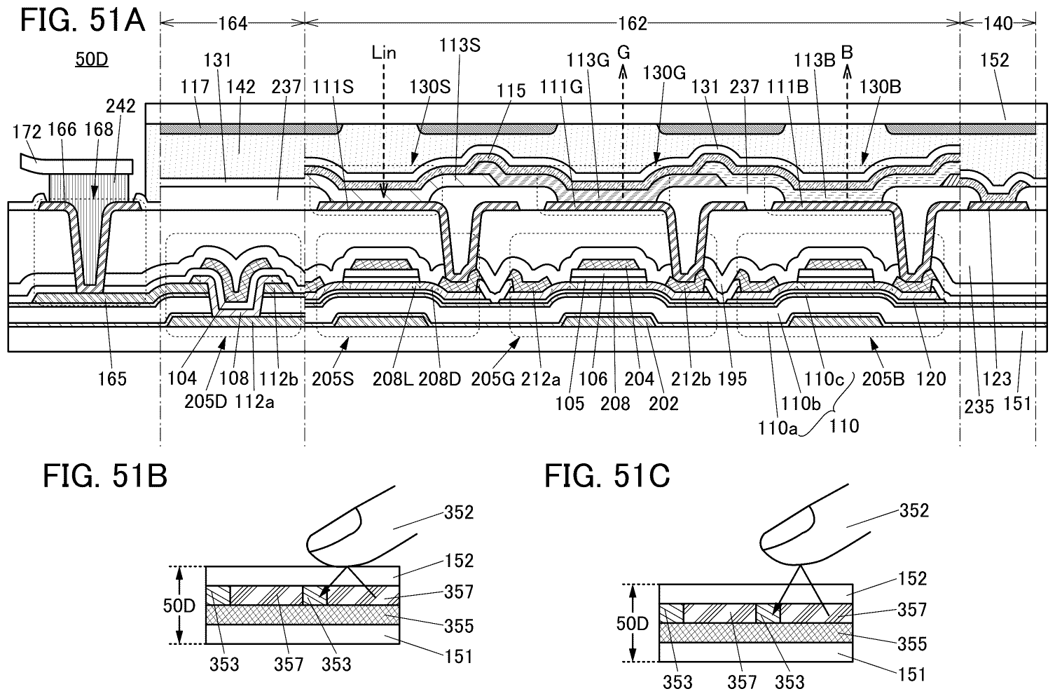

A display device 50D illustrated in FIG. 51A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in a display device including the organic EL elements.

The display device 50D can detect the touch or proximity of an object while displaying an image because the pixel includes the light-emitting elements and the light-receiving element and thus has a light-receiving function. Accordingly, the display portion 162 has one or both of an image capturing function and a sensing function in addition to a function of displaying an image. For example, an image can be displayed by using all the subpixels included in the display device 50D; alternatively, light can be emitted by some of the subpixels as a light source, light can be detected by some other subpixels, and an image can be displayed by using the remaining subpixels.

Accordingly, a light-receiving portion and a light source do not need to be provided separately from the display device 50D; hence, the number of components of an electronic device can be reduced. For example, a biometric authentication device provided in the electronic device or a capacitive touch panel for scroll operation or the like does not need to be provided separately. Thus, with the use of the display device 50D, the electronic device can be provided at lower manufacturing costs.

When the light-receiving element is used for an image sensor, the display device 50D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin from outside the display device 50D enters the functional layer 113S.

The pixel electrode 111S is electrically connected to the conductive layer 112b included in a transistor 205S through an opening provided in the insulating layer 195 and the insulating layer 235.

An end portion of the pixel electrode 111S is covered with the insulating layer 237.

The common electrode 115 is one continuous film shared by the light-receiving element 130S, the light-emitting element 130R (not shown), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment illustrates an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

As a layer other than the active layer, the functional layer 113S may further include a layer including a substance having a good hole-transport property, a substance having a good electron-transport property, a substance having a bipolar property (a substance having a good electron-transport property and a good hole-transport property), or the like. Without limitation to the above, the functional layer 113S may further include a layer including a substance having a good hole-injection property, a hole-blocking material, a substance having a good electron-injection property, an electron-blocking material, or the like. Layers other than the active layer included in the light-receiving element can be formed using a material that can be used for the light-emitting element.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an ink-jet method, a coating method, and the like.

In the display device 50D illustrated in FIG. 51B and FIG. 51C, a layer 353 including a light-receiving element, a circuit layer 355, and a layer 357 including a light-emitting element are provided between the substrate 151 and the substrate 152.

The layer 353 includes the light-receiving element 130S, for example. The layer 357 includes the light-emitting elements 130R, 130G, and 130B, for example.

The circuit layer 355 includes a circuit for driving a light-receiving element and a circuit for driving a light-emitting element. The circuit layer 355 includes the transistors 205R, 205G, and 205B, for example. The circuit layer 355 can further include one or more of a switch, a capacitor, a resistor, a wiring, a terminal, and the like.

FIG. 51B illustrates an example where the light-receiving element 130S is used as a touch sensor. Light emitted from the light-emitting element in the layer 357 is reflected by a finger 352 that touches the display device 50D as illustrated in FIG. 51B, and the light-receiving element in the layer 353 senses the reflected light. Thus, the touch of the finger 352 on the display device 50D can be detected.

FIG. 51C illustrates an example where the light-receiving element 130S is used as a contactless sensor. Light emitted from the light-emitting element in the layer 357 is reflected by the finger 352 that is close to (i.e., that does not touch) the display device 50D as illustrated in FIG. 51C, and the light-receiving element in the layer 353 senses the reflected light.

### Structure Example 5 of Display Device

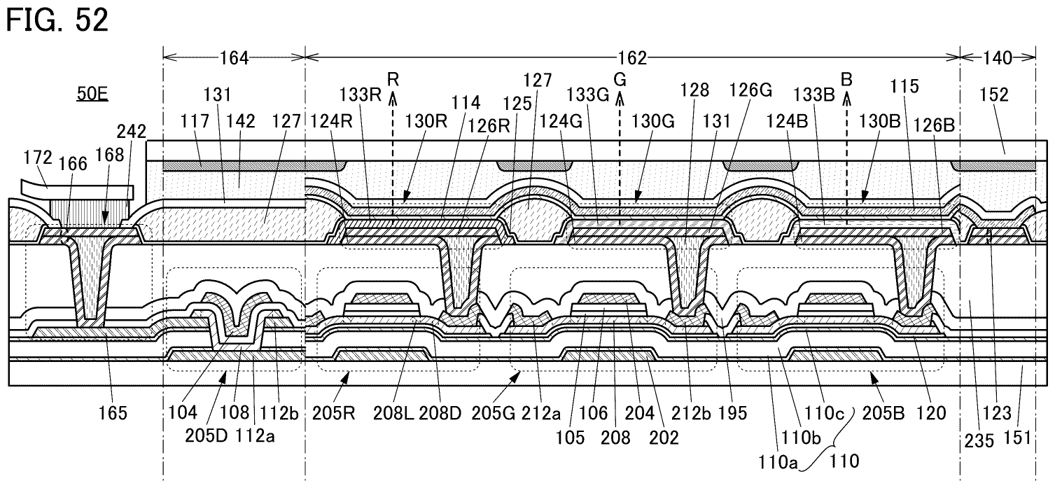

A display device 50E illustrated in FIG. 52 is an example of a display device having an MML (metal maskless) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; therefore, description thereof is omitted.

In FIG. 52, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 52 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 52 emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 52 emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are apart from each other. When the EL layer is provided to have an island shape for each light-emitting element, a leakage current between adjacent light-emitting elements can be inhibited. This can prevent crosstalk-induced unintended light emission, so that a display device with extremely high contrast can be obtained.

Although the layers 133R, 133G, and 133B have the same thickness in FIG. 52, the present invention is not limited thereto. The layers 133R, 133G, and 133B may have different thicknesses.

The conductive layer 124R is electrically connected to the conductive layer 112b included in the transistor 205R through an opening provided in the insulating layer 195 and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a function of filling the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 52 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may match an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portions of the pixel electrodes have a tapered shape, the layer 133R provided along the side surfaces of the pixel electrodes also has a tapered shape. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with the insulating layers 125 and 127. The common layer 114 is provided over the layer 133R, the layer 133G, the layer 133B and the insulating layers 125 and 127, and the common electrode 115 is provided over the common layer 114. The common layer 114 and the common electrode 115 are each one continuous film shared by a plurality of light-emitting elements.

In FIG. 52, the insulating layer 237 illustrated in FIG. 48 or the like is not provided between the conductive layer 126R and the layer 133R. That is, an insulating layer (also referred to as a partition wall, a bank, a spacer, or the like) being in contact with the pixel electrode and covering an end portion of the top surface of the pixel electrode is not provided in the display device 50E. Thus, the interval between adjacent light-emitting elements can be extremely short. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting elements can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting elements can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting elements can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby unevenness with a large level difference on the formation surface of the layers (e.g., the carrier-injection layer and the common electrode) provided over the island-shaped layers can be reduced and the formation surface can be flatter. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, defective connection caused by step disconnection can be inhibited. In addition, an increase in electrical resistance, which is caused by local thinning of the common electrode 115 due to the step, can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with high flatness.

The insulating layer 125 can be formed using an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used for the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that would be diffused into the light-emitting elements from the outside can be inhibited. With this structure, a highly reliable light-emitting element and a highly reliable display device can be provided.

The insulating layer 125 preferably has a low impurity concentration. In that case, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of reducing unevenness with a large level difference on the insulating layer 125 formed between the adjacent light-emitting elements. In other words, the insulating layer 127 has an effect of improving the flatness of the formation surface of the common electrode 115.

As the insulating layer 127, an insulating layer including an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymers in a broad sense in some cases.

The insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved.

Since no polarizing plate is required to improve the display quality of the display device, the display device can be lightweight and thin.

Examples of the material absorbing visible light include a material containing a pigment of black or any other color, a material containing a dye, a light-absorbing resin material (e.g., polyimide), and a resin material that can be used for color filters (a color filter material). A resin material obtained by stacking or mixing color filter materials of two or three or more colors is particularly preferably used to enhance the effect of blocking visible light. In particular, mixing color filter materials of three or more colors enables formation of a black or nearly black resin layer.

### Structure Example 6 of Display Device

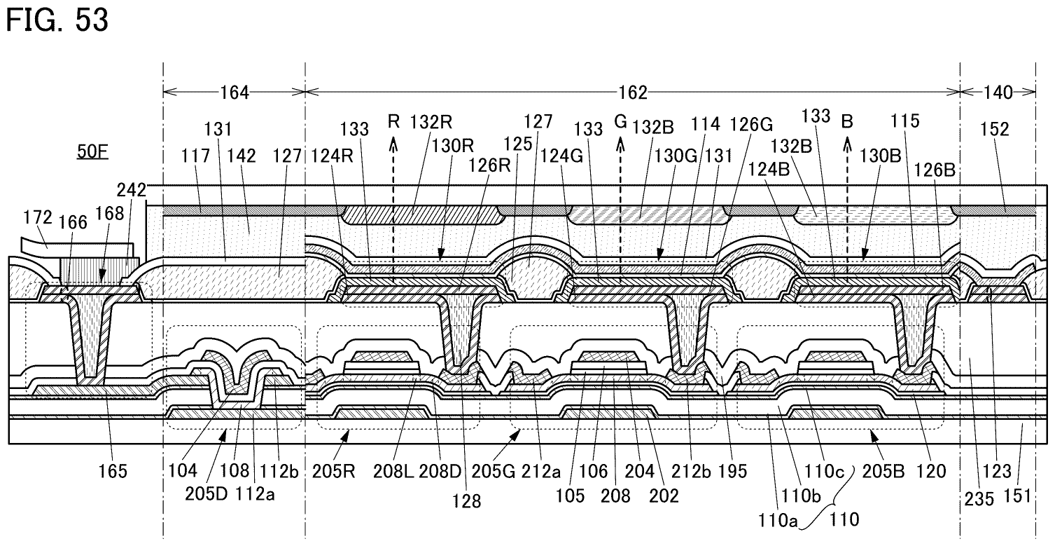

A display device 50F illustrated in FIG. 53 is different from the display device 50E mainly in that the subpixels of different colors include coloring layers (color filters or the like).

In the display device 50F illustrated in FIG. 53, the transistors 205D, 205R, 205G, and 205B, the light-emitting elements 130R, 130G, and 130B, the coloring layer 132R transmitting red light, the coloring layer 132G transmitting green light, the coloring layer 132B transmitting blue light, and the like are provided between the substrate 151 and the substrate 152.

Light emitted from the light-emitting element 130R is extracted as red light to outside the display device 50F through the coloring layer 132R. Similarly, light emitted from the light-emitting element 130G is extracted as green light to outside the display device 50F through the coloring layer 132G. Light emitted from the light-emitting element 130B is extracted as blue light to outside the display device 50F through the coloring layer 132B.

The light-emitting elements 130R, 130G, and 130B each include the layer 133. The three layers 133 are formed using the same process and the same material. The three layers 133 are apart from each other. When the EL layer is provided to have an island shape for each light-emitting element, a leakage current between adjacent light-emitting elements can be inhibited. This can prevent crosstalk-induced unintended light emission, so that a display device with extremely high contrast can be obtained.

The light-emitting elements 130R, 130G, and 130B illustrated in FIG. 53 emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 53 emit blue light, for example. In this case, the layer 133 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### Structure Example 7 of Display Device

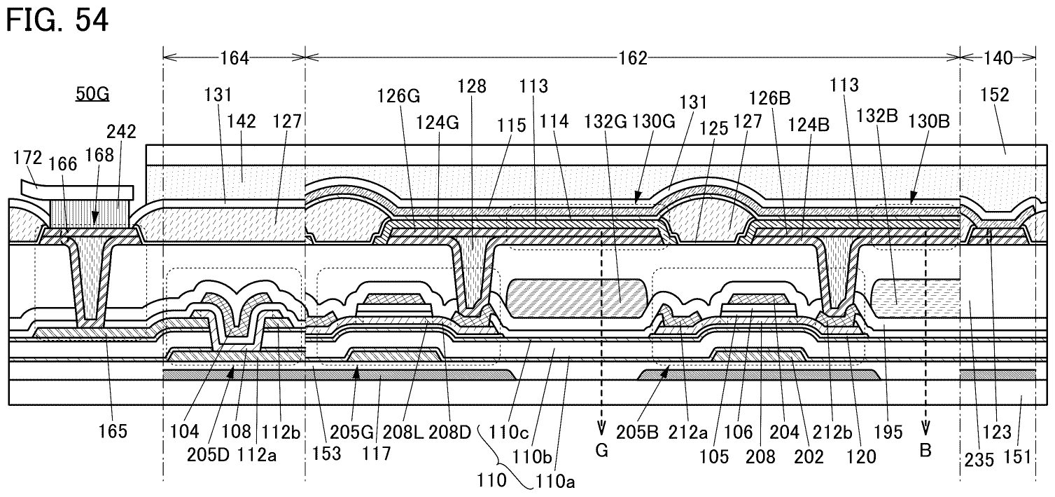

A display device 50G illustrated in FIG. 54 is different from the display device 50F mainly in having a bottom-emission structure.

Light from the light-emitting element is emitted toward the substrate 151. For the substrate 151, a material having a good visible-light-transmitting property is preferably used. By contrast, there is no limitation on the light-transmitting property of a material used for the substrate 152.

The light-blocking layer 117 is preferably formed between the substrate 151 and the transistor. FIG. 54 illustrates an example where the light-blocking layers 117 are provided over the substrate 151, the insulating layer 153 is provided over the light-blocking layers 117, and the transistor 205D, the transistor 205R (not shown), the transistor 205G, the transistor 205B, and the like are provided over the insulating layer 153. In addition, the coloring layer 132R (not shown), the coloring layer 132G, and the coloring layer 132B are provided over the insulating layer 195, and the insulating layer 235 is provided over the coloring layer 132R (not shown), the coloring layer 132G, and the coloring layer 132B.

The light-emitting element 130G overlapping with the coloring layer 132G includes the conductive layer 124G, the conductive layer 126G, the EL layer 113, the common layer 114, and the common electrode 115.

The light-emitting element 130B overlapping with the coloring layer 132B includes the conductive layer 124B, the conductive layer 126B, the EL layer 113, the common layer 114, and the common electrode 115.

A material having a good visible-light-transmitting property is used for each of the conductive layers 124G, 124B, 126G, and 126B. A material that reflects visible light is preferably used for the common electrode 115. In the display device having a bottom-emission structure, a metal or the like having low resistivity can be used for the common electrode 115; thus, a voltage drop due to the resistance of the common electrode 115 can be inhibited and the display quality can be high.

### Manufacturing Method Example of Display Device

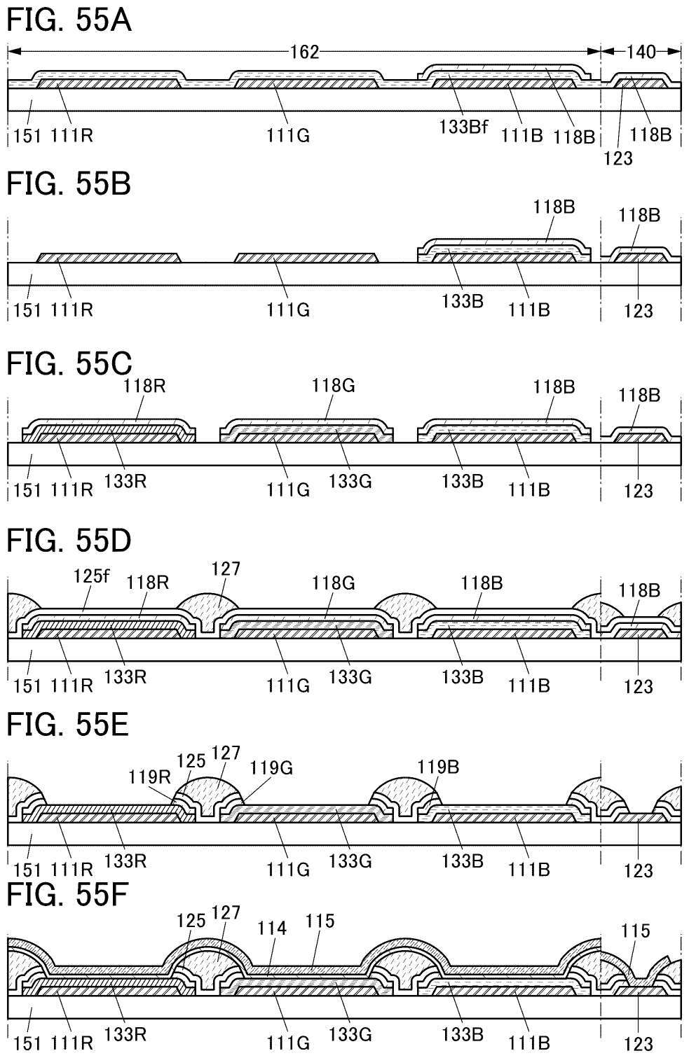

A method for manufacturing a display device having an MML (metal maskless) structure will be described below with reference to FIG. 55. Here, steps of manufacturing light-emitting elements without using a fine metal mask will be described in detail. FIG. 55 shows cross-sectional views of three light-emitting elements included in the display portion 162 and the connection portion 140 in the steps.

For manufacture of the light-emitting elements, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

In the method described below for manufacturing the display device, the island-shaped layer (the layer including the light-emitting layer) is formed not by using a fine metal mask but by forming a light-emitting layer on the entire surface and processing the light-emitting layer by a photolithography method. Accordingly, a high-resolution display device or a display device with a high aperture ratio, which has been difficult to form so far, can be obtained. Moreover, light-emitting layers can be formed separately for the respective colors, enabling the display device to perform extremely clear display with high contrast and high display quality. Moreover, providing a sacrificial layer over the light-emitting layer can reduce damage to the light-emitting layer in the manufacturing process of the display device, resulting in an increase in reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B and the like (not shown) (FIG. 55A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. The conductive film can be processed by one or both of a wet etching method and a dry etching method.

Next, a film 133Bf to be the layer 133B later is formed over the pixel electrodes 111R, 111G, and 111B (FIG. 55A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In that case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed in the order of blue, green, and red or in the order of blue, red, and green.

This enables the blue-light-emitting element to keep the favorable state of the interface between the pixel electrode and the EL layer, thereby inhibiting an increase in the driving voltage of the blue-light-emitting device. In addition, the blue-light-emitting element can have a longer lifetime and higher reliability. Since the red-light-emitting element and the green-light-emitting element are less affected by an increase in driving voltage and the like than the blue-light-emitting element, the driving voltage of the whole display device can be lowered and the reliability thereof can be increased.

Note that the formation order of the island-shaped EL layers is not limited to the above; for example, the island-shaped EL layers may be formed in the order of red, green, and blue.

As illustrated in FIG. 55A, the film 133Bf is not formed over the conductive layer 123. The film 133Bf can be formed only in a desired region using an area mask, for example. Employing a film formation step using an area mask and a processing step using a resist mask enables a light-emitting element to be manufactured by a relatively easy process.

The upper temperature limit of the compounds included in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Therefore, the range of choices of the materials and the formation method of the display device can be widened, thereby improving the yield and the reliability.

The upper temperature limit, for example, can be any of the glass transition point, the softening point, the melting point, the thermal decomposition temperature, and the 5% weight loss temperature, preferably the lowest one among these temperatures.

The film 133Bf can be formed by an evaporation method, specifically a vacuum evaporation method, for example. The film 133Bf may be formed by a transfer method, a printing method, an ink-jet method, a coating method, or the like.

Next, a sacrificial layer 118B is formed over the film 133Bf and the conductive layer 123 (FIG. 55A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display device, resulting in an increase in reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can suppress a variation in the characteristics of the light-emitting elements and can improve reliability.

When the layer 133B covers the top surface and the side surface of the pixel electrode 111B, the steps after the formation of the layer 133B can be performed without exposing the pixel electrode 111B. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

For the sacrificial layer 118B, a film that is highly resistant to the process conditions for the film 133Bf, specifically, a film having high etching selectivity with respect to the film 133Bf is used.

The sacrificial layer 118B is formed at a temperature lower than the upper temperature limit of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film formed at a higher temperature can be denser and have a better barrier property. Therefore, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the sacrificial layer 118B may be formed by the above-described wet film-formation process.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

For the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In place of gallium described above, the element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

For the sacrificial layer 118B, any of a variety of inorganic insulating films that can be used for the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. For the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. For the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a good barrier property against at least one of water and oxygen. Meanwhile, since the sacrificial layer 118B is a layer a large part or the whole of which is to be removed in a later step, it is preferable that the processing of the sacrificial layer 118B be easy. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film-formation process and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet film-formation process and an inorganic film (e.g., a silicon nitride film) formed by a sputtering method can be employed for the sacrificial layer 118B.

Note that in the display device of one embodiment of the present invention, part of a sacrificial film remains as the sacrificial layer in some cases.

Then, the film 133Bf is processed using the sacrificial layer 118B as a hard mask, so that the layer 133B is formed (FIG. 55B).

Accordingly, as illustrated in FIG. 55B, a stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 55C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B, and the sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a high-resolution display device with a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 55D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage during film formation is reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation rate than an ALD method. In that case, a highly reliable display device can be manufactured with high productivity.

For example, an insulating film to be the insulating layer 127 is preferably formed by the aforementioned wet film-formation process (e.g., spin coating) using a photosensitive resin composite containing an acrylic resin. After the film formation, heat treatment (also referred to as pre-baking) is preferably performed to eliminate a solvent included in the insulating film. Next, part of the insulating film is irradiated with visible light or ultraviolet rays as light exposure. Next, the region of the insulating film that is exposed to light is removed by development. Then, heat treatment (also referred to as post-baking) is performed. Accordingly, the insulating layer 127 illustrated in FIG. 55D can be formed. Note that the shape of the insulating layer 127 is not limited to the shape illustrated in FIG. 55D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 55E, etching treatment is performed using the insulating layer 127 as a mask to remove parts of the insulating film 125f and the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Note that parts of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, by providing the insulating layer 127, the insulating layer 125, the sacrificial layer 118R, the sacrificial layer 118G, and the sacrificial layer 118B, defective connection due to a split portion and an increase in electrical resistance due to a locally thinned portion can be inhibited from occurring in the common layer 114 and the common electrode 115 between the light-emitting elements. Thus, the display device of one embodiment of the present invention can have improved display quality.

Next, the common layer 114 and the common electrode 115 are formed in this order over the insulating layer 127, the layer 133B, the layer 133G, and the layer 133R (FIG. 55F). The common layer 114 can be formed by an evaporation method (including a vacuum evaporation method), a transfer method, a printing method, an ink-jet method, a coating method, or the like.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133R, the island-shaped layer 133G, and the island-shaped layer 133B are formed not by using a fine metal mask but by forming a film on the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133R, the layer 133G, and the layer 133B can be inhibited from being in contact with each other in the adjacent subpixels. As a result, generation of a leakage current between the subpixels can be inhibited. This can prevent crosstalk-induced unintended light emission, so that a display device with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. Thus, defective connection due to a split portion and an increase in electrical resistance due to a locally thinned portion can be inhibited from occurring in the common layer 114 and the common electrode 115. Hence, the display device of one embodiment of the present invention achieves both high resolution and high display quality.

This embodiment can be combined with the other embodiments as appropriate.

### Embodiment 4

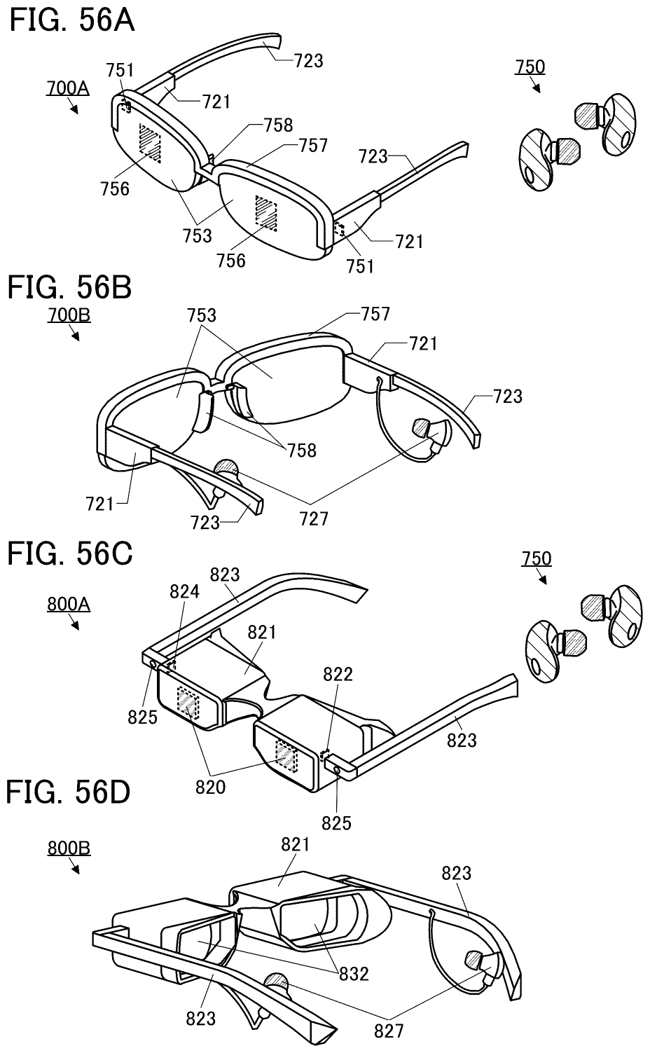

In this embodiment, electronic devices of embodiments of the present invention will be described with reference to FIG. 56 to FIG. 58.

Electronic devices in this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head will be described with reference to FIG. 56A to FIG. 56D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 56A and an electronic device 700B illustrated in FIG. 56B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery (not shown) so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 56C and an electronic device 800B illustrated in FIG. 56D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are not shown in FIG. 56D.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portions 823. FIG. 56C and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance from an object may be provided. In other words, the image capturing portion 825 is one embodiment of the sensing portion. As the sensing portion, an image sensor or a range image sensor such as a LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as a bone-conduction earphone. For example, a structure including the vibration mechanism can be employed for any one or more of the display portion 820, the housing 821, and the wearing portion 823. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A in FIG. 56A has a function of transmitting information to the earphones 750 with the wireless communication function. For another example, the electronic device 800A in FIG. 56C has a function of transmitting information to the earphones 750 with the wireless communication function.

The electronic device may include an earphone portion. The electronic device 700B in FIG. 56B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 56D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

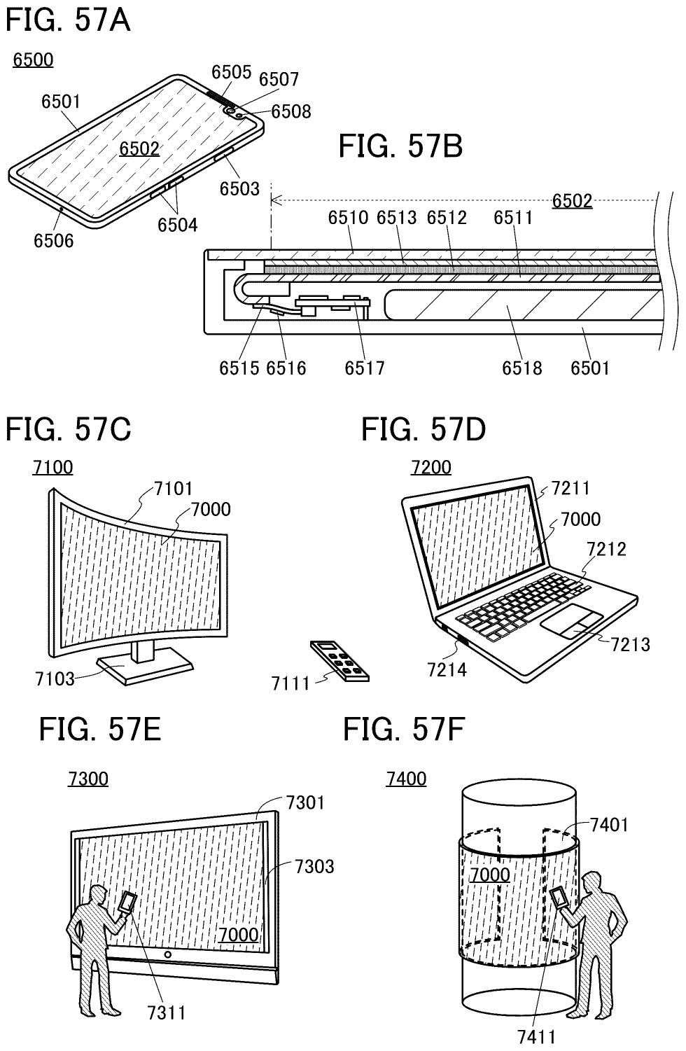

An electronic device 6500 illustrated in FIG. 57A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 57B is a schematic cross-sectional view including an end portion of the housing 6501 on the microphone 6506 side.

A protection member 6510 having a light-transmitting property is provided on the display surface side of the housing 6501; a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 57C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 57C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 57D illustrates an example of a notebook personal computer. The notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 57E and FIG. 57F illustrate examples of digital signage.

Digital signage 7300 illustrated in FIG. 57E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 57F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 57E and FIG. 57F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 57E and FIG. 57F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

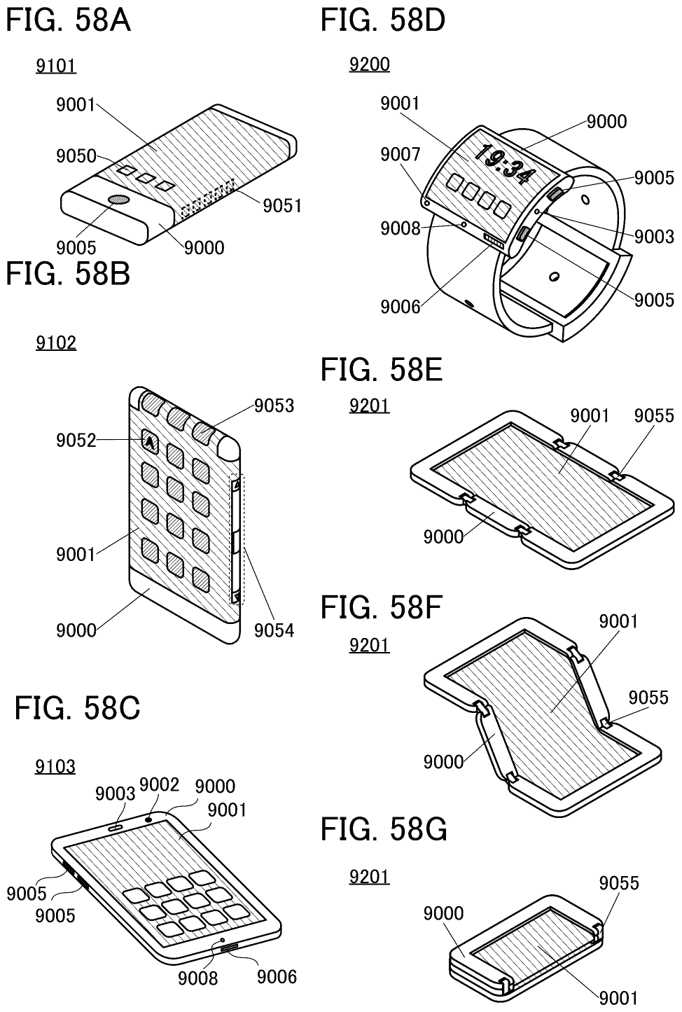

Electronic devices illustrated in FIG. 58A to FIG. 58G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIG. 58A to FIG. 58G, the display device of one embodiment of the present invention can be used in the display portion 9001.

The electronic devices illustrated in FIG. 58A to FIG. 58G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIG. 58A to FIG. 58G will be described in detail below.

FIG. 58A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 58A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, the remaining battery, and the radio field intensity. Alternatively, the icon 9050 or the like may be displayed at the position where the information 9051 is displayed.

FIG. 58B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 58C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 58D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 58E to FIG. 58G are perspective views of a foldable portable information terminal 9201. FIG. 58E is a perspective view illustrating the portable information terminal 9201 that is opened. FIG. 58G is a perspective view illustrating the portable information terminal 9201 that is folded. FIG. 58F is a perspective view illustrating the portable information terminal 9201 that is shifted from one of the states in FIG. 58E and FIG. 58G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example

In this example, transistors were fabricated, and their electrical characteristics were evaluated.

In this example, a sample including a semiconductor device of one embodiment of the present invention was fabricated. For the structure of the sample, the description of the semiconductor device illustrated in FIG. 13, FIG. 14A, and FIG. 14B can be referred to. Specifically, the fabricated sample includes the transistors 100B, which are VFETs, and the transistors 200B, which are TGSA transistors.

### <Sample Fabrication>

A glass substrate with a size of 600 mm×720 mm was used as the substrate 102. The structure of the transistor 100B will be described. For the conductive layer 112a, a stacked-layer structure of an approximately 300-nm-thick copper film and an approximately 100-nm-thick In—Sn—Si oxide (ITSO) film over the copper film was used. For the conductive layer 112b, an approximately 100-nm-thick In—Sn—Si oxide (ITSO) film was used. For the semiconductor layer 108, an approximately 16-nm-thick first metal oxide film was used. For the insulating layer 106, an approximately 50-nm-thick silicon oxynitride film was used. The insulating layer 106 functions as a gate insulating layer of the transistor 100B. For the conductive layer 104, a stacked-layer structure in which an approximately 50-nm-thick titanium film, an approximately 200-nm-thick aluminum film, and an approximately 50-nm-thick titanium film were formed in this order was used.

The structure of the insulating layer 110 will be described. An approximately 70-nm-thick silicon nitride film was used for the insulating layer 110a_1, an approximately 100-nm-thick silicon nitride film was used for the insulating layer 110a_2, an approximately 500-nm-thick silicon oxynitride film was used for the insulating layer 110b, an approximately 50-nm-thick silicon nitride film was used for the insulating layer 110c_1, and an approximately 100-nm-thick silicon nitride film was used for the insulating layer 110c_2. The top-view shapes of the opening 141 and the opening 143 were circular.

The structure of the transistor 200B will be described. For the conductive layer 202, a stacked-layer structure of an approximately 300-nm-thick copper film and an approximately 100-nm-thick In—Sn—Si oxide (ITSO) film over the copper film was used. The conductive layer 202 was formed through the same process as the conductive layer 112a. The structure of the insulating layer 110 is as described above. An approximately 60-nm-thick silicon nitride film was used for the insulating layer 120_1 of the insulating layer 120, and an approximately 50-nm-thick silicon oxynitride film was used for the insulating layer 120_2. The insulating layer 120 was formed in a region where the semiconductor layer 208 was to be provided. For the semiconductor layer 208, an approximately 20-nm-thick second metal oxide film was used. The semiconductor layer 208 and the semiconductor layer 108 were formed using different materials in different steps. That is, the composition of the first metal oxide film used for the semiconductor layer 108 and the composition of the second metal oxide film used for the semiconductor layer 208 were different from each other. For the insulating layer 105, an approximately 40-nm-thick silicon oxynitride film was used. The structure of the insulating layer 106 is as described above. The insulating layer 105 and the insulating layer 106 function as a gate insulating layer of the transistor 200B. In other words, the thickness of the gate insulating layer of the transistor 200B was set to be larger than the thickness of the gate insulating layer of the transistor 100B. For each of the conductive layer 204, the conductive layer 212a, and the conductive layer 212b, a stacked-layer structure in which an approximately 50-nm-thick titanium film, an approximately 200-nm-thick aluminum film, and an approximately 50-nm-thick titanium film were formed in this order was used. The conductive layer 204, the conductive layer 212a, and the conductive layer 212b were formed in the same process as the conductive layer 104. The regions 208L and the regions 208D were formed by supplying an impurity element (here, boron) to the semiconductor layer 208 with the use of the conductive layer 204 as a mask.

For the insulating layer 195, an approximately 300-nm-thick silicon nitride oxide film was used. Over the insulating layer 195, an approximately 1.5-μm-thick polyimide film was formed.

<I_{d}-V_{g} Characteristics>

Next, the I_{d}-V_{g} characteristics of the transistors 100B and the transistors 200B of the above sample were measured.

For the measurement of the I_{d}-V_{g} characteristics of the transistors, a voltage applied to the gate electrode (hereinafter also referred to as gate voltage (V_{g} or V_{gs})) was applied from −10 V to +10 V in increments of 0.1 V. Moreover, a voltage applied to the source electrode (hereinafter also referred to as source voltage (Vs)) was 0 V (comm), and a voltage applied to the drain electrode (hereinafter also referred to as drain voltage (Va or Vas)) was 0.1 V and 5.1 V. In the transistor 200, the back gate electrode (the conductive layer 202) was electrically connected to the source electrode (GND), and the I_{d}-V_{d} characteristics were measured with a gate voltage (V_{g}) applied to the gate electrode (the conductive layer 204).

Here, the measurement was performed for the transistors 100B in each of which the channel width W100 was approximately 6.3 μm (the width D143 of the opening 143 was 2.0 μm) and the transistors 200B in each of which the channel length L200 was 6.0 μm and the channel width W200 was 3.0 μm. The channel length L100 of the transistor 100B was approximately 0.5 μm. The measurement was performed for 10 of the transistors 100B and 10 of the transistors 200B in the substrate plane of 600 mm×720 mm.

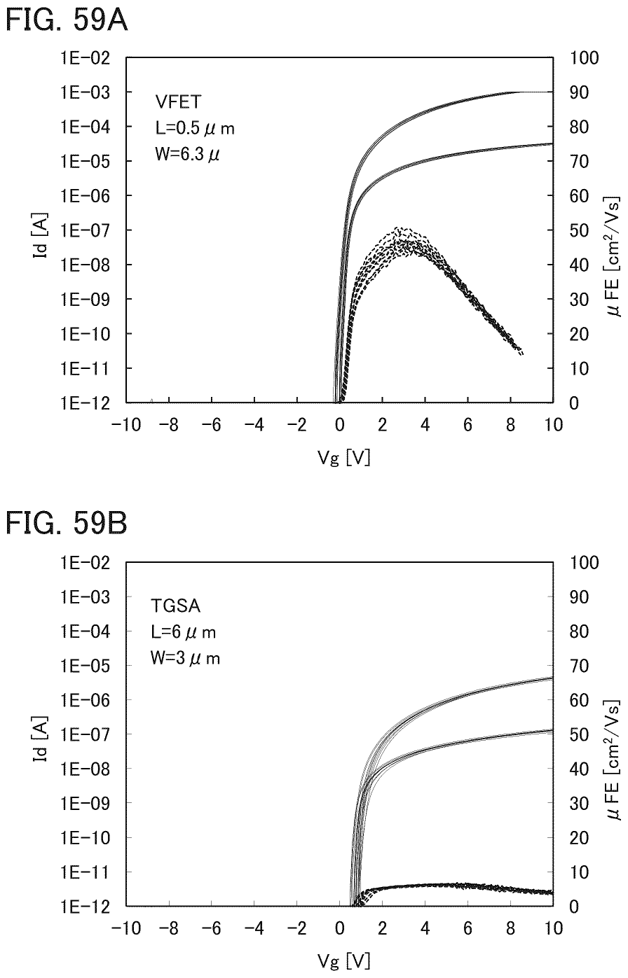

FIG. 59A shows the I_{d}-V_{g} characteristics of the transistors 100B, and FIG. 59B shows the I_{d}-V_{g} characteristics of the transistors 200B. In FIG. 59A and FIG. 59B, the horizontal axis represents a gate voltage (V_{g}), the left vertical axis represents a drain current (I_{d}), and the right vertical axis represents field-effect mobility (μFE) at a drain voltage (V_{d}) of 5.1 V. FIG. 59A and FIG. 59B each show superimposed I_{d}-V_{g} characteristics of the 10 transistors. In FIG. 59A, the channel length is denoted as “L=0.5 μm” and the channel width is denoted as “W=6.3 μm”. In FIG. 59B, the channel length is denoted as “L=6 μm” and the channel width is denoted as “W=3 μm”.

As shown in FIG. 59A and FIG. 59B, it was confirmed that the transistors 100B as VFETs and the transistors 200B as TGSA transistors formed over the same glass substrate by the formation steps some of which were shared had favorable electrical characteristics. In addition, it was confirmed that the transistors 100B had higher field-effect mobility than the transistors 200B.

### <Reliability>

Next, the reliability of the above sample was evaluated.

To evaluate the reliability, a GBT (Gate Bias Temperature) stress test was performed. In this example, a PBTS (Positive Bias Temperature Stress) test and an NBTIS (Negative Bias Temperature Illumination Stress) test were performed.

In the PBTS test, the substrate over which the transistors were formed was held at 60° C., a voltage of 0.1 V was applied to the source and the drain of each transistor, and a voltage of 10 V was applied to the gate thereof; this state was maintained for one hour. The test was performed in a dark environment. In the NBTIS test, the substrate over which the transistors were formed was held at 60° C., a voltage of 0 V was applied to the source and the drain of each transistor and a voltage of −10 V was applied to the gate thereof in a state where irradiation with white LED light at 5000 lx was performed; this state was maintained for one hour. The irradiation with white LED light was performed from the glass substrate side.

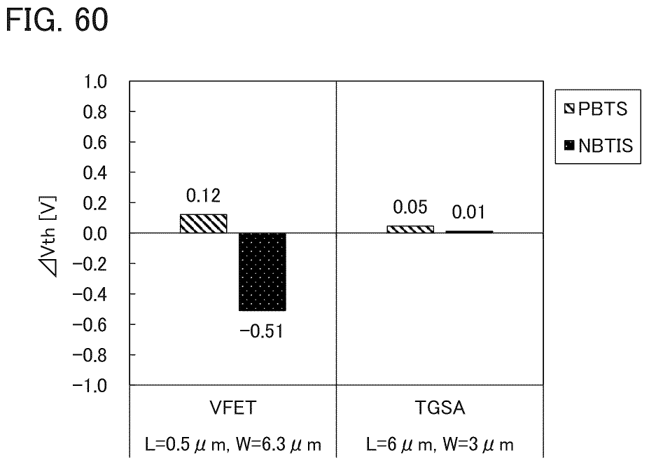

FIG. 60 shows the amounts of change in the threshold voltage before and after the PBTS test and the amounts of change in the threshold voltage before and after the NBTIS test. In FIG. 60, the horizontal axis represents the conditions of the transistors, and the vertical axis represents the amount of change in threshold voltage (ΔVₜₕ). In FIG. 60, the channel lengths and the channel widths are shown as in FIG. 59A and FIG. 59B.

As shown in FIG. 60, it was confirmed that the amount of change in threshold voltage was small in each of the transistor 100B and the transistor 200B in both the PBTS test and the NBTIS test, and that each of the transistor 100B and the transistor 200B had high reliability.

In this example, it was confirmed that the VFET and the TGSA transistor which are different in the material of the semiconductor layer and the thickness of the gate insulating layer and which are fabricated over the glass substrate can have favorable electrical characteristics and high reliability.

### REFERENCE NUMERALS

10A: semiconductor device, 10B: semiconductor device, 10C: semiconductor device, 10D: semiconductor device, 10E: semiconductor device, 10F: semiconductor device, 10G: semiconductor device, 10H: semiconductor device, 10J: semiconductor device, 10: semiconductor device, 50A: display device, 50B: display device, 50C: display device, 50D: display device, 50E: display device, 50F: display device, 50G: display device, 51A: pixel circuit, 51: pixel circuit, 52A: transistor, 52B: transistor, 52C: transistor, 53: capacitor, 61: light-emitting device, 100A: transistor, 100B: transistor, 100C: transistor, 100D: transistor, 100E: transistor, 100F: transistor, 100: transistor, 102: substrate, 103: conductive layer, 104C: conductive layer, 104F: conductive layer, 104f: conductive film, 104: conductive layer, 105A: insulating layer, 105f: insulating film, 105: insulating layer, 106f: insulating film, 106: insulating layer, 107: insulating layer, 108C: semiconductor layer, 108F: semiconductor layer, 108f: metal oxide film, 108L: region, 108: semiconductor layer, 110a: insulating layer, 110a_1: insulating layer, 110a_2: insulating layer, 110af: insulating film, 110b: insulating layer, 110bf: insulating film, 110c: insulating layer, 110c_1: insulating layer, 110c_2: insulating layer, 110cf: insulating film, 110: insulating layer, 111B: pixel electrode, 111G: pixel electrode, 111R: pixel electrode, 111S: pixel electrode, 111: pixel electrode, 112a: conductive layer, 112aC: conductive layer, 112aF: conductive layer, 112B: conductive layer, 112b: conductive layer, 112bC: conductive layer, 112BF: conductive layer, 112bF: conductive layer, 112bf: conductive film, 113B: EL layer, 113G: EL layer, 113R: EL layer, 113S: functional layer, 113: EL layer, 114: common layer, 115: common electrode, 117: light-blocking layer, 118B: sacrificial layer, 118G: sacrificial layer, 118R: sacrificial layer, 119B: sacrificial layer, 119G: sacrificial layer, 120_1: insulating layer, 120_1f: insulating film, 120_2: insulating layer, 120_2f: insulating film, 120f: insulating film, 120: insulating layer, 123: conductive layer, 124B: conductive layer, 124G: conductive layer, 124R: conductive layer, 125f: insulating film, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133Bf: film, 133G: layer, 133R: layer, 133: layer, 135: opening, 139: opening, 140: connection portion, 141F: opening, 141: opening, 142: adhesive layer, 143F: opening, 143: opening, 147a: opening, 147b: opening, 148: opening, 149: opening, 151: substrate, 152: substrate, 153: insulating layer, 159a: resist mask, 159b: resist mask, 159c: resist mask, 162: display portion, 164: peripheral circuit portion, 165: wiring, 166: conductive layer, 168: connection portion, 172: FPC, 173: IC, 180: metal oxide layer, 195: insulating layer, 200A: transistor, 200B: transistor, 200C: transistor, 200D: transistor, 200E: transistor, 200F: transistor, 200G: transistor, 200H: transistor, 200: transistor, 202: conductive layer, 204: conductive layer, 205B: transistor, 205D: transistor, 205G: transistor, 205R: transistor, 205S: transistor, 208D: region, 208f: metal oxide film, 208L: region, 208: semiconductor layer, 210: pixel, 212a: conductive layer, 212b: conductive layer, 230B: pixel, 230G: pixel, 230R: pixel, 230: pixel, 231: first driver circuit portion, 232: second driver circuit portion, 235: insulating layer, 236: wiring, 237: insulating layer, 238: wiring, 242: connection layer, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first transistor, a second transistor, and a first insulating layer,
wherein the first transistor comprises a first conductive layer, a second conductive layer, a first semiconductor layer, a second insulating layer over the first semiconductor layer, and a third conductive layer over the second insulating layer,
wherein the first insulating layer is sandwiched between the first conductive layer and the second conductive layer,
wherein the first insulating layer and the second conductive layer comprise an opening reaching the first conductive layer,
wherein in the opening, the first semiconductor layer is in contact with a top surface of the first conductive layer, a side surface of the first insulating layer, and a first side surface of the second conductive layer,
wherein the first semiconductor layer comprises a region overlapping with the third conductive layer with the second insulating layer between the region and the third conductive layer,
wherein the second transistor comprises a second semiconductor layer over the first insulating layer, a third insulating layer over the second semiconductor layer, the second insulating layer over the third insulating layer, and a fourth conductive layer over the second insulating layer,
wherein an end portion of the second semiconductor layer is aligned or substantially aligned with an end portion of the third insulating layer,
wherein the second insulating layer is in contact with a top surface and a side surface of the third insulating layer and a side surface of the second semiconductor layer, and
wherein the second semiconductor layer comprises a region overlapping with the fourth conductive layer with the second insulating layer and the third insulating layer between the region and the fourth conductive layer.

2. The semiconductor device according to claim 1, further comprising a fourth insulating layer between the first insulating layer and the second semiconductor layer,
wherein the fourth insulating layer is in contact with a bottom surface of the second conductive layer.

3. The semiconductor device according to claim 1, further comprising an island-shaped fourth insulating layer between the first insulating layer and the second semiconductor layer,
wherein the end portion of the second semiconductor layer is in contact with a top surface of the fourth insulating layer,
wherein an end portion of the fourth insulating layer is in contact with a top surface of the first insulating layer, and
wherein the second insulating layer is in contact with the top surface and a side surface of the fourth insulating layer.

4. The semiconductor device according to claim 1, further comprising a fourth insulating layer between the first insulating layer and the second semiconductor layer,
wherein the fourth insulating layer is in contact with a top surface and a second side surface of the second conductive layer.

5. A semiconductor device comprising:
a first transistor, a second transistor, and a first insulating layer,
wherein the first transistor comprises a first conductive layer, a second conductive layer, a first semiconductor layer, a second insulating layer over the first semiconductor layer, and a third conductive layer over the second insulating layer,
wherein the first insulating layer is sandwiched between the first conductive layer and the second conductive layer,
wherein the first insulating layer and the second conductive layer comprise a first opening reaching the first conductive layer,
wherein in the first opening, the first semiconductor layer is in contact with a top surface of the first conductive layer, a first side surface of the first insulating layer, and a side surface of the second conductive layer,
wherein the first semiconductor layer comprises a region overlapping with the third conductive layer with the second insulating layer between the region and the third conductive layer,
wherein the second transistor comprises a fourth conductive layer, a fifth conductive layer, a second semiconductor layer, a third insulating layer over the second semiconductor layer, the second insulating layer over the third insulating layer, and a sixth conductive layer over the second insulating layer,
wherein the first insulating layer is sandwiched between the fourth conductive layer and the fifth conductive layer,
wherein the first insulating layer and the fifth conductive layer comprise a second opening reaching the fourth conductive layer,
wherein in the second opening, the second semiconductor layer is in contact with a top surface of the fourth conductive layer, a second side surface of the first insulating layer, and a side surface of the fifth conductive layer,
wherein an end portion of the second semiconductor layer is aligned or substantially aligned with an end portion of the third insulating layer, and
wherein the second semiconductor layer comprises a region overlapping with the sixth conductive layer with the second insulating layer and the third insulating layer between the region and the sixth conductive layer.

6. The semiconductor device according to claim 1,
wherein the first semiconductor layer and the second semiconductor layer each comprise a metal oxide.

7. The semiconductor device according to claim 1,
wherein the first semiconductor layer and the second semiconductor layer comprise different materials.

8. The semiconductor device according to claim 1,
wherein the first semiconductor layer and the second semiconductor layer comprise the same material.

9. The semiconductor device according to claim 1,
wherein the second transistor comprises a seventh conductive layer, and
wherein the seventh conductive layer comprises a region overlapping with the second semiconductor layer with the first insulating layer between the region and the second semiconductor layer.

10. The semiconductor device according to claim 9,
wherein the first conductive layer and the seventh conductive layer comprise the same material.

11. The semiconductor device according to claim 2,
wherein the second transistor comprises a seventh conductive layer, and
wherein the seventh conductive layer is provided between the first insulating layer and the fourth insulating layer.

12. The semiconductor device according to claim 11,
wherein the second conductive layer and the seventh conductive layer comprise the same material.
